(19) United States
(12) Patent Application Publication
(10) Pub. No.: US 2021/0109446 A1
(43) Pub. Date: Apr. 15, 2021

(54) ACTINIC RAY-SENSITIVE OR RADIATION-SENSITIVE RESIN COMPOSITION, PATTERN FORMING METHOD, METHOD FOR MANUFACTURING ELECTRONIC DEVICE, AND RESIN

(71) Applicant: FUJIFILM Corporation, Tokyo (JP)

(72) Inventors: Akiyoshi Goto, Haibara-gun (JP); Takashi Kawashima, Haibara-gun (JP); Kazunari Yagi, Haibara-gun (JP); Daisuke Asakawa, Haibara-gun (JP); Akira Takada, Haibara-gun (JP)

(73) Assignee: FUJIFILM Corporation, Tokyo (JP)

(21) Appl. No.: 17/130,054

(22) Filed: Dec. 22, 2020

Related U.S. Application Data
(63) Continuation of application No. PCT/JP2019/024899, filed on Jun. 24, 2019.

(30) Foreign Application Priority Data
Jun. 28, 2018 (JP) 2018-123195

(51) Int. Cl. G03F 7/039; G03F 7/038; C08F 220/18; C08F 216/36; C08F 220/28

(52) U.S. Cl. CPC G03F 7/039; G03F 7/038; C08F 220/1806; C08F 220/1808; C08F 220/1818; C08F 220/281; C08F 220/1807; C08F 216/36; C08F 220/1804; C08F 220/1812; C08F 220/1805; C08F 220/1809

(57) ABSTRACT

The present invention provides an actinic ray-sensitive or radiation-sensitive resin composition in which fewer defects are generated in any development treatment of alkali development and organic solvent development, a pattern forming method, a method for manufacturing an electronic device, and a resin. The actinic ray-sensitive or radiation-sensitive resin composition of an embodiment of the present invention includes a resin having a repeating unit represented by Formula (1) and a repeating unit having an acid-decomposable group, and a photoacid generator.

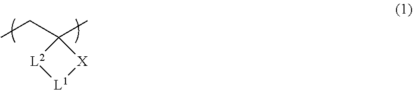

### CROSS-REFERENCE TO RELATED APPLICATIONS

This application is a Continuation of PCT International Application No. PCT/JP2019/024899 filed on Jun. 24, 2019, which claims priority under 35 U.S.C. § 119(a) to Japanese Patent Application No. 2018-123195 filed on Jun. 28, 2018. Each of the above applications is hereby expressly incorporated by reference, in its entirety, into the present application.

### BACKGROUND OF THE INVENTION

### 1. Field of the Invention

The present invention relates to an actinic ray-sensitive or radiation-sensitive resin composition, a pattern forming method, a method for manufacturing an electronic device, and a resin.

### 2. Description of the Related Art

In processes for manufacturing semiconductor devices such as an integrated circuit (IC) and a large scale integrated circuit (LSI), microfabrication by lithography using an actinic ray-sensitive or radiation-sensitive resin composition has been performed.

Examples of the lithography method include a method of forming a resist film with an actinic ray-sensitive or radiation-sensitive resin composition, exposing the obtained film, and then performing development.

A photoresist composition containing a polymer component having a structural unit represented by Formula (1) is disclosed in WO2012/157352A.

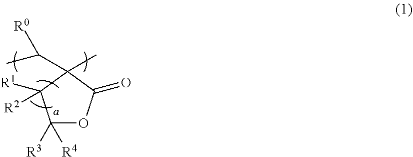

### SUMMARY OF THE INVENTION

In recent years, in pattern formation using an actinic ray-sensitive or radiation-sensitive resin composition, it is desirable that there are fewer defects after a development treatment (development defects). Further, in the present specification, a defect means a defect derived from a residue after a resist film is undissolved in a region from which the resist film formed using the actinic ray-sensitive or radiation-sensitive resin composition is to be removed in a case where a development treatment is performed. In particular, it is desirable that there be fewer defects in a case where any of an alkali developer or an organic solvent developer (a developer including an organic solvent) is used.

The present inventors have performed evaluations of the defects using the polymer component described in WO2012/157352A, and have thus found that a further improvement was required.

An object of the present invention is to provide an actinic ray-sensitive or radiation-sensitive resin composition in which fewer defects are generated in any development treatment of alkali development and organic solvent development.

In addition, another object of the present invention is to provide a pattern forming method, a method for manufacturing an electronic device, and a resin.

The present inventors have found that the problems can be solved by the following configurations.

(1) An actinic ray-sensitive or radiation-sensitive resin composition comprising: a resin having a repeating unit represented by Formula (1) which will be described later and a repeating unit having an acid-decomposable group; and

a photoacid generator.

(2) The actinic ray-sensitive or radiation-sensitive resin composition as described in (1),

in which a ring including X, L¹, and L² in Formula (1) has 5 or 6 ring members.

(3) The actinic ray-sensitive or radiation-sensitive resin composition as described in (1) or (2),

in which at least one of L or L² includes a heteroatom.

(4) The actinic ray-sensitive or radiation-sensitive resin composition as described in any one of (1) to (3),

in which at least one of L or L² includes a halogen atom.

(5) A pattern forming method comprising:

a step of forming a resist film on a substrate, using the actinic ray-sensitive or radiation-sensitive resin composition as described in any one of (1) to (4);

a step of exposing the resist film; and

a step of developing the exposed resist film using a developer to form a pattern.

(6) A method for manufacturing an electronic device, comprising the pattern forming method as described in (5).

(7) A resin comprising:

a repeating unit represented by Formula (1) which will be described later; and

a repeating unit having an acid-decomposable group.

According to the present invention, it is possible to provide an actinic ray-sensitive or radiation-sensitive resin composition in which fewer defects are generated in any development treatment of alkali development and organic solvent development.

Furthermore, according to the present invention, it is also possible to provide a pattern forming method, a method for manufacturing an electronic device, and a resin.

### DESCRIPTION OF THE PREFERRED EMBODIMENTS

Hereinafter, an example of aspects for carrying out the present invention will be described.

Furthermore, in the present specification, a numerical value range expressed using “to” means a range that includes the preceding and succeeding numerical values of “to” as a lower limit value and an upper limit value, respectively.

In addition, in citations for a group (atomic group) in the present specification, in a case where the group is cited without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

“(Meth)acryl” in the present specification is a generic term encompassing acryl and methacryl, and means “at least one of acryl or methacryl”. Similarly, “(meth)acrylic acid” means “at least one of acrylic acid or methacrylic acid”.

In the present specification, the weight-average molecular weight (Mw), the number-average molecular weight (Mn), and the dispersity (also referred to as a molecular weight distribution) (Mw/Mn) of a resin are each defined as a value converted in terms of polystyrene by means of gel permeation chromatography (GPC) measurement (solvent:tetrahydrofran, flow amount (amount of a sample injected): 10 μL, columns: TSK gel Multipore HXL-M manufactured by Tosoh Corporation, column temperature: 40° C., flow rate: 1.0 mL/min, detector: differential refractive index detector) using a GPC apparatus (HLC-8120 GPC manufactured by Tosoh Corporation).

1 Å is 1×10⁻¹⁰ m.

One of the characteristic points of the actinic ray-sensitive or radiation-sensitive resin composition of the embodiment of the present invention (hereinafter also referred to as a “resist composition”) is that a repeating unit represented by Formula (1) which will be described later is used. In a case where the resin has the repeating unit represented by Formula (1), the solubility in an alkali developer and an organic solvent developer is improved, and as a result, generation of defects in any of alkali development and organic solvent development is suppressed.

In addition, the resist composition is also excellent in line width roughness (LWR).

The resist composition includes a resin having a repeating unit represented by Formula (1) which will be described later and a repeating unit having an acid-decomposable group, and a photoacid generator.

Hereinafter, the respective components included in the resist composition will be described in detail.

<Resin Having Repeating Unit Represented by Formula (1) and Repeating Unit Having Acid-Decomposable Group (Hereinafter Also Referred to “Resin (A)”)>

The resin (A) has a repeating unit represented by Formula (1).

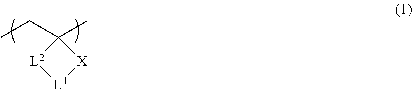

In Formula (1), X represents —C(═O)—.

L¹ represents a group represented by Formula (A) or a group represented by Formula (B). Further, in Formula (A) and Formula (B), *1 represents a bonding position with X and *2 represents a bonding position with L².

*2-L⁴-L³-*1 Formula (A)

*2-L⁶=L⁵-*1 Formula (B)

In a case where L is the group represented by Formula (A), the repeating unit represented by Formula (1) represents a repeating unit represented by Formula (1-A), and in a case where the group is the group represented by Formula (B), the repeating unit represented by Formula (1) represents a repeating unit represented by Formula (1-B).

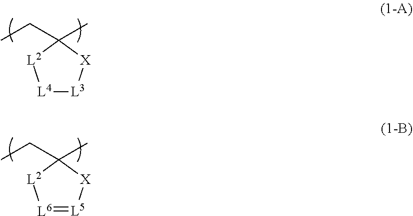

In Formula (A), L³ represents —C(R¹)(R²)—, —C(═O)—, —C(═S)—, or —C(═N—R³)—. L⁴ represents a single bond or —C(R⁴)(R⁵)—.

R¹ to R⁵ each independently represent a hydrogen atom or a substituent.

The type of the substituent represented by each of R¹ to R⁵ is not particularly limited, and examples of the substituent include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butylsulfanyl group; arylsulfanyl groups such as a phenylsulfanyl group and a p-tolylsulfanyl group; an alkyl group; a cycloalkyl group; an aryl group; a heteroaryl group; a hydroxyl group; a carboxyl group; a formyl group; a sulfo group; an alkylsulfonyl group; a cyano group; an alkylaminocarbonyl group; an arylaminocarbonyl group; a sulfonamido group; a silyl group; an amino group; a monoalkylamino group; a dialkylamino group; an arylamino group; and a combination thereof.

Incidentally, the above-exemplified groups may be further substituted with a substituent. The substituent may be, for example, a halogenated alkyl group in which a halogen atom is substituted on the alkyl group.

As the substituent represented by each of R¹, R², R⁴, and R⁵, a group having a polar group, a group having an acid-decomposable group, the alkyl group, the acyloxy group, the alkylsulfonyl group, or the alkoxycarbonyl group is preferable. These substituents may be further substituted with a substituent (for example, a halogen atom).

The polar group is preferably a phenolic hydroxyl group, a fluorinated alcohol group, a carbonate group, a ketone group, a sulfonamido group, an ester group, an amido group, a hydroxyl group, an ether group, or a cyano group, and more preferably the phenolic hydroxyl group or the hexafluoro-2-propanol group.

Examples of the acid-decomposable group include groups exemplified as an acid-decomposable group contained in the repeating unit having an acid-decomposable group which will be described later.

R¹ and R² may be bonded to each other to form a ring which may include a heteroatom.

The type of the ring thus formed is not particularly limited, and examples of the ring include an aliphatic hydrocarbon ring which may have a heteroatom. In other words, examples of the ring formed by the mutual bonding of R¹ and R² include an aliphatic hydrocarbon ring or an aliphatic heterocycle. The number of ring members of the ring formed is preferably 3 to 8, and more preferably 4 to 6. Examples of the heteroatom (heteroatom included in the aliphatic heterocycle) include an oxygen atom, a sulfur atom, and a nitrogen atom. The heteroatom may be included as a group such as —O—, —S—, —CO—, and —NH—.

The ring formed by the mutual bonding of R¹ and R² may further have a substituent. Examples of the substituent include the groups exemplified in the description of the substituent represented by each of R¹ to R⁵.

R⁴ and R⁵ may be bonded to each other to form a ring which may include a heteroatom. Suitable aspects of the ring formed by the mutual bonding of R⁴ and R⁵ are the same as the suitable aspects of the ring formed by the mutual bonding of R¹ and R².

In a case where L³ is —C(R′)(R²)— and L⁴ is —C(R⁴)(R⁵)—, R¹ or R², and R⁴ or R⁵ may be bonded to each other to form a ring which may include a heteroatom. Suitable aspects of the ring are the same as those of the ring formed by the mutual bonding of R¹ or R², and R⁴ or R⁵.

In Formula (B), L⁵ represents ═C(R⁶)—. L⁶ represents —C(R⁷)═.

R⁶ and R⁷ each independently represent a hydrogen atom or a substituent.

Examples of the substituent represented by each of R⁶ and R⁷ include the groups exemplified in the description of the substituent represented by each of R¹ to R⁵. R⁶ and R⁷ may be bonded to each other to form a ring which may include a heteroatom. The type of the ring thus formed is not particularly limited, and examples of the ring include an aromatic ring (for example, a benzene ring) which may have a heteroatom. In other words, examples of the ring formed by the mutual bonding of R⁶ and R⁷ include an aromatic hydrocarbon ring or an aromatic heterocycle. The number of ring members of the ring formed is preferably 3 to 8, and more preferably 4 to 6. Examples of the heteroatom (heteroatom included in the aromatic heterocycle) include an oxygen atom, a sulfur atom, and a nitrogen atom. Heteroatoms may be included as a group such as —O—, —S—, and —N═.

As described above, in Formulae (A) and (B), *1 represents a bonding position with X and *2 represents a bonding position with L².

L² represents a divalent linking group.

Examples of the divalent linking group include —O—, —CO—, —COO—, —S—, —SO₂—, —NR—(R represents a hydrogen atom or an alkyl group), a divalent hydrocarbon group (for example, an alkylene group, an alkenylene group (for example, —CH═CH—), an alkynylene group (for example, —C≡C—), and an arylene group) which may have a substituent, and a group formed by combination thereof.

Examples of the substituent which may be contained in the divalent hydrocarbon group which may have a substituent include the groups exemplified in the description of the substituent represented by each of R¹ to R⁵.

The divalent hydrocarbon group may have a plurality of substituents, and the plurality of substituents may be bonded to each other to form a ring which may include a heteroatom. Suitable aspects of the ring formed by the mutual bonding of a plurality of substituents are the same as the suitable aspects of the ring formed by the mutual bonding of R¹ and R².

As the divalent linking group, a divalent hydrocarbon group which may have a substituent, —O—, or a group (for example, an oxyalkylene group) formed by combination of a divalent hydrocarbon group which may have a substituent and —O— is preferable. Examples of the divalent hydrocarbon group which may have a substituent include an alkylene group which may have a substituent. The number of carbon atoms of the alkylene group is not particularly limited, and is preferably 1 to 5, and more preferably 1 to 4.

The number of ring members of the ring including X, L¹, and L² in Formula (1) is not particularly limited, and is 4 to 7 in many cases, and from the viewpoint that at least one effect of further suppressing the generation of defects or achieving more excellent LWR can be obtained (hereinafter also simply referred to as “the effects of the present invention are more excellent”), the number of ring members is preferably 5 or 6.

In addition, the ring including X, L¹, and L² means a ring formed with carbon atoms of the main chain to which X and L² are each bonded, X, L¹, and L².

Among those, it is preferable that at least one of L¹ or L² includes a heteroatom from the viewpoint that the effects of the present invention are more excellent. Examples of the heteroatom include an oxygen atom, a nitrogen atom, and a sulfur atom. For example, in a case where L¹ is —C(═O)—, the oxygen atom is included in L.

Furthermore, it is preferable that at least one of L¹ or L² includes a halogen atom from the viewpoint that this makes the composition suitable as an actinic ray-sensitive or radiation-sensitive resin composition for extreme ultraviolet rays (EUV). Examples of the halogen atom include a fluorine atom, a chlorine atom, a bromine atom, and an iodine atom, and the fluorine atom is preferable.

As the repeating unit represented by Formula (1), repeating units represented by Formulae (10) to (14) are preferable from the viewpoint that the effects of the present invention are more excellent.

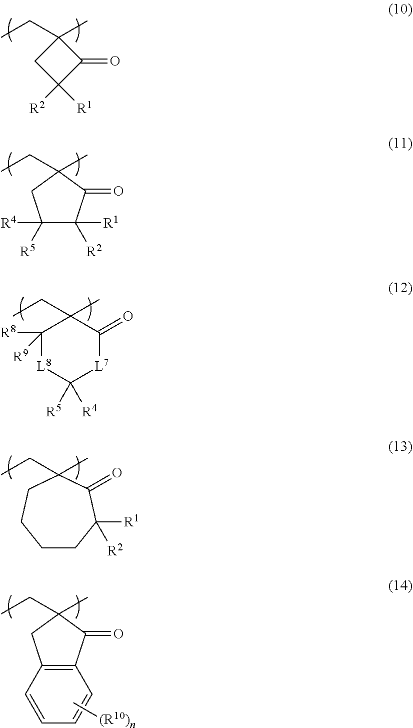

In Formula (10), the definitions of R¹ and R² are as described above. In addition, as described above, R¹ and R² may be bonded to each other to form a ring which may include a heteroatom.

In Formula (11), the definitions of R¹ and R², and R⁴ and R⁵ are as described above. In addition, as described above, R¹ and R² may be bonded to each other to form a ring which may include a heteroatom. Further, R⁴ and R⁵ may be bonded to each other to form a ring which may include a heteroatom. In addition, R¹ or R², and R⁴ or R⁵ may be bonded to each other to form a ring which may include a heteroatom.

In Formula (12), the definitions of R⁴ and R⁵ are as described above. L⁷ represents —C(R¹)(R²)— or —C(═O)—. The definitions of R¹ and R² are as described above. L⁸ represents —C(R¹¹)(R¹²)— or —O—. R¹¹ and R¹² each independently represent a hydrogen atom or a substituent. Examples of the substituent represented by each of R¹¹ and R¹² include the groups exemplified in the description of the substituent represented by each of R¹ to R⁵. R¹¹ and R¹² may be bonded to each other to form a ring which may include a heteroatom. Suitable aspects of the ring formed by the mutual bonding of R¹¹ and R¹² are the same as the suitable aspects of the ring formed by the mutual bonding of R¹ and R². R⁸ and R⁹ each independently represent a hydrogen atom or a substituent. Examples of the substituent represented by each of R⁸ and R⁹ include the groups exemplified in the description of the substituent represented by each of R¹ to R⁵. In addition, as described above, R¹ and R² may be bonded to each other to form a ring which may include a heteroatom. Further, R⁴ and R⁵ may be bonded to each other to form a ring which may include a heteroatom.

In Formula (13), the definitions of R¹ and R² are as described above. In addition, as described above, R¹ and R² may be bonded to each other to form a ring which may include a heteroatom.

In Formula (14), R¹⁰ represents a substituent. Examples of the substituent represented by R¹⁰ include the groups exemplified in the description of the substituent represented by each of R¹ to R⁵. n represents an integer of 0 to 5. In a case where n is 2 or more, R¹⁰'s may be the same as or different from each other.

The content of the repeating unit represented by Formula (1) is preferably 5% to 80% by mole, and more preferably 10% to 70% by mole, with respect to all the repeating units in the resin (A).

(Repeating Unit Having Acid-Decomposable Group)

The resin (A) has a repeating unit having an acid-decomposable group.

The acid-decomposable group is a group that decomposes by the action of an acid to produce a polar group. The acid-decomposable group preferably has a structure in which the polar group is protected with a leaving group that leaves by the action of an acid. That is, the resin (A) has a repeating unit having a group that decomposes by the action of an acid to produce a polar group. A resin having this repeating unit has an increased polarity by the action of an acid, and thus has an increased solubility in an alkali developer, and a decreased solubility in an organic solvent.

As the polar group, an alkali-soluble group is preferable, and examples thereof an acidic group such as a carboxyl group, a phenolic hydroxyl group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group, and an alcoholic hydroxyl group.

Among those, as the polar group, the carboxyl group, the phenolic hydroxyl group, the fluorinated alcohol group (preferably the hexafluoroisopropanol group), or the sulfonic acid group is preferable.

Examples of the leaving group that leaves by the action of an acid include groups represented by Formulae (Y1) to (Y4).

—C(Rx₁)(Rx₂)(Rx₃) Formula (Y1):

—C(═O)OC(Rx₁)(Rx₂)(Rx₃) Formula (Y2):

—C(R₃₆)(R₃₇)(OR₃₈). Formula (Y3):

—C(Rn)(H)(Ar) Formula (Y4):

In Formula (Y1) and Formula (Y2), Rx₁ to Rx₃ each independently represent an (linear or branched) alkyl group or a (monocyclic or polycyclic) cycloalkyl group. Further, in a case where all of Rx₁ to Rx₃ are (linear or branched) alkyl groups, it is preferable that at least two of Rx₁, . . . , or Rx₃ are methyl groups.

Among those, Rx₁ to Rx₃ each independently preferably represent a linear or branched alkyl group, and Rx₁ to Rx₃ each independently more preferably represent a linear alkyl group.

Two of Rx₁ to Rx₃ may be bonded to each other to form a monocycle or polycycle. As the alkyl group of each of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group, is preferable.

As the cycloalkyl group of each of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the cycloalkyl group formed by the bonding of two of Rx₁ to Rx₃, a monocyclic cycloalkyl group such as a cyclopentyl group and a cyclohexyl group, and a polycyclic cycloalkyl group such as a norbornyl group, a tetracyclodecanyl group, a tetracyclododecanyl group, and an adamantyl group are preferable, and a monocyclic cycloalkyl group having 5 or 6 carbon atoms is more preferable.

In the cycloalkyl group formed by the bonding of two of Rx₁ to Rx₃, for example, one of the methylene groups constituting the ring may be substituted with a heteroatom such as an oxygen atom or a group having a heteroatom, such as a carbonyl group.

With regard to the group represented by Formula (Y1) or Formula (Y2), for example, an aspect in which Rx₁ is a methyl group or an ethyl group, and Rx₂ and Rx₃ are bonded to each other to form a cycloalkyl group is preferable.

In Formula (Y3), R₃₆ to R₃₈ each independently represent a hydrogen atom or a monovalent organic group. R₃₇ and R₃₈ may be bonded to each other to form a ring. Examples of the monovalent organic group include an alkyl group, a cycloalkyl group, an aryl group, an aralkyl group, and an alkenyl group. It is also preferable that R₃₆ is a hydrogen atom.

As Formula (Y3), a group represented by Formula (Y3-1) is preferable.

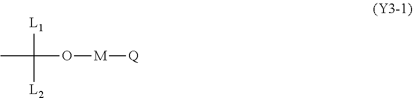

Here, L₁ and L₂ each independently represent a hydrogen atom, an alkyl group, a cycloalkyl group, an aryl group, or a group formed by combination thereof (for example, a group formed by combination of an alkyl group and an aryl group).

M represents a single bond or a divalent linking group.

Q represents an alkyl group which may include a heteroatom, a cycloalkyl group which may include a heteroatom, an aryl group which may include a heteroatom, an amino group, an ammonium group, a mercapto group, a cyano group, an aldehyde group, or a group formed by combination thereof (for example, a group formed by combination of an alkyl group and a cycloalkyl group).

In the alkyl group and the cycloalkyl group, for example, one of the methylene groups may be substituted with a heteroatom such as an oxygen atom or a group having a heteroatom, such as a carbonyl group.

In addition, it is preferable that one of L₁ or L₂ is a hydrogen atom, and the other is an alkyl group, a cycloalkyl group, an aryl group, or a group formed by combination of an alkylene group and an aryl group.

At least two of Q, M, or L₁ may be bonded to each other to form a ring (preferably a 5-membered or 6-membered ring).

From the viewpoint of pattern miniaturization, L₂ is preferably a secondary or tertiary alkyl group, and more preferably the tertiary alkyl group. Examples of the secondary alkyl group include an isopropyl group, a cyclohexyl group, and a norbornyl group, and examples of the tertiary alkyl group include a tert-butyl group and an adamantane group. In these aspects, since the glass transition temperature (Tg) and the activation energy are increased, it is possible to suppress fogging in addition to ensuring film hardness.

In Formula (Y4), Ar represents an aromatic ring group. Rn represents an alkyl group, a cycloalkyl group, or an aryl group. Rn and Ar may be bonded to each other to form a non-aromatic ring. Ar is more preferably an aryl group.

The repeating unit having an acid-decomposable group is preferably the repeating unit represented by Formula (A).

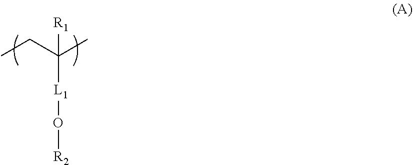

L₁ represents a divalent linking group which may have a fluorine atom or an iodine atom, R₁ represents a hydrogen atom, a fluorine atom, an iodine atom, a fluorine atom, an alkyl group which may have an iodine atom, or an aryl group which may have a fluorine atom or an iodine atom, and R₂ represents a leaving group that leaves by the action of an acid and may have a fluorine atom or an iodine atom. It should be noted that at least one of L₁, R₁, or R₂ has a fluorine atom or an iodine atom.

L₁ represents a divalent linking group which may have a fluorine atom or an iodine atom. Examples of the divalent linking group which may have a fluorine atom or an iodine atom include —CO—, —O—, —S—, —SO—, —SO₂—, a hydrocarbon group (for example, an alkylene group, a cycloalkylene group, an alkenylene group, and an arylene group) which may have a fluorine atom or an iodine atom, and a linking group in which a plurality of these groups are linked. Among those, L₁ is preferably —CO—, -arylene group-alkylene group having fluorine atom or iodine atom-from the viewpoint that the effects of the present invention are more excellent.

The arylene group is preferably a phenylene group.

The alkylene group may be linear or branched. The number of carbon atoms of the alkylene group is not particularly limited, but is preferably 1 to 10, more preferably 1 to 3.

The total number of fluorine atoms and iodine atoms included in the alkylene group having a fluorine atom or an iodine atom is not particularly limited, but is preferably 2 or more, more preferably 2 to 10, and still more preferably 3 to 6, from the viewpoint that the effects of the present invention are more excellent.

R₁ represents a hydrogen atom, a fluorine atom, an iodine atom, an alkyl group which may have a fluorine atom or an iodine atom, or an aryl group which may have a fluorine atom or an iodine atom.

The alkyl group may be linear or branched. The alkyl group preferably has 1 to 10 carbon atoms, and more preferably has 1 to 3 carbon atoms.

The total number of fluorine atoms and iodine atoms included in the alkyl group having a fluorine atom or an iodine atom is not particularly limited, but is preferably 1 or more, more preferably 1 to 5, and still more preferably 1 to 3, from the viewpoint that the effects of the present invention are more excellent.

The alkyl group may include a heteroatom such as an oxygen atom other than a halogen atom.

R₂ represents a leaving group that leaves by the action of an acid and may have a fluorine atom or an iodine atom.

Among those, examples of the leaving group include groups represented by Formulae (Z1) to (Z4).

—C(Rx₁₁)(Rx₁₂)(Rx₁₃). Formula (Z1):

—C(═O)OC(Rx₁₁)(Rx₁₂)(Rx₁₃). Formula (Z2):

—C(R₁₃₆)(R₁₃₇)(OR₁₃₈). Formula (Z3):

—C(Rn₁)(H)(Ar₁) Formula (Z4):

In Formulae (Z1) and (Z2), Rx₁₁ to Rx₁₃ each independently represent an (linear or branched) alkyl group which may have a fluorine atom or an iodine atom, or a (monocyclic or polycyclic) cycloalkyl group which may have a fluorine atom or an iodine atom. Further, in a case where all of Rx₁₁ to Rx₁₃ are (linear or branched) alkyl groups, it is preferable that at least two of Rx₁₁, . . . , or Rx₁₃ are methyl groups.

Rx₁₁ to Rx₁₃ are the same as Rx₁ to Rx₃ in (Y1) and (Y2) described above, respectively, except that they may have a fluorine atom or an iodine atom, and have the same definitions and suitable ranges as those of the alkyl group and the cycloalkyl group.

In Formula (Z3), R₁₃₆ to R₁₃₈ each independently represent a hydrogen atom, or a monovalent organic group which may have a fluorine atom or an iodine atom. R₁₃₇ and R₁₃₈ may be bonded to each other to form a ring. Examples of the monovalent organic group which may have a fluorine atom or an iodine atom include an alkyl group which may have a fluorine atom or an iodine atom, a cycloalkyl group which may have a fluorine atom or an iodine atom, an aryl group which may have a fluorine atom or an iodine atom, an aralkyl group which may have a fluorine atom or an iodine atom, and a group formed by combination thereof (for example, a group formed by combination of the alkyl group and the cycloalkyl group are combined).

Incidentally, the alkyl group, the cycloalkyl group, the aryl group, and the aralkyl group may include a heteroatom such as an oxygen atom, in addition to the fluorine atom and the iodine atom. That is, in the alkyl group, the cycloalkyl group, the aryl group, and the aralkyl group, for example, one of the methylene groups may be substituted with a heteroatom such as an oxygen atom or a group having a heteroatom, such as a carbonyl group.

As Formula (Z3), a group represented by Formula (Z3-1) is preferable.

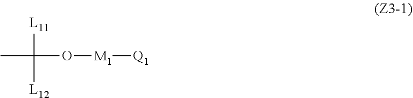

Here, L₁₁ and L₁₂ each independently represent a hydrogen atom; an alkyl group which may have a heteroatom selected from the group consisting of a fluorine atom, an iodine atom, and an oxygen atom; a cycloalkyl group which may have a heteroatom selected from the group consisting of a fluorine atom, an iodine atom, and an oxygen atom; an aryl group which may have a heteroatom selected from the group consisting of a fluorine atom, an iodine atom, and an oxygen atom; or a group formed by combination thereof (for example, a group formed by combination of an alkyl group and a cycloalkyl group, each of which may have a heteroatom selected from the group consisting of a fluorine atom, an iodine atom, and an oxygen atom).

M₁ represents a single bond or a divalent linking group.

Q₁ represents an alkyl group which may have a heteroatom selected from the group consisting of a fluorine atom, an iodine atom, and an oxygen atom; a cycloalkyl group which may have a heteroatom selected from the group consisting of a fluorine atom, an iodine atom, and an oxygen atom; an aryl group which may have a heteroatom selected from the group consisting of a fluorine atom, an iodine atom, and an oxygen atom; an amino group; an ammonium group; a mercapto group; a cyano group; an aldehyde group; a group formed by combination thereof (for example, a group formed by combination of the alkyl group and the cycloalkyl group, each of which may have a heteroatom selected from the group consisting of a fluorine atom, an iodine atom, and an oxygen atom).

In Formula (Y4), Ar represents an aromatic ring group which may have a fluorine atom or an iodine atom. Rn₁ is an alkyl group which may have a fluorine atom or an iodine atom, a cycloalkyl group which may have a fluorine atom or an iodine atom, or an aryl group which may have a fluorine atom or an iodine atom. Rn₁ and Ar₁ may be bonded to each other to form a non-aromatic ring.

As the repeating unit having an acid-decomposable group, a repeating unit represented by Formula (AI) is also preferable.

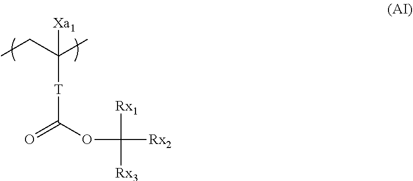

In Formula (AI),

Xa₁ represents a hydrogen atom or an alkyl group which may have a substituent.

T represents a single bond or a divalent linking group.

Rx₁ to Rx₃ each independently represent an (linear or branched) alkyl group or a (monocyclic or polycyclic) cycloalkyl group. It should be noted that in a case where all of Rx₁ to Rx₃ are (linear or branched) alkyl groups, at least two of Rx₁, . . . , or Rx₃ are preferably methyl groups.

Two of Rx₁ to Rx₃ may be bonded to each other to form a (monocyclic or polycyclic) cycloalkyl group.

Examples of the alkyl group which may have a substituent, represented by Xa₁, include a methyl group and a group represented by —CH₂—Ru. R₁ represents a halogen atom (a fluorine atom or the like), a hydroxyl group, or a monovalent organic group; examples thereof include an alkyl group having 5 or less carbon atoms, which may be substituted with a halogen atom, an acyl group having 5 or less carbon atoms, which may be substituted with a halogen atom, and an alkoxy group having 5 or less carbon atoms, which may be substituted with a halogen atom; and an alkyl group having 3 or less carbon atoms is preferable, and a methyl group is more preferable. Xa₁ is preferably a hydrogen atom, a methyl group, a trifluoromethyl group, or a hydroxymethyl group.

Examples of the divalent linking group of T include an alkylene group, an aromatic ring group, a —COO-Rt- group, and an —O-Rt- group. In Formulae, Rt represents an alkylene group or a cycloalkylene group.

T is preferably the single bond or the —COO-Rt- group. In a case where T represents the —COO-Rt- group, Rt is preferably an alkylene group having 1 to 5 carbon atoms, and is more preferably a —CH₂— group, a —(CH₂)₂— group, or a —(CH₂)₃— group.

As the alkyl group of each of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group, is preferable.

As the cycloalkyl group of each of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the cycloalkyl group formed by the bonding of two of Rx₁ to Rx₃, a monocyclic cycloalkyl group such as a cyclopentyl group and a cyclohexyl group is preferable, and in addition, a polycyclic cycloalkyl group such as a norbornyl group, a tetracyclodecanyl group, a tetracyclododecanyl group, and an adamantyl group is preferable. Among those, a monocyclic cycloalkyl group having 5 or 6 carbon atoms is preferable.

In the cycloalkyl group formed by the bonding of two of Rx₁ to Rx₃, for example, one of the methylene groups constituting the ring may be substituted with a heteroatom such as an oxygen atom or a group having a heteroatom, such as a carbonyl group.

With regard to the repeating unit represented by Formula (AI), for example, an aspect in which Rx₁ is a methyl group or an ethyl group, and Rx₂ and Rx₃ are bonded to each other to form the above-mentioned cycloalkyl group is preferable.

In a case where each of the groups has a substituent, examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). The number of carbon atoms in the substituent is preferably 8 or less.

The repeating unit represented by Formula (AI) is preferably an acid-decomposable tertiary alkyl (meth)acrylate ester repeating unit (the repeating unit in which Xa₁ represents a hydrogen atom or a methyl group, and T represents a single bond).

The content of the repeating unit having an acid-decomposable group is preferably 15% to 80% by mole, and more preferably 20% to 70% by mole, with respect to all the repeating units in the resin (A).

Specific examples of the repeating unit having an acid-decomposable group are shown below, but the present invention is not limited thereto. Further, in the formulae, Xa₁ represents H, CH₃, CF₃, or CH₂OH, and Rxa and Rxb each represent a linear or branched alkyl group having 1 to 4 carbon atoms.

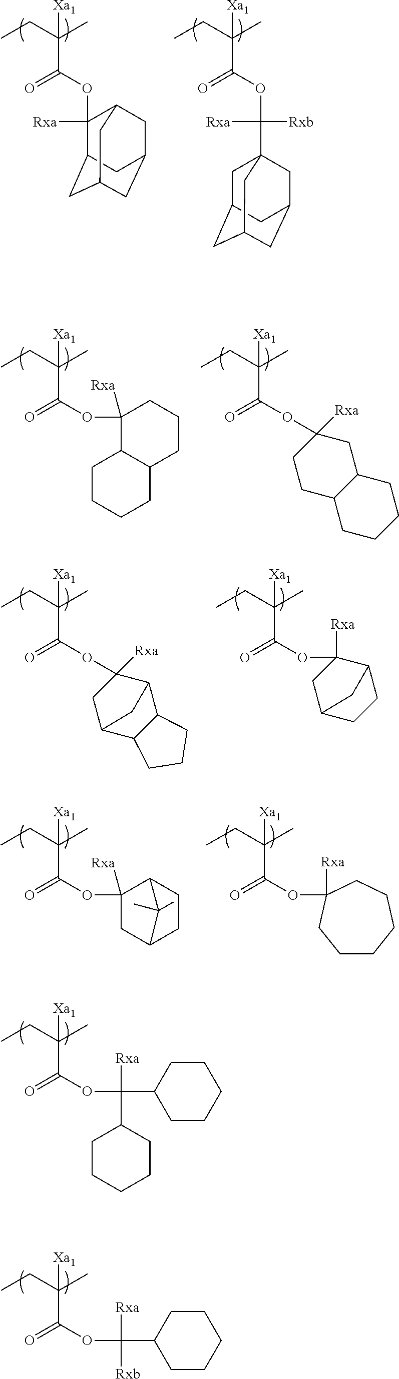

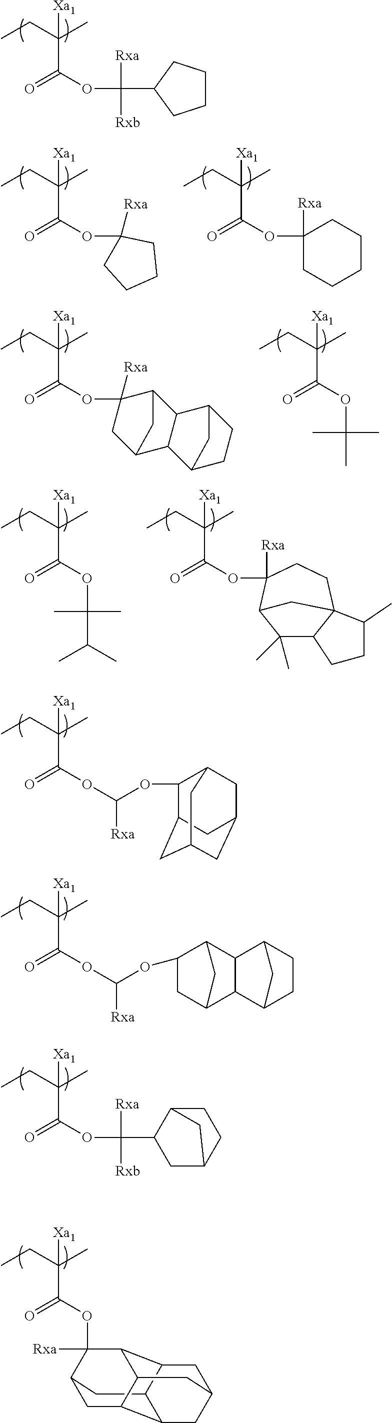

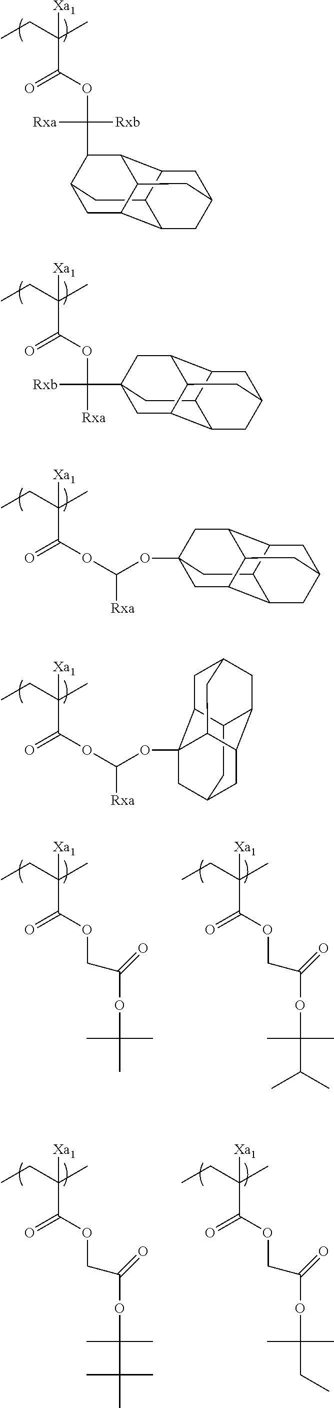

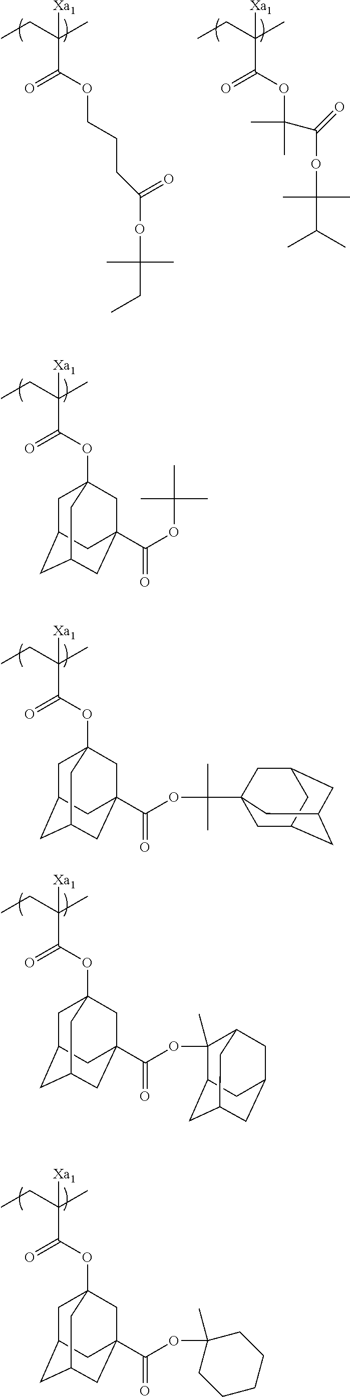

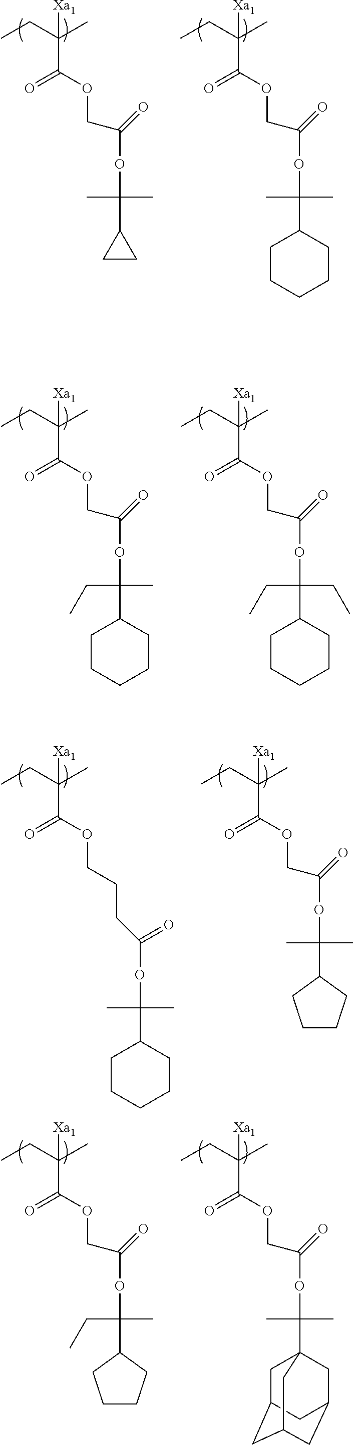

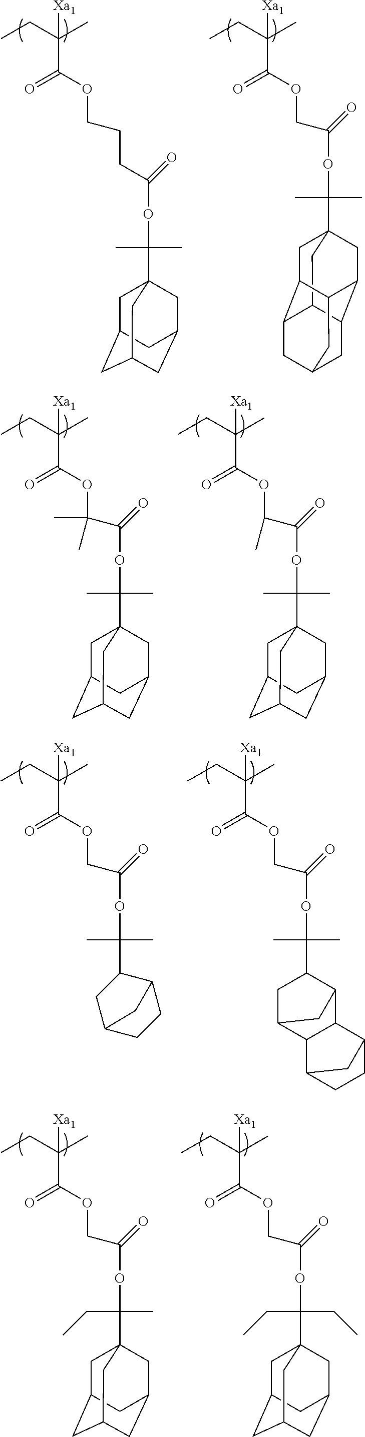

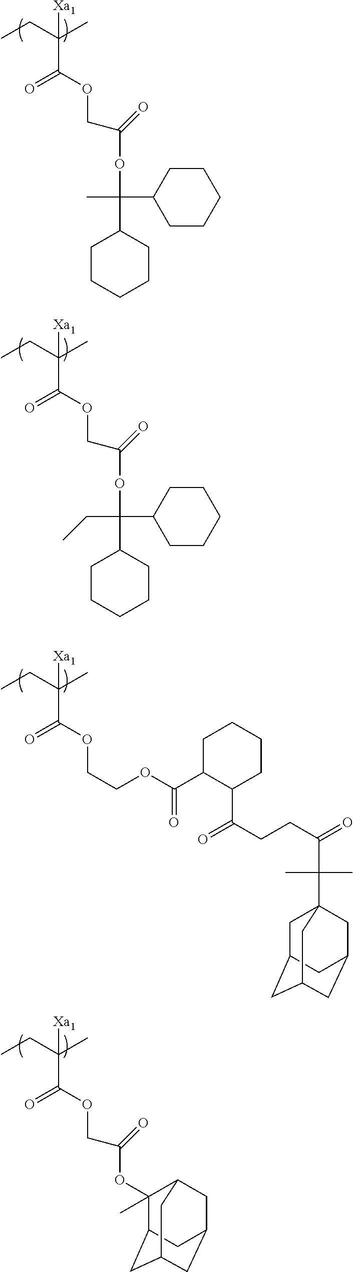

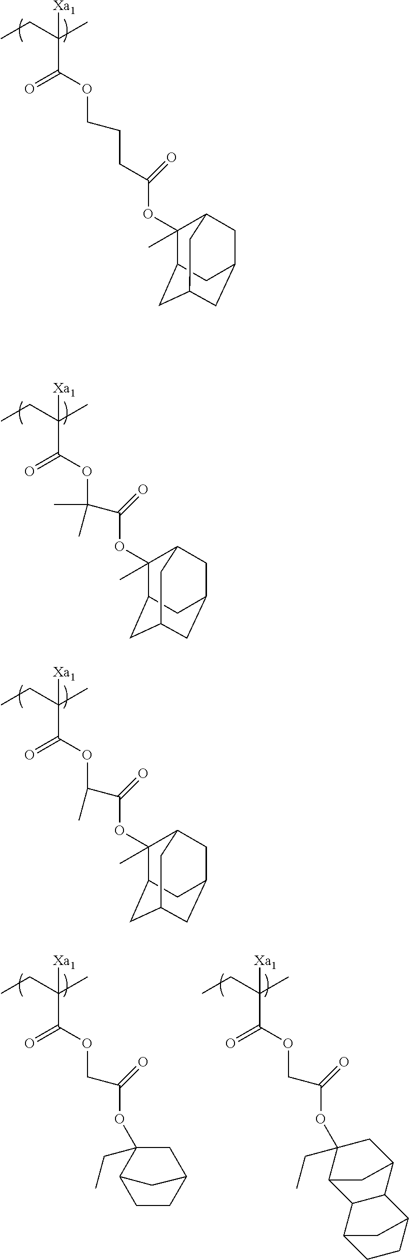

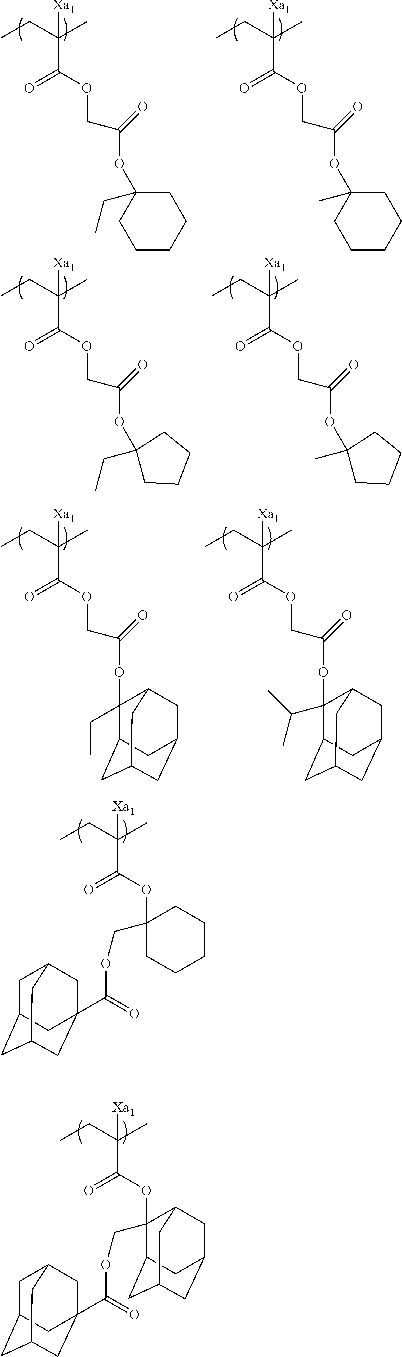

The resin (A) may include a repeating unit other than the above-mentioned repeating units.

For example, the resin (A) may include at least one repeating unit selected from the group consisting of the following group A and/or at least one repeating unit selected from the group consisting of the following group B.

Group A: A group consisting of the following repeating units (20) to (29).

(20) A repeating unit having an acid group, which will be described later.

(21) A repeating unit having a fluorine atom or an iodine atom, which will be described later.

(22) A repeating unit having a lactone group, which will be described later

(23) A repeating unit having a photoacid generating group, which will be described later.

(24) A repeating unit represented by Formula (V-1) or Formula (V-2), which will be described later.

(25) A repeating unit represented by Formula (A), which will be described later.

(26) A repeating unit represented by Formula (B), which will be described later.

(27) A repeating unit represented by Formula (C), which will be described later.

(28) A repeating unit represented by Formula (D), which will be described later.

(29) A repeating unit represented by Formula (E), which will be described later.

Group B: A group consisting of the following repeating units (30) to (32).

(30) A repeating unit having at least one group selected from a lactone group, a hydroxyl group, a cyano group, and an alkali-soluble group, which will be described later.

(31) A repeating unit having an alicyclic hydrocarbon structure and showing no acid decomposability described later.

(32) A repeating unit represented by Formula (III) having neither a hydroxyl group nor a cyano group, which will be described later.

In a case where the resist composition of the embodiment of the present invention is used as an actinic ray-sensitive or radiation-sensitive resin composition for EUV, it is preferable that the resin (A) has at least one repeating unit selected from the group consisting of the group A.

Furthermore, in a case where the resist composition is used as the actinic ray-sensitive or radiation-sensitive resin composition for EUV, it is preferable that the resin (A) includes a fluorine atom and an iodine atom. In a case where the resin (A) includes both a fluorine atom and an iodine atom, the resin (A) may have one repeating unit including both a fluorine atom and an iodine atom, and the resin (A) may include two kinds of repeating units, that is, a repeating unit having a fluorine atom and a repeating unit having an iodine atom.

In a case where the resist composition of the embodiment of the present invention is used as an actinic ray-sensitive or radiation-sensitive resin composition for ArF, it is preferable that the resin (A) has at least one repeating unit selected from the group consisting of the group B.

Furthermore, in a case where the resist composition is used as the actinic ray-sensitive or radiation-sensitive resin composition for ArF, it is preferable that the resin (A) includes neither a fluorine atom nor a silicon atom.

In addition, in a case where the resist composition is used as the actinic ray-sensitive or radiation-sensitive resin composition for ArF, it is preferable that the resin (A) does not have an aromatic group.

(Repeating Unit Having Acid Group)

The resin (A) may have a repeating unit having an acid group.

As the acid group, an acid group having an acid dissociation constant (pKa) of 13 or less is preferable. Examples of the acid group having an acid dissociation constant (pKa) of 13 or less include a carboxyl group, a phenolic hydroxyl group, a fluorinated alcohol group (preferably a hexafluoroisopropanol group), a sulfonic acid group, and a sulfonamido group.

The repeating unit having an acid group may have a fluorine atom or an iodine atom.

As the repeating unit having an acid group, a repeating unit represented by Formula (B) is preferable.

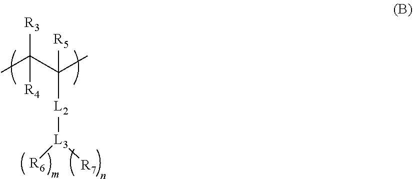

R₃ represents a hydrogen atom or a monovalent organic group which may have a fluorine atom or an iodine atom.

The monovalent organic group which may have a fluorine atom or an iodine atom is preferably a group represented by -L₄-R₈. L₄ represents a single bond or an ester group. R⁸ is an alkyl group which may have a fluorine atom or an iodine atom, a cycloalkyl group which may have a fluorine atom or an iodine atom, an aryl group which may have a fluorine atom or an iodine atom, or a group formed by combination thereof.

R₄ and R₅ each independently represent a hydrogen atom, a fluorine atom, an iodine atom, or an alkyl group which may have a fluorine atom or an iodine atom.

L₂ represents a single bond or an ester group.

L₃ represents an (n+m+1)-valent aromatic hydrocarbon ring group or an (n+m+1)-valent alicyclic hydrocarbon ring group. Examples of the aromatic hydrocarbon ring group include a benzene ring group and a naphthalene ring group. The alicyclic hydrocarbon ring group may be either a monocycle or a polycycle, and examples thereof include a cycloalkyl ring group.

R₆ represents a hydroxyl group or a fluorinated alcohol group (preferably a hexafluoroisopropanol group). In addition, in a case where R₆ is a hydroxyl group, L₃ is preferably the (n+m+1)-valent aromatic hydrocarbon ring group.

R₇ represents a halogen atom. Examples of the halogen atom include a fluorine atom, a chlorine atom, a bromine atom, and an iodine atom.

m represents an integer of 1 or more. m is preferably an integer of 1 to 3 and more preferably an integer of 1 or 2.

n represents 0 or an integer of 1 or more. n is preferably an integer of 1 to 4.

In addition, (n+m+1) is preferably an integer of 1 to 5.

As the repeating unit having an acid group, a repeating unit represented by Formula (I) is also preferable.

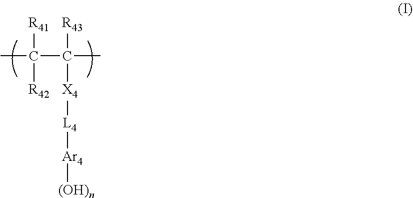

In Formula (I),

R₄₁, R₄₂, and R₄₃ each independently represent a hydrogen atom, an alkyl group, a cycloalkyl group, a halogen atom, a cyano group, or an alkoxycarbonyl group. It should be noted that R₄₂ may be bonded to Ar₄ to form a ring, in which case R₄₂ represents a single bond or an alkylene group.

X₄ represents a single bond, —COO—, or —CONR₆₄—, and R₆₄ represents a hydrogen atom or an alkyl group.

L₄ represents a single bond or an alkylene group.

Ar₄ represents an (n+1)-valent aromatic ring group, and in a case where Ar₄ is bonded to R₄₂ to form a ring, Ar₄ represents an (n+2)-valent aromatic ring group.

n represents an integer of 1 to 5.

As the alkyl group represented by each of R₄₁, R₄₂, and R₄₃ in Formula (I), an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, is preferable, an alkyl group having 8 or less carbon atoms is more preferable, and an alkyl group having 3 or less carbon atoms is still more preferable.

The cycloalkyl group of each of R₄₁, R₄₂, and R₄₃ in Formula (I) may be monocyclic or polycyclic. Among those, a monocyclic cycloalkyl group having 3 to 8 carbon atoms, such as a cyclopropyl group, a cyclopentyl group, and a cyclohexyl group, is preferable.

Examples of the halogen atom of each of R₄₁, R₄₂, and R₄₃ in Formula (I) include a fluorine atom, a chlorine atom, a bromine atom, and an iodine atom, and the fluorine atom is preferable.

As the alkyl group included in the alkoxycarbonyl group of each of R₄₁, R₄₂, and R₄₃ in Formula (I), the same ones as the alkyl group in each of R₄₁, R₄₂, and R₄₃ are preferable.

Preferred examples of the substituent in each of the groups include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The number of carbon atoms of the substituent is preferably 8 or less.

Ar₄ represents an (n+1)-valent aromatic ring group. The divalent aromatic ring group in a case where n is 1 may have a substituent, and is preferably, for example, an arylene group having 6 to 18 carbon atoms, such as a phenylene group, a tolylene group, a naphthylene group, and an anthracenylene group, or an aromatic ring group including a heterocycle such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring.

Specific examples of the (n+1)-valent aromatic ring group in a case where n is an integer of 2 or more include groups formed by removing any (n-1) hydrogen atoms from the above-described specific examples of the divalent aromatic ring group.

The (n+1)-valent aromatic ring group may further have a substituent.

Examples of the substituent which may be included in the alkyl group, the cycloalkyl group, the alkoxycarbonyl group, the alkylene group, and the (n+1)-valent aromatic ring group as mentioned above include alkyl groups; alkoxy groups such as a methoxy group, an ethoxy group, a hydroxyethoxy group, a propoxy group, a hydroxypropoxy group, and a butoxy group; aryl groups such as a phenyl group; and the like, as mentioned for each of R₄₁, R₄₂, and R₄₃ in Formula (I).

Examples of the alkyl group of R₆₄ in —CONR₆₄— represented by X₄ (R₆₄ represents a hydrogen atom or an alkyl group) include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, and an alkyl group having 8 or less carbon atoms, is preferable.

As X₄, a single bond, —COO—, or —CONH— is preferable, and the single bond or —COO— is more preferable.

The alkylene group for L₄ is preferably an alkylene group having 1 to 8 carbon atoms, such as a methylene group, an ethylene group, a propylene group, a butylene group, a hexylene group, and an octylene group.

As Ar₄, an aromatic ring group having 6 to 18 carbon atoms is preferable, and a benzene ring group, a naphthalene ring group, and a biphenylene ring group are more preferable.

The repeating unit represented by Formula (I) preferably has a hydroxystyrene structure. That is, Ar₄ is preferably the benzene ring group.

The repeating unit represented by Formula (I) is preferably a repeating unit represented by Formula (1).

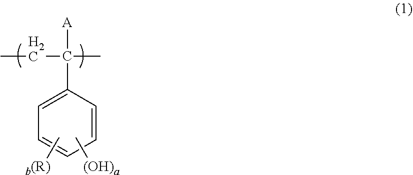

In Formula (1),

A represents a hydrogen atom, an alkyl group, a cycloalkyl group, a halogen atom, or a cyano group.

R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group, and in a case where a plurality of R′s are present, R′s may be the same as or different from each other. In a case where there are a plurality of R′s, R′s may be combined with each other to form a ring. As R, the hydrogen atom is preferable.

a represents an integer of 1 to 3.

b represents an integer of 0 to (5-a).

Specific examples of the repeating unit represented by Formula (I) are shown below, but the present invention is not limited thereto. In the formula, a represents 1 or 2.

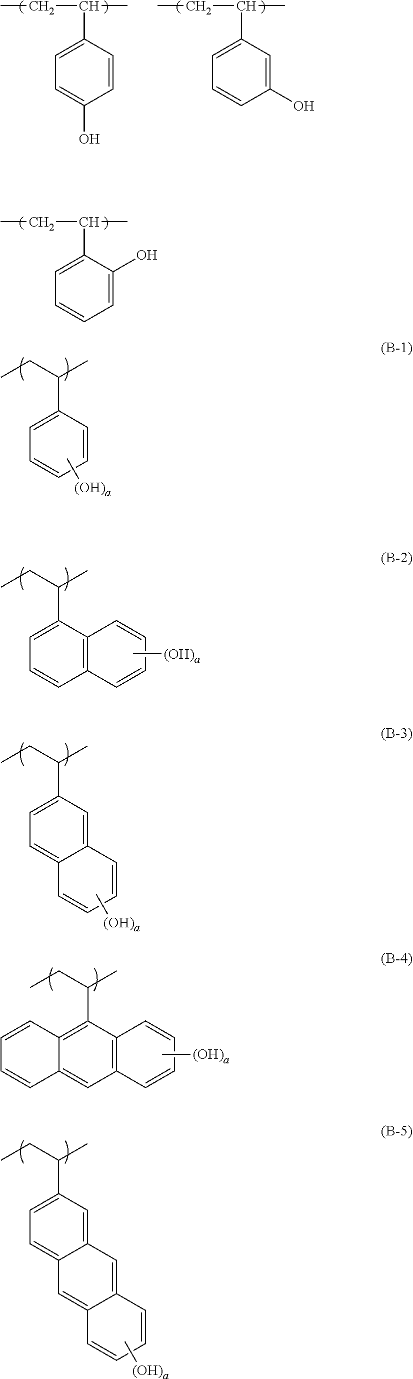

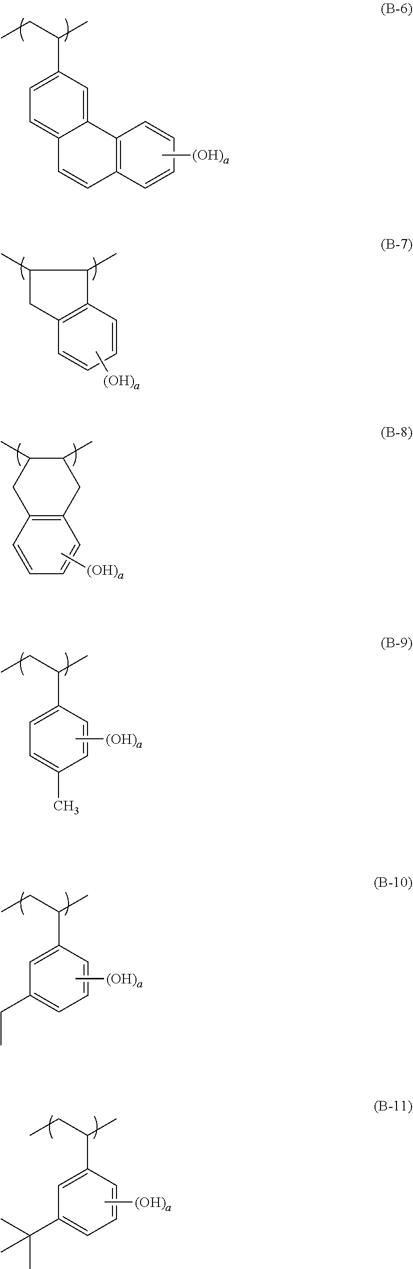

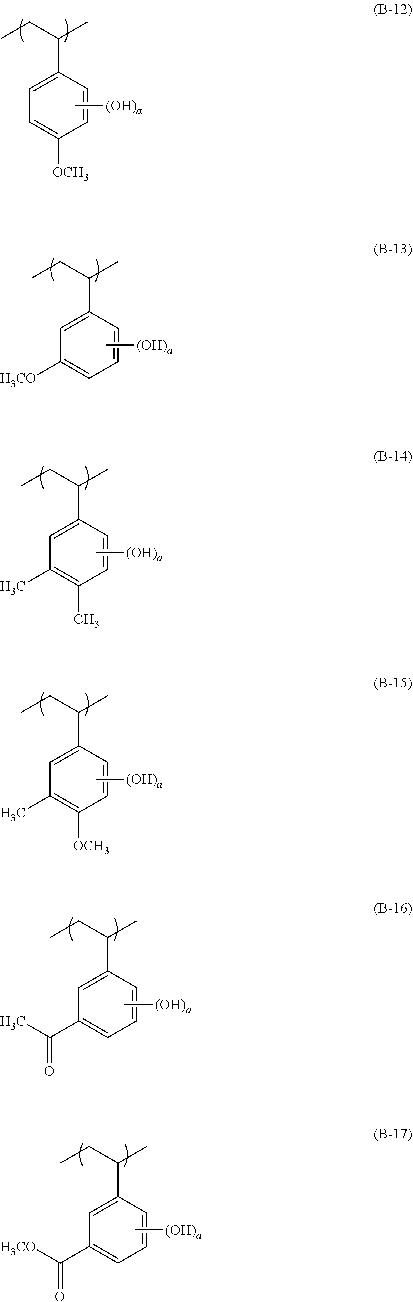

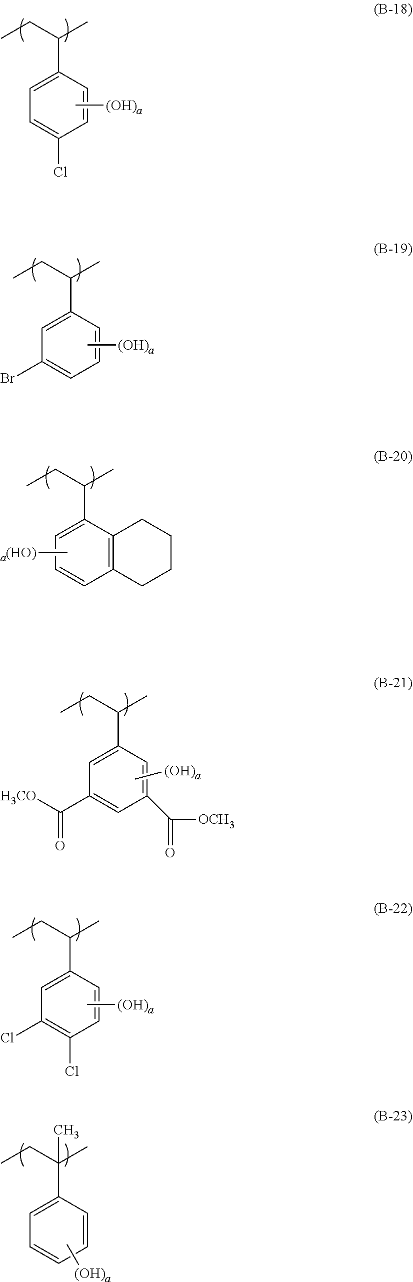

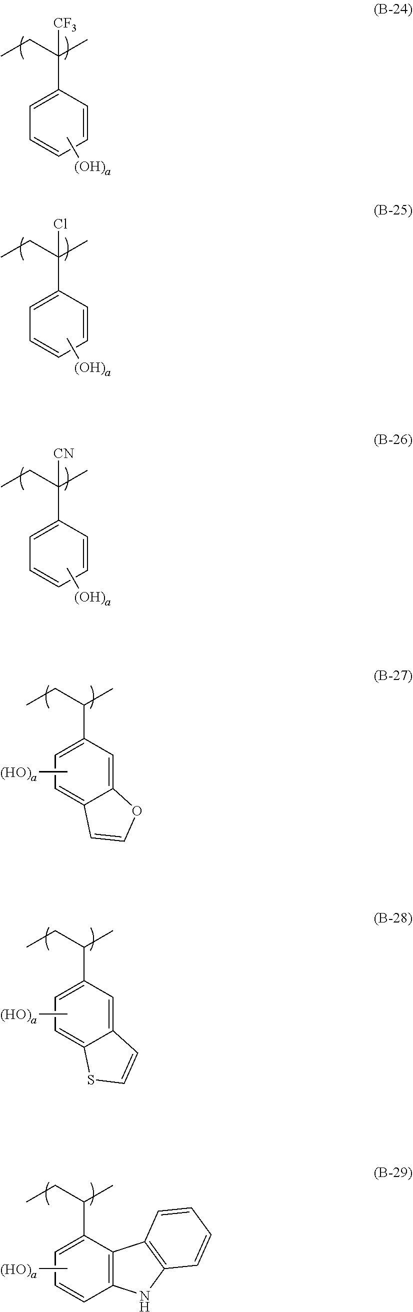

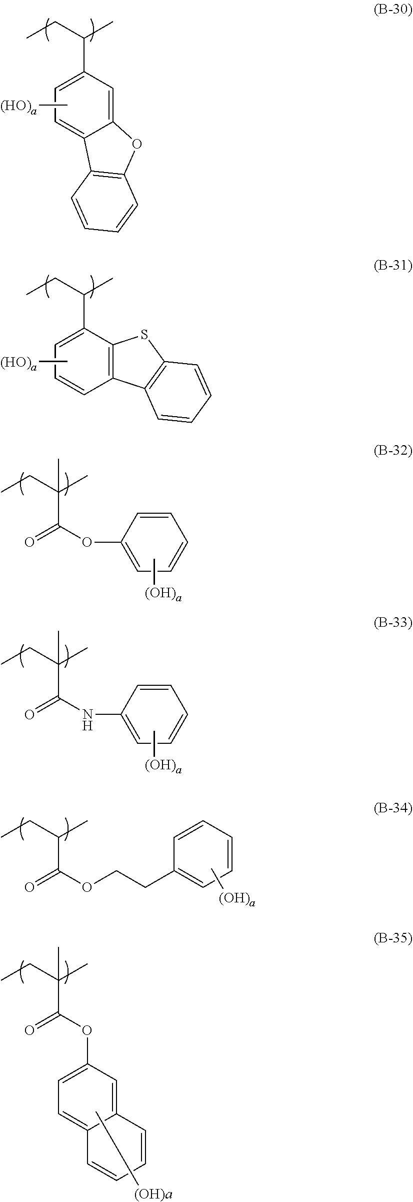

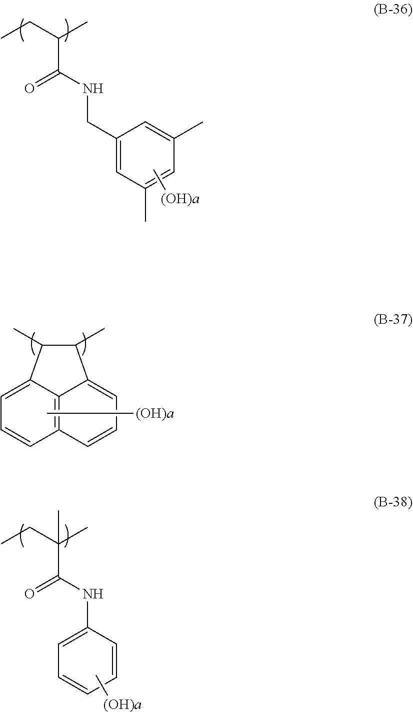

Among the repeating units, the repeating units specifically described below are preferable. In the formulae, R represents a hydrogen atom or a methyl group, and a represents 2 or 3.

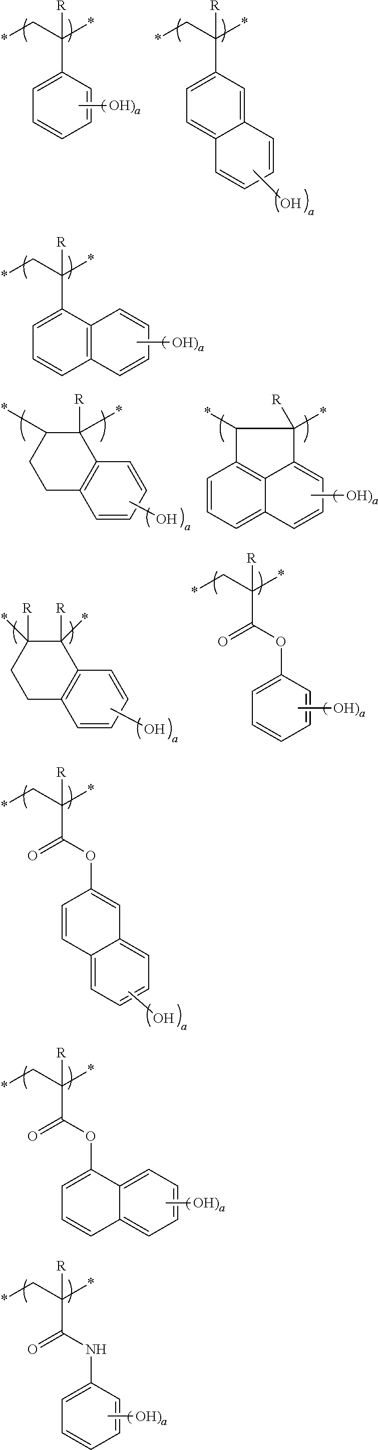

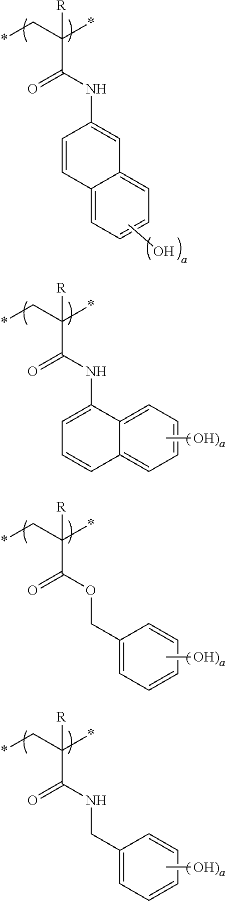

The content of the repeating unit having an acid group is preferably 10% to 70% by mole, more preferably 15% to 65% by mole, and still more preferably 20% to 60% by mole, with respect to all the repeating units in the resin (A).

(Repeating Unit Having Fluorine Atom or Iodine Atom)

The resin (A) may have a repeating unit having a fluorine atom or an iodine atom (hereinafter also simply referred to as a “specific repeating unit”), in addition to (Repeating Unit Represented by Formula (1)), (Repeating Unit Having Acid-Decomposable Group), and (Repeating Unit Having Acid Group) as described above.

As the specific repeating unit, a repeating unit represented by Formula (C) is preferable.

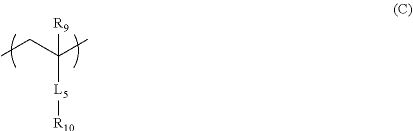

L₅ represents a single bond or an ester group.

R₉ represents a hydrogen atom or an alkyl group which may have a fluorine atom or an iodine atom.

R₁₀ represents a hydrogen atom, an alkyl group which may have a fluorine atom or an iodine atom, a cycloalkyl group which may have a fluorine atom or an iodine atom, an aryl group which may have a fluorine atom or an iodine atom, or a group formed by combination thereof.

The content of the specific repeating unit is preferably 0% to 50% by mole, more preferably 5% to 45% by mole, and still more preferably 10% to 40% by mole, with respect to all the repeating units in the resin (A).

Furthermore, as described above, since the specific repeating unit does not include (Repeating Unit Represented by Formula (1)), (Repeating Unit Having Acid-Decomposable Group), and (Repeating Unit Having Acid Group), the content of the specific repeating unit is also intended to mean the content of the repeating unit having a fluorine atom or an iodine atom, excluding (Repeating Unit Represented by Formula (1)), (Repeating Unit Having Acid-Decomposable Group), and (Repeating Unit Having Acid Group).

As described above, the repeating unit represented by Formula (1) may include a fluorine atom or an iodine atom, the repeating unit having an acid-decomposable group may include a fluorine atom or an iodine atom, and the repeating unit having an acid group may include a fluorine atom or an iodine atom.

Among the repeating units of the resin (A), the total content of the repeating units including at least one of a fluorine atom or an iodine atom is preferably 20% to 100% by mole, more preferably 30% to 100% by mole, and still more preferably 40% to 100% by mole, with respect to all the repeating units of the resin (A).

In addition, examples of the repeating unit including at least one of a fluorine atom or an iodine atom include repeating units which have a fluorine atom or an iodine atom; have the repeating unit represented by Formula (1), a fluorine atom, or an iodine atom; have the repeating unit having an acid-decomposable group, a fluorine atom, or an iodine atom; and have the repeating unit having an acid group, a fluorine atom, or an iodine atom.

(Repeating Unit Having Lactone Group)

The resin (A) may further have a repeating unit having a lactone group.

As the lactone group, any of groups having a lactone structure can be used, but a group having a 5- to 7-membered ring lactone structure is preferable, and a 5- to 7-membered ring lactone structure to which another ring structure is fused in the form of forming a bicyclo structure or a spiro structure is more preferable. The resin (A) still more preferably has a repeating unit having a group having a lactone structure represented by any of Formulae (LC1-1) to (LC1-17). Further, a group having a lactone structure may be bonded directly to the main chain. The lactone structure is preferably a lactone structure represented by Formula (LC1-1), Formula (LC1-4), Formula (LC1-5), Formula (LC1-6), Formula (LC1-13), or Formula (LC1-14).

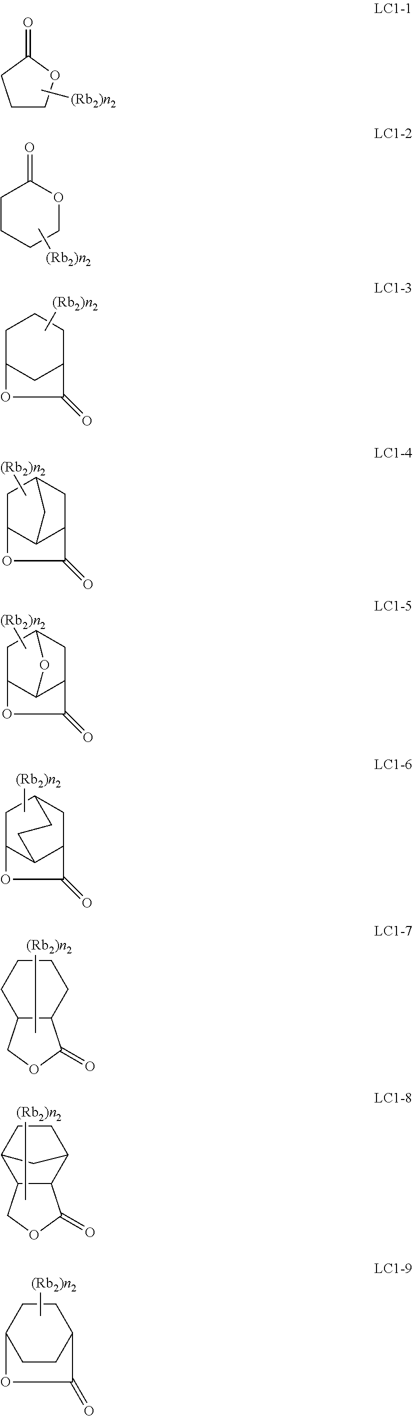

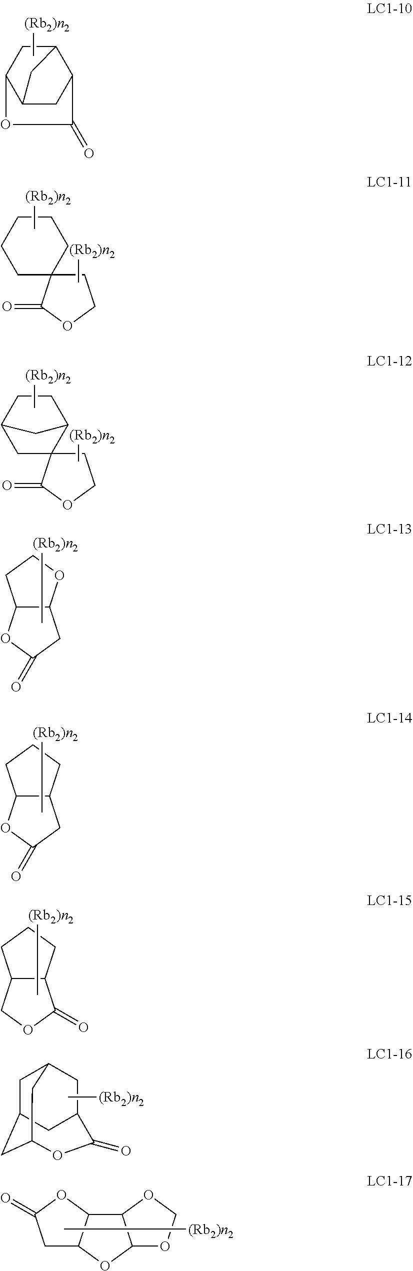

The lactone structural moiety may have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, and an acid-decomposable group. n₂ represents an integer of 0 to 4. In a case where n₂ is 2 or more, Rb₂'s which are present in a plural number may be different from each other and Rb₂'s which are present in a plural number may be bonded to each other to form a ring.

Examples of the repeating unit having the group having a lactone structure represented by any of Formulae (LC1-1) to (LC1-17) include a repeating unit represented by Formula (A1).

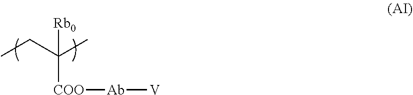

In Formula (AI), Rb₀ represents a hydrogen atom, a halogen atom, or an alkyl group having 1 to 4 carbon atoms.

Preferred examples of a substituent which may be contained in the alkyl group of Rb₀ include a hydroxyl group and a halogen atom.

Examples of the halogen atom of Rb₀ include a fluorine atom, a chlorine atom, a bromine atom, and an iodine atom. Rb₀ is preferably the hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent group formed by combination thereof. Among those, the single bond or a linking group represented by -Ab₁-CO₂— is preferable. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group having a lactone structure represented by any of Formulae (LC1-1) to (LC1-17).

The repeating unit having the group having a lactone structure usually has optical isomers, and any of optical isomers may be used. In addition, one kind of optical isomers may be used singly or a plurality of kinds of optical isomers may be mixed and used. In a case where one kind of optical isomers is mainly used, an optical purity (ee) thereof is preferably 90% or more, and more preferably 95% or more.

Specific examples of the repeating unit having a group having a lactone structure are shown below, but the present invention is not limited thereto.

(in the formulae, Rx represents H, CH₃, CH₂OH, or CF₃)

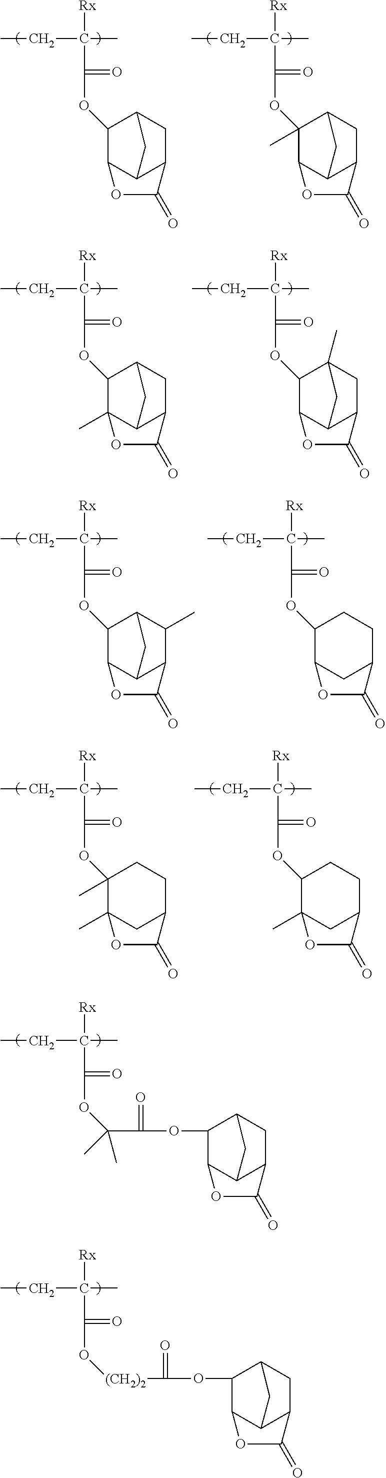

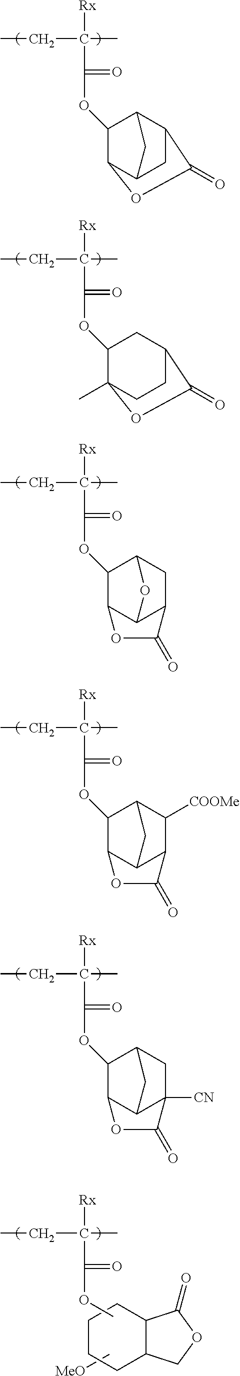

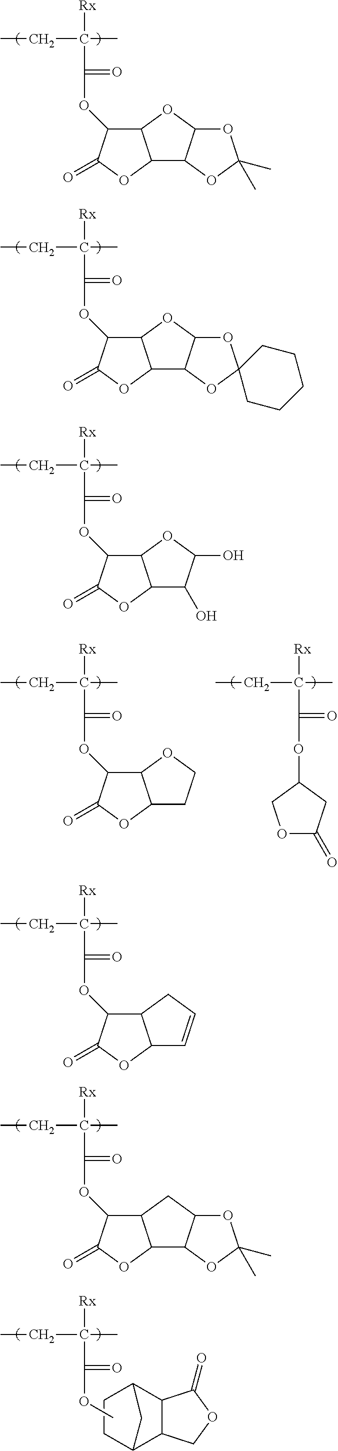

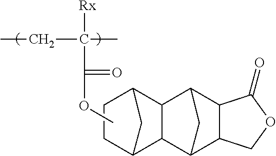

The content of the repeating unit having a lactone group is preferably 1% to 30% by mole, more preferably 5% to 25% by mole, and still more preferably 5% to 20% by mole, with respect to all the repeating units in the resin (A).

(Repeating Unit Having Photoacid Generating Group)

The resin (A) may have, as a repeating unit other than those above, a repeating unit having a group that generates an acid upon irradiation with actinic rays or radiation (hereinafter also referred to as “photoacid generating group”).

In this case, it can be considered that the repeating unit having the photoacid generating group corresponds to a compound (also referred to as “photoacid generator”) that generates an acid upon irradiation with actinic rays or radiation which will be described below.

Examples of such a repeating unit include a repeating unit represented by Formula (4).

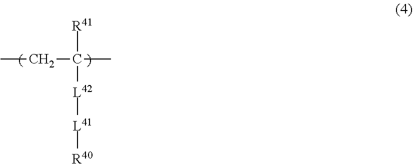

R⁴¹ represents a hydrogen atom or a methyl group. L⁴¹ represents a single bond or a divalent linking group. L⁴² represents a divalent linking group. R⁴⁰ represents a structural moiety that decomposes upon irradiation with actinic rays or radiation to generate an acid in the side chain.

Specific examples of the repeating unit represented by Formula (4) are shown below, but the present invention is not limited thereto.

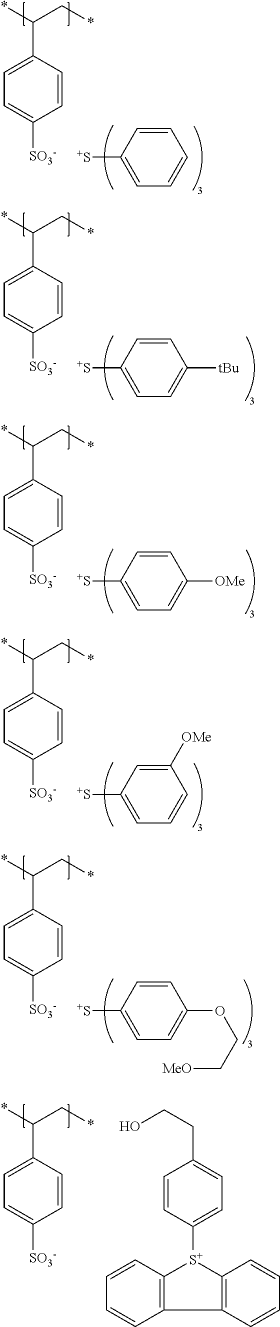

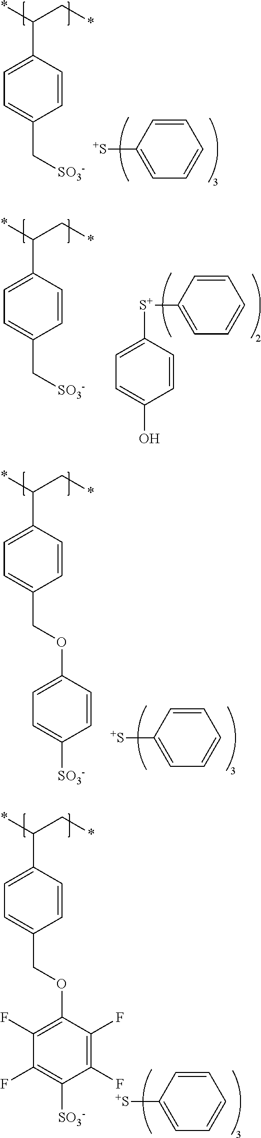

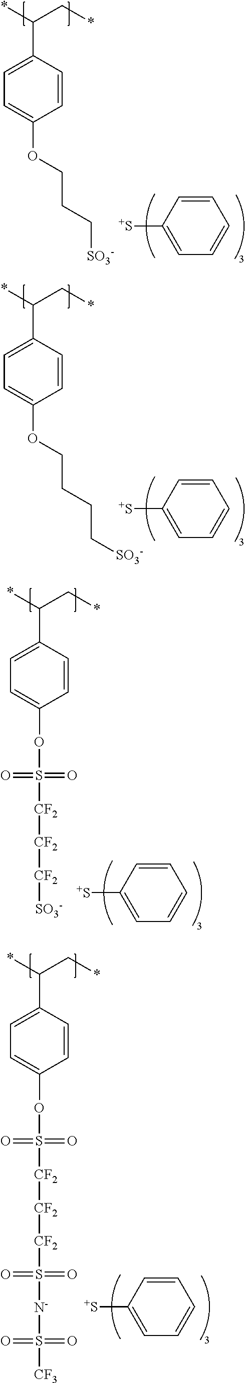

In addition, examples of the repeating unit represented by Formula (4) include the repeating units described in paragraphs [0094] to [0105] of JP2014-041327A.

The content of the repeating unit having a photoacid generating group is preferably 1% to 40% by mole, more preferably 5% to 35% by mole, and still more preferably 5% to 30% by mole, with respect to all the repeating units in the resin (A).

(Repeating Unit Represented by Formula (V-1) or Formula (V-2))

The resin (A) may have a repeating unit represented by Formula (V-1) or Formula (V-2).

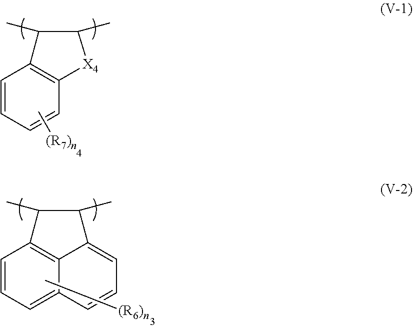

In the formulae,

R₆ and R₇ each independently represent a hydrogen atom, a hydroxyl group, an alkyl group, an alkoxy group, an acyloxy group, a cyano group, a nitro group, an amino group, a halogen atom, an ester group (—OCOR or —COOR: R is an alkyl group or fluorinated alkyl group having 1 to 6 carbon atoms), or a carboxyl group. As the alkyl group, a linear, branched, or cyclic alkyl group having 1 to 10 carbon atoms is preferable.

n₃ represents an integer of 0 to 6.

n₄ represents an integer of 0 to 4.

X₄ is a methylene group, an oxygen atom, or a sulfur atom.

Specific examples of the repeating unit represented by Formula (V-1) or (V-2) are shown below, but the present invention is not limited thereto.

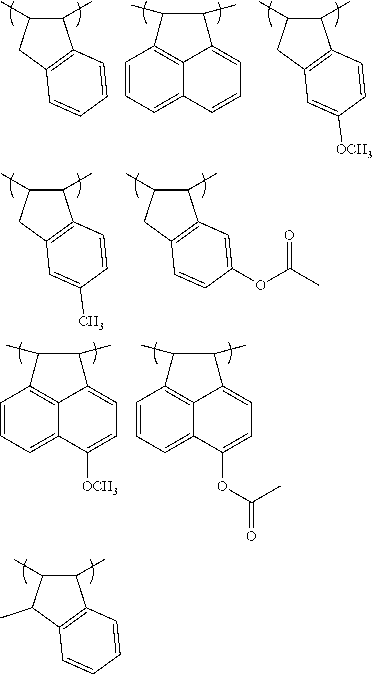

The resin (A) preferably has a high glass transition temperature (Tg) from the viewpoint that excessive diffusion of an acid generated or pattern collapse during development can be suppressed. Tg is preferably higher than 90° C., more preferably higher than 100° C., still more preferably higher than 110° C., and particularly preferably higher than 125° C. In addition, since an excessive increase in Tg causes a decrease in the dissolution rate in a developer, Tg is preferably 400° C. or lower, and more preferably 350° C. or lower.

Furthermore, in the present specification, the glass transition temperature (Tg) of a polymer such as the resin (A) is calculated by the following method. First, the Tg of a homopolymer consisting only of the respective repeating units included in the polymer is calculated by a Bicerano method. Hereinafter, the calculated Tg is referred to as a “Tg of a repeating unit”. Next, the mass proportion (%) of each repeating unit to all repeating units in the polymer is calculated. Then, the Tg at each mass proportion is calculated using a Fox's equation (described in Materials Letters 62 (2008) 3152, and the like), and these are summed to obtain the Tg (° C.) of the polymer.

The Bicerano method is described in Prediction of polymer properties, Marcel Dekker Inc., New York (1993) and the like. In addition, calculation of the Tg by the Bicerano method can be performed using a software for estimating physical properties of a polymer, MDL Polymer (MDL Information Systems, Inc.).

In order to adjust the Tg of the resin (A) to be higher than 90° C., it is preferable to reduce the motility of the main chain of the resin (A). Examples of a method for reducing the motility of the main chain of the resin (A) include the following methods (a) to (e).

(a) Introduction of a bulky substituent into the main chain

(b) Introduction of a plurality of substituents into the main chain

(c) Introduction of a substituent that induces an interaction between the resins (A) near the main chain

(d) Formation of the main chain in a cyclic structure

(e) Connection of a cyclic structure to the main chain

Furthermore, the resin (A) preferably has a repeating unit having a Tg of a homopolymer exhibiting 130° C. or higher.

In addition, the type of the repeating unit having a Tg of the homopolymer exhibiting 130° C. or higher is not particularly limited, and may be any of repeating units having a Tg of a homopolymer of 130° C. or higher calculated by the Bicerano method. Further, it corresponds to a repeating unit having a Tg of a homopolymer exhibiting 130° C. or higher, depending on the type of a functional group in the repeating units represented by Formulae (A) to (E) which will be described later.

(Repeating Unit Represented by Formula (A))

As an example of a specific unit for achieving (a) above, a method of introducing a repeating unit represented by Formula (A) into the resin (A) may be mentioned.

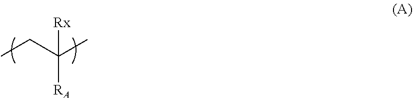

In Formula (A), R_{A} represents a group having a polycyclic structure. Rx represents a hydrogen atom, a methyl group, or an ethyl group. The group having a polycyclic structure is a group having a plurality of ring structures, and the plurality of ring structures may or may not be fused.

Specific examples of the repeating unit represented by Formula (A) include the following repeating units.

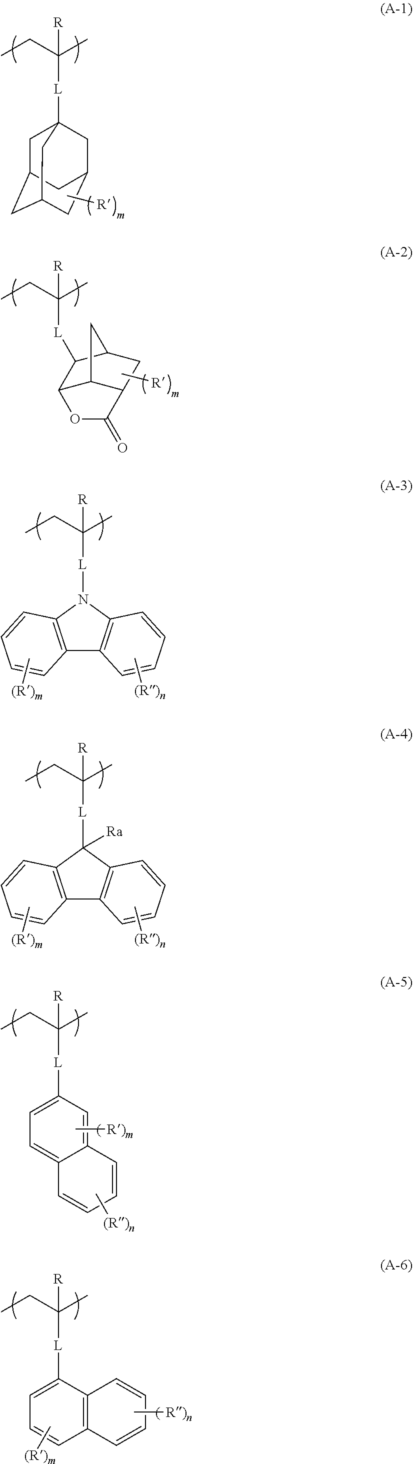

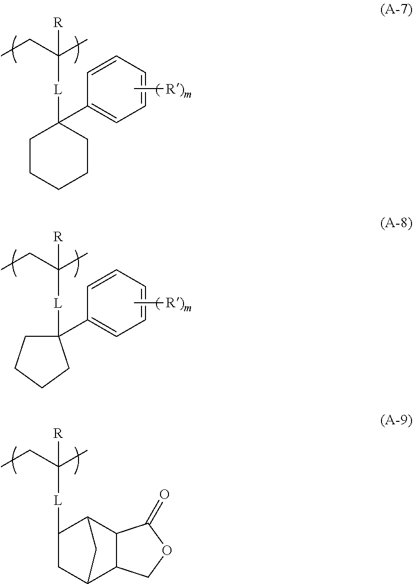

In the formulae, R represents a hydrogen atom, a methyl group, or an ethyl group.

Ra represents a hydrogen atom, an alkyl group, a cycloalkyl group, an aryl group, an aralkyl group, an alkenyl group, a hydroxyl group, an alkoxy group, an acyloxy group, a cyano group, a nitro group, an amino group, a halogen atom, an ester group (—OCOR′″ or —COOR′″: R′″ is an alkyl group or fluorinated alkyl group having 1 to 20 carbon atoms), or a carboxyl group. Further, the alkyl group, the cycloalkyl group, the aryl group, the aralkyl group, and the alkenyl group may each have a substituent. Incidentally, a hydrogen atom bonded to the carbon atom in the group represented by Ra may be substituted with a fluorine atom or an iodine atom.

Moreover, R′ and R″ each independently represent an alkyl group, a cycloalkyl group, an aryl group, an aralkyl group, an alkenyl group, a hydroxyl group, an alkoxy group, an acyloxy group, a cyano group, a nitro group, an amino group, a halogen atom, an ester group (—OCOR′″ or —COOR′″: R′″ is an alkyl group or fluorinated alkyl group having 1 to 20 carbon atoms), or a carboxyl group. Further, the alkyl group, the cycloalkyl group, the aryl group, the aralkyl group, and the alkenyl group may each have a substituent. In addition, a hydrogen atom bonded to the carbon atom in the groups represented by each of R′ and R″ may be substituted with a fluorine atom or an iodine atom.

L represents a single bond or a divalent linking group. Examples of the divalent linking group include —COO—, —CO—, —O—, —S—, —SO—, —SO₂—, an alkylene group, a cycloalkylene group, an alkenylene group, and a linking group in which a plurality of these groups are linked.

m and n each independently represent an integer of 0 or more. The upper limit of each of m and n is not particularly limited, but is 2 or less in many cases, and 1 or less in more cases.

(Repeating Unit Represented by Formula (B))

As an example of a specific unit for achieving (b) above, a method of introducing a repeating unit represented by Formula (B) into the resin (A) may be mentioned.

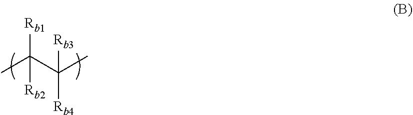

In Formula (B), R_{b1} to R_{b4} each independently represent a hydrogen atom or an organic group, and at least two or more of R_{b1}, . . . , or R_{b4} represent an organic group.

Furthermore, in a case where at least one of the organic groups is a group in which a ring structure is directly linked to the main chain in the repeating unit, the types of the other organic groups are not particularly limited.

In addition, in a case where none of the organic groups is a group in which a ring structure is directly linked to the main chain in the repeating unit, at least two or more of the organic groups are substituents having three or more constituent atoms excluding hydrogen atoms.

Specific examples of the repeating unit represented by Formula (B) include the following repeating units.

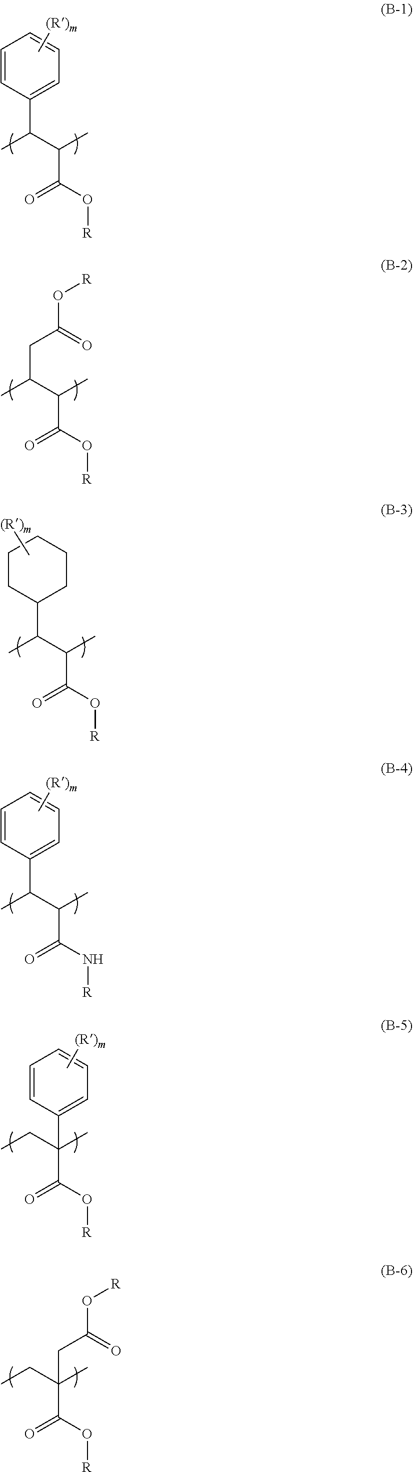

In the formula, R′s each independently represent a hydrogen atom or an organic group. Examples of the organic group include an organic group such as an alkyl group, a cycloalkyl group, an aryl group, an aralkyl group, and an alkenyl group, each of which may have a substituent.

R″s each independently represent an alkyl group, a cycloalkyl group, an aryl group, an aralkyl group, an alkenyl group, a hydroxyl group, a hydroxyl group, an alkoxy group, an acyloxy group, a cyano group, a nitro group, an amino group, a halogen atom, an ester group (—OCOR″ or —COOR″: R″ is an alkyl group or fluorinated alkyl group having 1 to 20 carbon atoms), or a carboxyl group. Further, the alkyl group, the cycloalkyl group, the aryl group, the aralkyl group, and the alkenyl group may each have a substituent. Incidentally, a hydrogen atom bonded to the carbon atom in the group represented by R′ may be substituted with a fluorine atom or an iodine atom.

m represents an integer of 0 or more. The upper limit of n is not particularly limited, but is 2 or less in many cases, and 1 or less in more cases.

(Repeating Unit Represented by Formula (C))

As an example of a specific unit for achieving (c) above, a method of introducing a repeating unit represented by Formula (C) into the resin (A) may be mentioned.

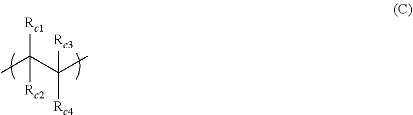

In Formula (C), R_{c1} to R_{c4} each independently represent a hydrogen atom or an organic group, and at least one of R_{c1}, . . . , or R_{c4} is a group having a hydrogen-bonding hydrogen atom within 3 atoms from the main chain carbon. Above all, in order to induce an interaction between the main chains of the resin (A), it is preferable to have a hydrogen-bonding hydrogen atom within 2 atoms (closer to the main chain).

Specific examples of the repeating unit represented by Formula (C) include the following repeating units.

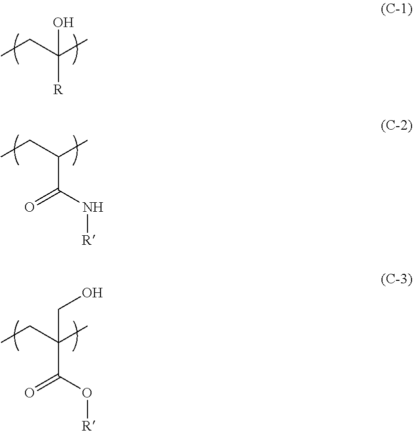

In the formula, R represents an organic group. The organic group may have a substituent, and examples thereof include an alkyl group, a cycloalkyl group, an aryl group, an aralkyl group, an alkenyl group, and an ester group (—OCOR or —COOR: R is an alkyl group or fluorinated alkyl group having 1 to 20 carbon atoms).

R′ represents a hydrogen atom or an organic group. Examples of the organic group include an organic group such as an alkyl group, a cycloalkyl group, an aryl group, an aralkyl group, and an alkenyl group. In addition, a hydrogen atom in the organic group may be substituted with a fluorine atom or an iodine atom.

(Repeating Unit Represented by Formula (D))

As an example of a specific unit for achieving (d) above, a method of introducing a repeating unit represented by Formula (D) into the resin (A) may be mentioned.

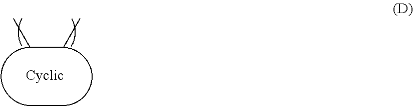

In Formula (D), “Cyclic” represents a group that forms a main chain with a cyclic structure. The number of ring-constituting atoms is not particularly limited.

Specific examples of the repeating unit represented by Formula (D) include the following repeating units.

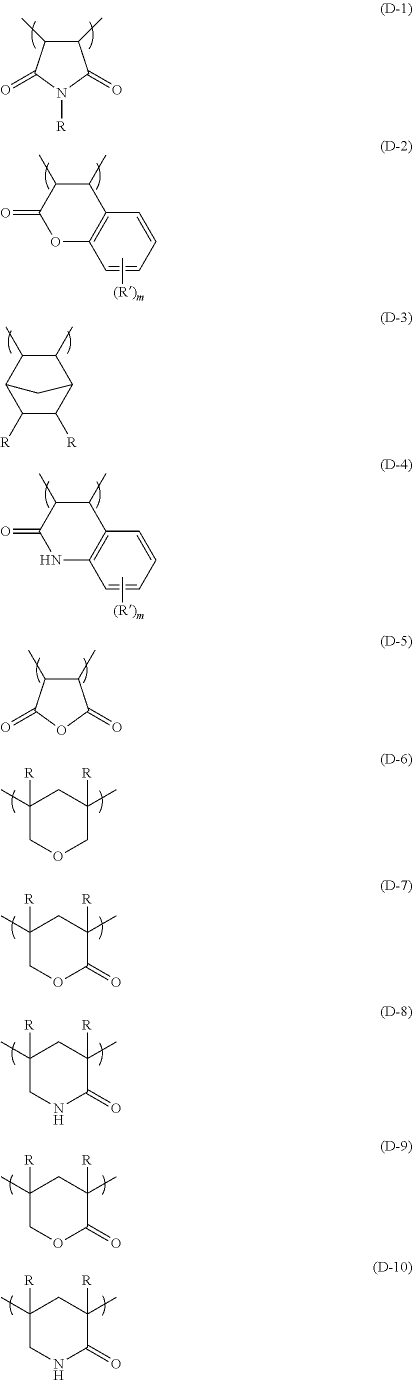

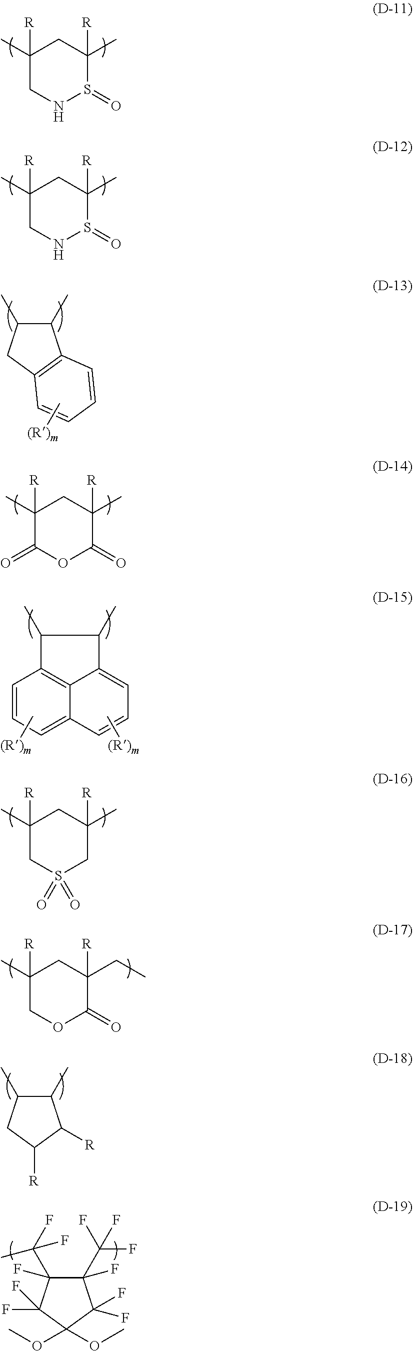

In the formula, R′s each independently represent a hydrogen atom, an alkyl group, a cycloalkyl group, an aryl group, an aralkyl group, an alkenyl group, a hydroxyl group, a hydroxyl group, an alkoxy group, an acyloxy group, a cyano group, a nitro group, an amino group, a halogen atom, an ester group (—OCOR″ or —COOR″: R″ is an alkyl group or fluorinated alkyl group having 1 to 20 carbon atoms), or a carboxyl group. Further, the alkyl group, the cycloalkyl group, the aryl group, the aralkyl group, and the alkenyl group may each have a substituent. Further, the hydrogen atom bonded to the carbon atom in the group represented by R may be substituted with a fluorine atom or an iodine atom.

In the formula, R″s each independently represent an alkyl group, a cycloalkyl group, an aryl group, an aralkyl group, an alkenyl group, a hydroxyl group, a hydroxyl group, an alkoxy group, an acyloxy group, a cyano group, a nitro group, an amino group, a halogen atom, an ester group (—OCOR″ or —COOR″: R″ is an alkyl group or fluorinated alkyl group having 1 to 20 carbon atoms), or a carboxyl group. Further, the alkyl group, the cycloalkyl group, the aryl group, the aralkyl group, and the alkenyl group may each have a substituent. Incidentally, a hydrogen atom bonded to the carbon atom in the group represented by R¹ may be substituted with a fluorine atom or an iodine atom.

m represents an integer of 0 or more. The upper limit of n is not particularly limited, but is 2 or less in many cases, and 1 or less in more cases.

(Repeating Unit Represented by Formula (E))

As an example of a specific unit for achieving (e) above, a method of introducing a repeating unit represented by Formula (E) into the resin (A) may be mentioned.

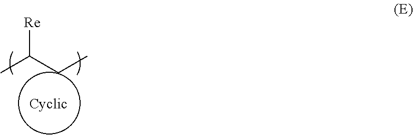

In Formula (E), Re's each independently represent a hydrogen atom or an organic group. Examples of the organic group include an alkyl group, a cycloalkyl group, an aryl group, an aralkyl group, and an alkenyl group, each of which may have a substituent.

The “Cyclic” is a cyclic group including a carbon atom of the main chain. The number of atoms included in the cyclic group is not particularly limited.

Specific examples of the repeating unit represented by Formula (E) include the following repeating units.

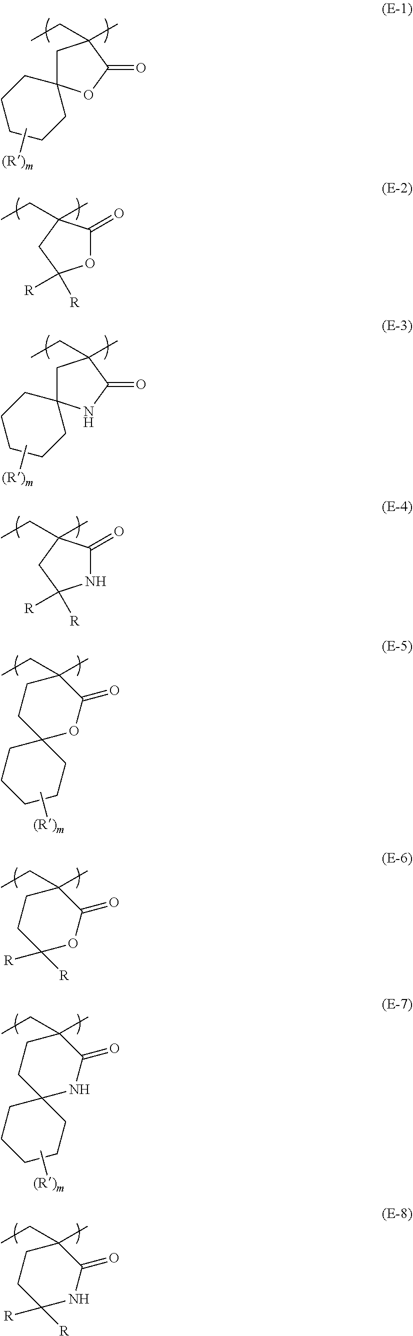

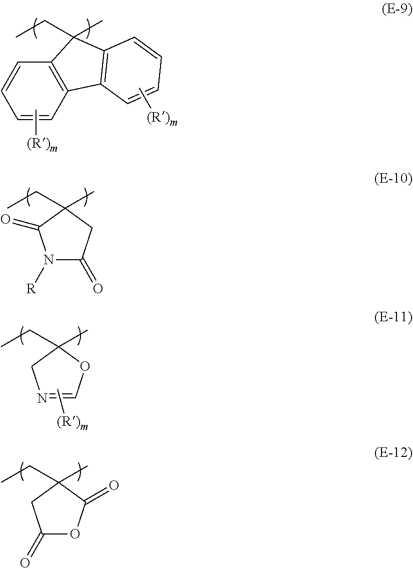

In the formula, R′s each independently represent a hydrogen atom, an alkyl group, a cycloalkyl group, an aryl group, an aralkyl group, an alkenyl group, a hydroxyl group, a hydroxyl group, an alkoxy group, an acyloxy group, a cyano group, a nitro group, an amino gr atom, an ester group (—OCOR″ or —COOR″: R″ is an alkyl group or fluorinated alkyl group having 1 to 20 carbon atoms), or a carboxyl group. Further, the alkyl group, the cycloalkyl group, the aryl group, the aralkyl group, and the alkenyl group may each have a substituent. Further, the hydrogen atom bonded to bonded to the carbon atom in the group represented by R may be substituted with a fluorine atom or an iodine atom.

R″s each independently represent a hydrogen atom, an alkyl group, a cycloalkyl group, an aryl group, an aralkyl group, an alkenyl group, a hydroxyl group, a hydroxyl group, an alkoxy group, an acyloxy group, a cyano group, a nitro group, an amino group, a halogen atom, an ester group (—OCOR″ or —COOR″: R″ is an alkyl group or fluorinated alkyl group having 1 to 20 carbon atoms), or a carboxyl group. Further, the alkyl group, the cycloalkyl group, the aryl group, the aralkyl group, and the alkenyl group may each have a substituent. Incidentally, a hydrogen atom bonded to the carbon atom in the group represented by R′ may be substituted with a fluorine atom or an iodine atom.

m represents an integer of 0 or more. The upper limit of n is not particularly limited, but is 2 or less in many cases, and 1 or less in more cases.

In addition, in Formula (E-2), Formula (E-4), Formula (E-6), and Formula (E-8), two R′s may be bonded to each other to form a ring.

(Repeating Unit Having at Least One Kind of Group Selected from Lactone Group, Hydroxyl Group, Cyano Group, and Alkali-Soluble Group)

The resin (A) may have a repeating unit having at least one kind of group selected from a lactone group, a hydroxyl group, a cyano group, and an alkali-soluble group.

Examples of the repeating unit having a lactone group contained in the resin (A) include the repeating unit described in (Repeating Unit Having Lactone Group) described above.

The resin (A) may have a repeating unit having a hydroxyl group or a cyano group. This improves adhesiveness to a substrate and affinity for a developer.

The repeating unit having a hydroxyl group or a cyano group is preferably a repeating unit having an alicyclic hydrocarbon structure substituted with a hydroxyl group or a cyano group.

The repeating unit having a hydroxyl group or a cyano group preferably has no acid-decomposable group. Examples of the repeating unit having a hydroxyl group or a cyano group include repeating units represented by Formulae (AIIa) to (AIId).

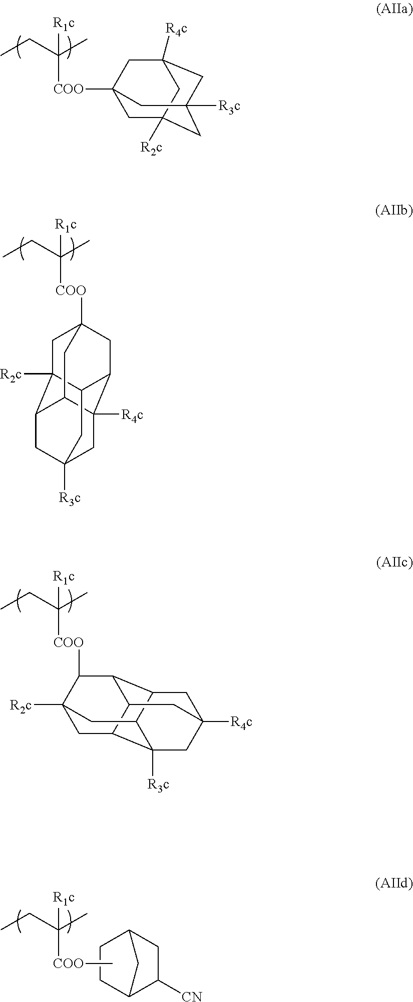

In Formulae (AIIa) to (AIId),

R_{1c} represents a hydrogen atom, a methyl group, a trifluoromethyl group, or a hydroxymethyl group.

R_{2c} to R_{4c} each independently represent a hydrogen atom, a hydroxyl group, or a cyano group. It should be noted that at least one of R_{2c}, . . . , or R_{4c} represents a hydroxyl group or a cyano group. Preferably, one or two of R_{2c} to R_{4c} are hydroxyl groups, and the rest are hydrogen atoms. More preferably, two of R_{2c} to R_{4c} are hydroxyl groups and the rest are hydrogen atoms.

The content of the repeating unit having a hydroxyl group or a cyano group is preferably 5% to 40% by mole, more preferably 5% to 30% by mole, and still more preferably 10% to 25% by mole, with respect to all the repeating units in the resin (A).

Specific examples of the repeating unit having a hydroxyl group or a cyano group are shown below, but the present invention is not limited thereto.

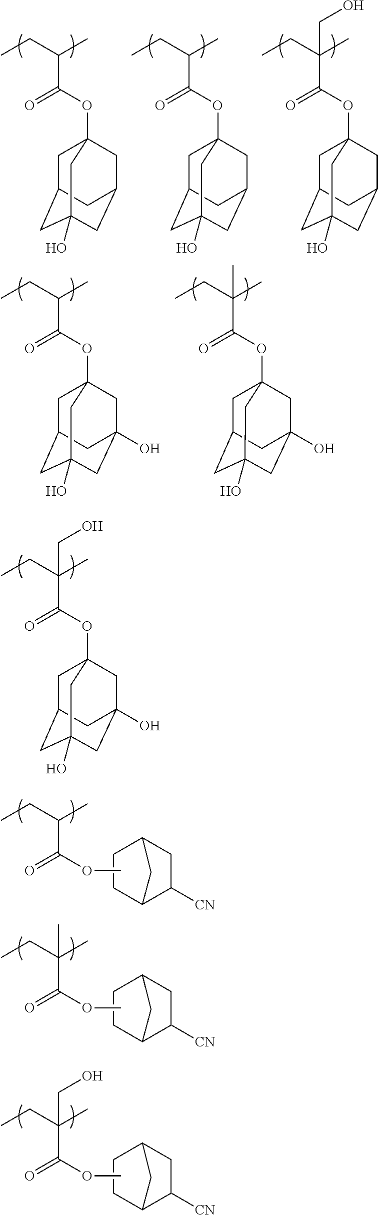

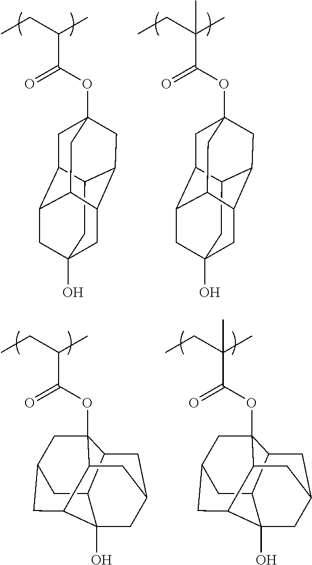

The resin (A) may have a repeating unit having an alkali-soluble group.

Examples of the alkali-soluble group include a carboxyl group, a sulfonamido group, a sulfonylimido group, a bisulsulfonylimido group, or an aliphatic alcohol in which the α-position is substituted with an electron-withdrawing group (for example, a hexafluoroisopropanol group), and the carboxyl group is preferable. In a case where the resin (A) includes a repeating unit having an alkali-soluble group, the resolution for use in contact holes is increased.

Examples of the repeating unit having an alkali-soluble group include a repeating unit in which an alkali-soluble group is directly linked to the main chain of a resin such as a repeating unit with acrylic acid and methacrylic acid, or a repeating unit in which an alkali-soluble group is directly linked to the main chain of the resin via a linking group. Further, the linking group may have a monocyclic or polycyclic cyclic hydrocarbon structure.

The repeating unit having an alkali-soluble group is preferably a repeating unit with acrylic acid or methacrylic acid.

The content of the repeating unit having an alkali-soluble group is preferably 0% to 20% by mole, more preferably 3% to 15% by mole, and still more preferably 5% to 10% by mole, with respect to all the repeating units in the resin (A).

Specific examples of the repeating unit having an alkali-soluble group are shown below, but the present invention is not limited thereto. In the specific examples, Rx represents H, CH₃, CH₂OH, or CF₃.

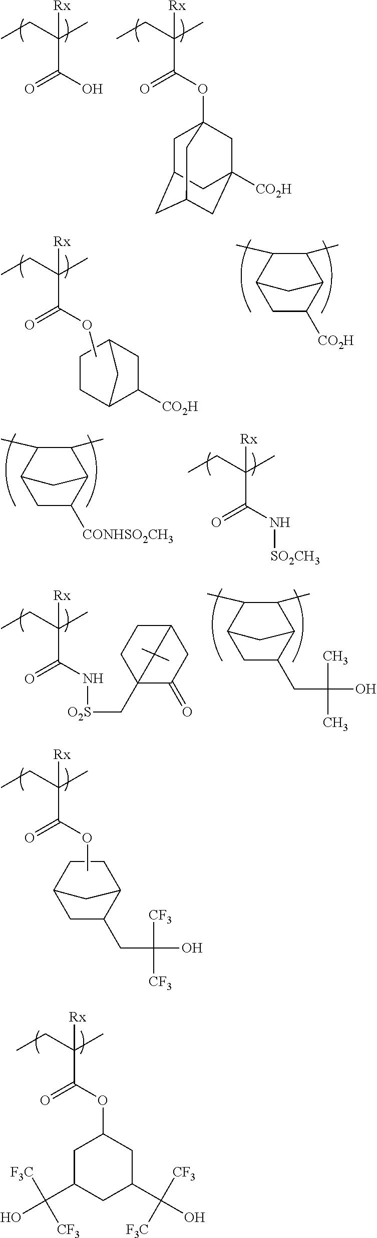

As the repeating unit having at least one kind of group selected from a lactone group, a hydroxyl group, a cyano group, or an alkali-soluble group, a repeating unit having at least two selected from a lactone group, a hydroxyl group, a cyano group, or an alkali-soluble group is preferable, a repeating unit having a cyano group and a lactone group is more preferable, and a repeating unit having a structure in which a cyano group is substituted in the lactone structure represented by Formula (LC1-4) is still more preferable.

(Repeating Unit Having Alicyclic Hydrocarbon Structure and not Exhibiting Acid Decomposability)

The resin (A) may have a repeating unit having an alicyclic hydrocarbon structure and not exhibiting acid decomposability. This can reduce the elution of low-molecular-weight components from the resist film into an immersion liquid during liquid immersion exposure. Examples of such the repeating unit include repeating units derived from 1-adamantyl (meth)acrylate, diamantyl (meth)acrylate, tricyclodecanyl (meth)acrylate, and cyclohexyl (meth)acrylate.

(Repeating Unit Represented by Formula (III) Having Neither Hydroxyl Group Nor Cyano Group)

The resin (A) may have a repeating unit represented by Formula (III), which has neither a hydroxyl group nor a cyano group.

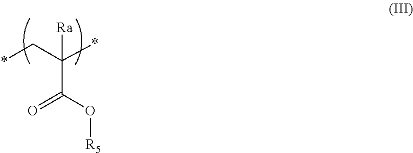

In Formula (III), R₅ represents a hydrocarbon group having at least one cyclic structure and having neither a hydroxyl group nor a cyano group.

Ra represents a hydrogen atom, an alkyl group, or a —CH₂—O—Ra₂ group. In the formula, Ra₂ represents a hydrogen atom, an alkyl group, or an acyl group.

The cyclic structure contained in R₅ includes a monocyclic hydrocarbon group and a polycyclic hydrocarbon group. Examples of the monocyclic hydrocarbon group include a cycloalkyl group having 3 to 12 carbon atoms (more preferably 3 to 7 carbon atoms) or a cycloalkenyl group having 3 to 12 carbon atoms.

Examples of the polycyclic hydrocarbon group include a ring-assembled hydrocarbon group and a crosslinked cyclic hydrocarbon group. Examples of the crosslinked cyclic hydrocarbon ring include a bicyclic hydrocarbon ring, a tricyclic hydrocarbon ring, and a tetracyclic hydrocarbon ring. Further, examples of the crosslinked cyclic hydrocarbon ring also include a fused ring formed by fusing a plurality of 5- to 8-membered cycloalkane rings. As the crosslinked cyclic hydrocarbon group, a norbornyl group, an adamantyl group, a bicyclooctanyl group, or a tricyclo[5,2,1,0^{2,6}]decanyl group is preferable, and the norbornyl group or the adamantyl group is more preferable.

The alicyclic hydrocarbon group may have a substituent, and examples of the substituent include a halogen atom, an alkyl group, a hydroxyl group protected with a protective group, and an amino group protected with a protective group.

The halogen atom is preferably a bromine atom, a chlorine atom, or a fluorine atom.

As the alkyl group, a methyl group, an ethyl group, a butyl group, or a t-butyl group is preferable. The alkyl group may further have a substituent, and examples of the substituent include a halogen atom, an alkyl group, a hydroxyl group protected with a protective group, and an amino group protected with a protective group.

Examples of the protective group include an alkyl group, a cycloalkyl group, an aralkyl group, a substituted methyl group, a substituted ethyl group, an alkoxycarbonyl group, and an aralkyloxycarbonyl group.

As the alkyl group, an alkyl group having 1 to 4 carbon atoms is preferable.

As the substituted methyl group, a methoxymethyl group, a methoxythiomethyl group, a benzyloxymethyl group, a t-butoxymethyl group, or a 2-methoxyethoxymethyl group is preferable.

The substituted ethyl group is preferably a 1-ethoxyethyl group or a 1-methyl-1-methoxyethylgroup.

As the acyl group, an aliphatic acyl group having 1 to 6 carbon atoms, such as a formyl group, an acetyl group, a propionyl group, a butyryl group, an isobutyryl group, a valeryl group, and a pivaloyl group, is preferable.

As the alkoxycarbonyl group, an alkoxycarbonyl group having 1 to 4 carbon atoms is preferable.

The content of the repeating unit represented by Formula (II), which has neither a hydroxyl group nor a cyano group, is preferably 0% to 40% by mole, and more preferably 0% to 20% by mole, with respect to all the repeating units in the resin (A).

Specific examples of the repeating unit represented by Formula (III) are shown below, but the present invention is not limited thereto. In the formulae, Ra represents H, CH₃, CH₂OH, or CF₃.

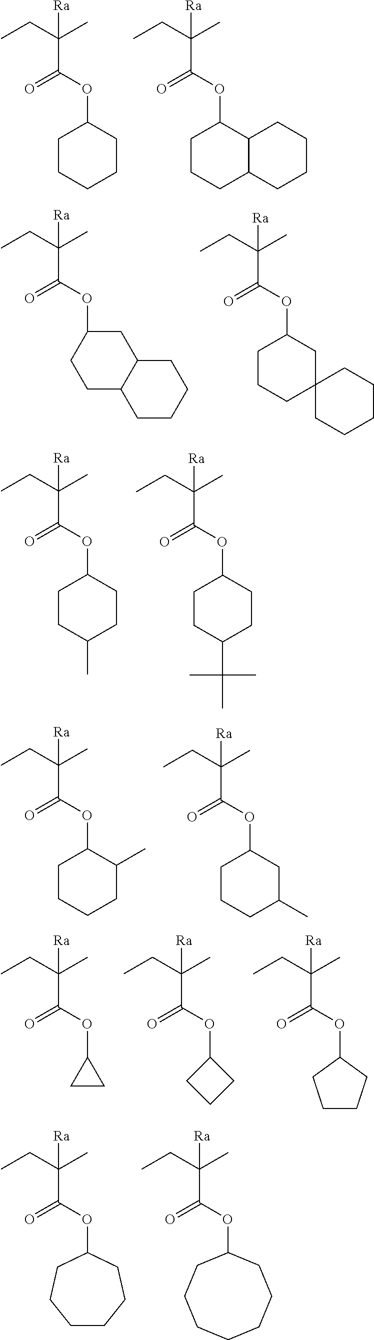

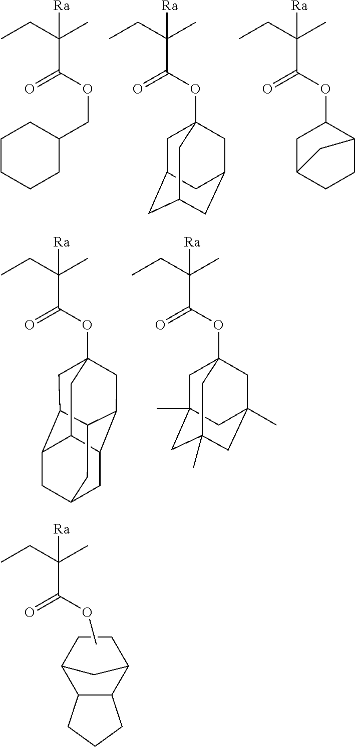

The resin (A) may have a variety of repeating structural units, in addition to the repeating structural units described above, for the purpose of adjusting dry etching resistance, suitability for a standard developer, adhesiveness to a substrate, a resist profile, resolving power, heat resistance, sensitivity, and the like.

In the resin (A), all the repeating units are preferably constituted with (meth)acrylate-based repeating units. In this case, any of a resin in which all of the repeating units are methacrylate-based repeating units, a resin in which all of the repeating units are acrylate-based repeating units, and a resin in which all of the repeating units are methacrylate-based repeating units and acrylate-based repeating unit scan be used, and it is preferable that the amount of the acrylate-based repeating units is 50% by mole or less with respect to all the repeating units.

The resin (A) can be synthesized in accordance with an ordinary method (for example, radical polymerization).

The weight-average molecular weight of the resin (A) as a value in terms of polystyrene by a GPC method is preferably 1,000 to 200,000, more preferably 3,000 to 20,000, and still more preferably 5,000 to 15,000. By setting the weight-average molecular weight of the resin (A) to 1,000 to 200,000, it is possible to prevent deterioration of heat resistance and dry etching resistance, and it is also possible to prevent deterioration of the film forming property due to deterioration of developability and an increase in viscosity.

The dispersity (molecular weight distribution) of the resin (A) is usually 1 to 5, preferably 1 to 3, more preferably 1.2 to 3.0, and still more preferably 1.2 to 2.0. The smaller the dispersity, the better the resolution and the resist shape, and the smoother the side wall of the resist pattern, the more excellent the roughness.

In the resist composition, the content of the resin (A) is preferably 50% to 99.9% by mass, and more preferably 60% to 99.0% by mass, with respect to the total solid content of the composition.

Furthermore, the resin (A) may be used singly or in combination of a plurality thereof.

<(B) Photoacid Generator>

The resist composition may include a photoacid generator.

The photoacid generator may be in a form of a low-molecular-weight compound or a form incorporated into a part of a polymer. Further, a combination of the form of a low-molecular-weight compound and the form incorporated into a part of a polymer may also be used.

In a case where the photoacid generator is in the form of a low-molecular-weight compound, the molecular weight is preferably 3,000 or less, more preferably 2,000 or less, and still more preferably 1,000 or less.

In a case where the photoacid generator is in the form incorporated into a part of a polymer, it may be incorporated into a part of the resin (A) or into a resin other than the resin (A).

The photoacid generator is preferably in the form of a low-molecular-weight compound.

The photoacid generator is not particularly limited as long as it is a known one, but a compound that generates an organic acid upon irradiation with EUV light is preferable, and a photoacid generator having a fluorine atom or an iodine atom in the molecule is more preferable.

Examples of the organic acid include sulfonic acids (aliphatic sulfonic acid, aromatic sulfonic acid, camphor sulfonic acid, and the like), carboxylic acids (aliphatic carboxylic acid, aromatic carboxylic acid, aralkyl carboxylic acid, and the like), carbonylsulfonylimide acid, bis(alkylsulfonyl)imide acid, and tris(alkylsulfonyl)methide acid.

The volume of an acid generated from the photoacid generator is not particularly limited, but from the viewpoint of suppressing the diffusion of the acid generated upon exposure into the non-exposed area and improving the resolution, the volume is preferably 240 Å³ or more, more preferably 305 Å³ or more, still more preferably 350 Å³ or more, and particularly preferably 400 Å³ or more. Incidentally, from the viewpoint of the sensitivity or the solubility in an application solvent, the volume of the acid generated from the photoacid generator is preferably 1,500 Å³ or less, more preferably 1,000 Å³ or less, and still more preferably 700 Å³ or less.

The value of the volume is obtained using “WinMOPAC” manufactured by Fujitsu Limited. In the calculation of the value of the volume, first, the chemical structure of the acid according to each example is input, next, using this structure as the initial structure, the most stable conformation of each acid is determined by molecular force field calculation using a Molecular Mechanics (MM) 3 method, and thereafter, with respect to the most stable conformation, molecular orbital calculation using a Parameterized Model number (PM) 3 method is performed, whereby the “accessible volume” of each acid can be computed.

The structure of the acid generated from the photoacid generator is not particularly limited, but from the viewpoints of suppressing the diffusion of an acid and improving the resolution, it is preferable that the interaction between the acid generated from the photoacid generator and the resin (A) is strong. From these viewpoints, in a case where the acid generated from the photoacid generator is an organic acid, it is preferable that a polar group is further contained, in addition to an organic acid group such as a sulfonic acid group, a carboxylic acid group, a carbonylsulfonylimide acid group, a bissulfonylimide acid group, and a trissulfonylmethide acid group.

Examples of the polar group include an ether group, an ester group, an amido group, an acyl group, a sulfo group, a sulfonyloxy group, a sulfonamido group, a thioether group, a thioester group, a urea group, carbonate group, a carbamate group, a hydroxyl group, and a mercapto group.

The number of the polar groups contained in the generated acid is not particularly limited, and is preferably 1 or more, and more preferably 2 or more. It should be noted that from the viewpoint of suppressing excessive development, the number of the polar groups is preferably less than 6, and more preferably less than 4.

As the photoacid generator, the photoacid generators that generate the following acids are preferable. In addition, the calculated value of the volume is added to some of the examples (unit: Å³).

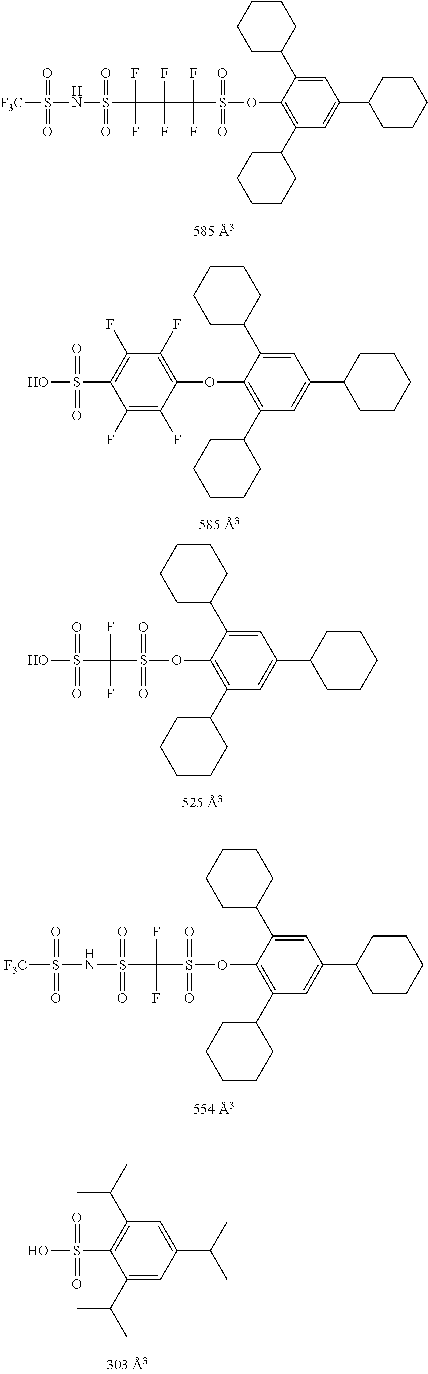 [SMILES: O=S(=O)(NS(=O)(=O)C(F)(F)C(F)(F)C(F)(F)S(=O)(=O)Oc1c(C2CCCCC2)cc(C2CCCCC2)cc1C1CCCCC1)C(F)(F)F ; O=S(=O)(O)c1c(F)c(F)c(Oc2c(C3CCCCC3)cc(C3CCCCC3)cc2C2CCCCC2)c(F)c1F ; O=S(=O)(O)C(F)(F)S(=O)(=O)Oc1c(C2CCCCC2)cc(C2CCCCC2)cc1C1CCCCC1 ; O=S(=O)(NS(=O)(=O)C(F)(F)S(=O)(=O)Oc1c(C2CCCCC2)cc(C2CCCCC2)cc1C1CCCCC1)C(F)(F)F ; CC(C)c1cc(C(C)C)c(S(=O)(=O)O)c(C(C)C)c1]

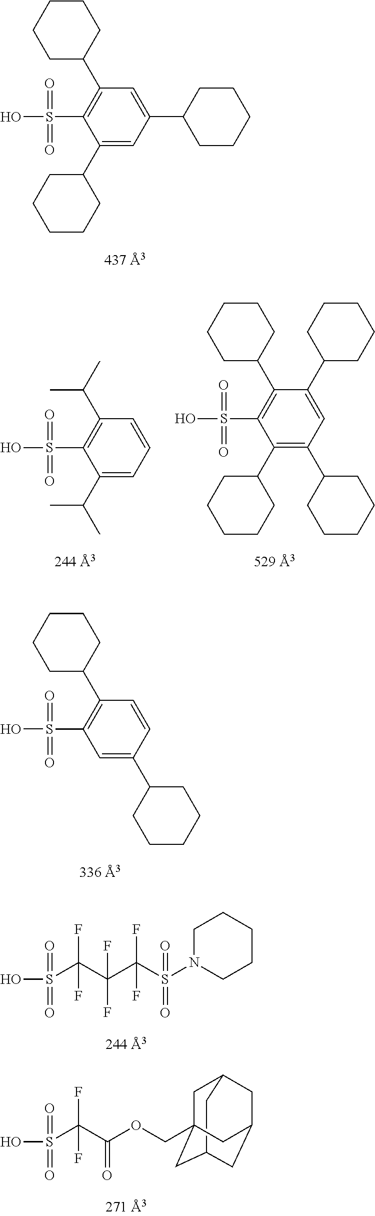 [SMILES: O=S(=O)(O)c1c(C2CCCCC2)cc(C2CCCCC2)cc1C1CCCCC1 ; CC(C)c1cccc(C(C)C)c1S(=O)(=O)O ; O=S(=O)(O)c1c(C2CCCCC2)c(C2CCCCC2)cc(C2CCCCC2)c1C1CCCCC1 ; O=S(=O)(O)c1cc(C2CCCCC2)ccc1C1CCCCC1 ; O=S(=O)(O)C(F)(F)C(F)(F)C(F)(F)S(=O)(=O)N1CCCCC1 ; O=C(OCC12CC3CC(CC(C3)C1)C2)C(F)(F)S(=O)(=O)O]

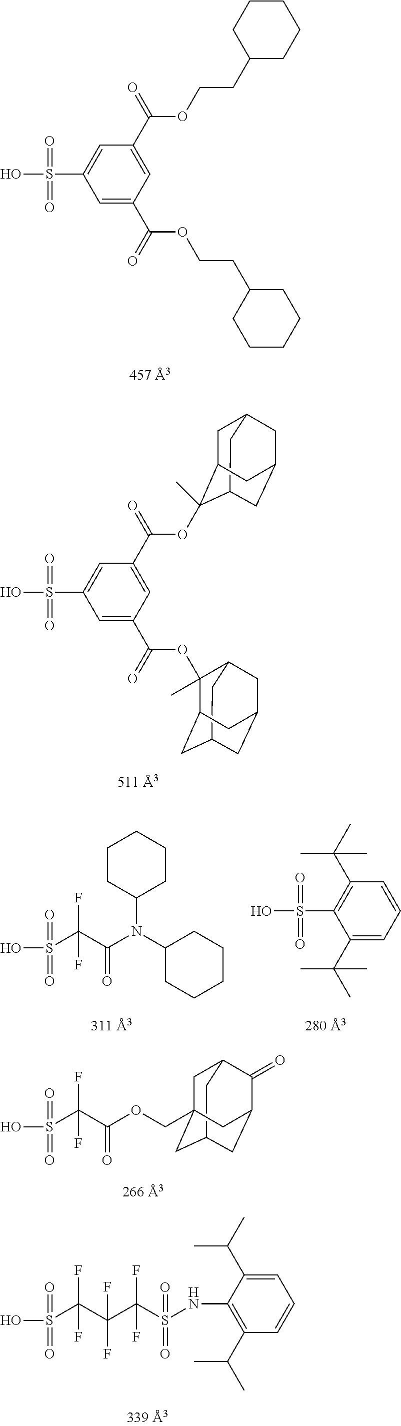 [SMILES: O=C(OCCC1CCCCC1)c1cc(C(=O)OCCC2CCCCC2)cc(S(=O)(=O)O)c1 ; CC1(OC(=O)c2cc(C(=O)OC3(C)C4CC5CC(C4)CC3C5)cc(S(=O)(=O)O)c2)C2CC3CC(C2)CC1C3 ; O=C(N(C1CCCCC1)C1CCCCC1)C(F)(F)S(=O)(=O)O ; CC(C)(C)c1cccc(C(C)(C)C)c1S(=O)(=O)O ; O=C1C2CC3CC1CC(COC(=O)C(F)(F)S(=O)(=O)O)(C3)C2 ; CC(C)c1cccc(C(C)C)c1NS(=O)(=O)C(F)(F)C(F)(F)C(F)(F)S(=O)(=O)O]

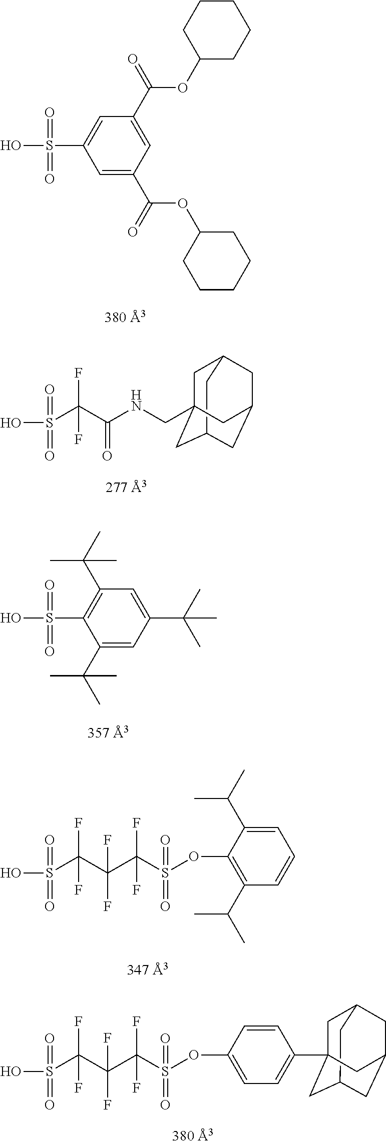 [SMILES: O=C(OC1CCCCC1)c1cc(C(=O)OC2CCCCC2)cc(S(=O)(=O)O)c1 ; O=C(NCC12CC3CC(CC(C3)C1)C2)C(F)(F)S(=O)(=O)O ; CC(C)(C)c1cc(C(C)(C)C)c(S(=O)(=O)O)c(C(C)(C)C)c1 ; CC(C)c1cccc(C(C)C)c1OS(=O)(=O)C(F)(F)C(F)(F)C(F)(F)S(=O)(=O)O ; O=S(=O)(O)C(F)(F)C(F)(F)C(F)(F)S(=O)(=O)Oc1ccc(C23CC4CC(CC(C4)C2)C3)cc1]

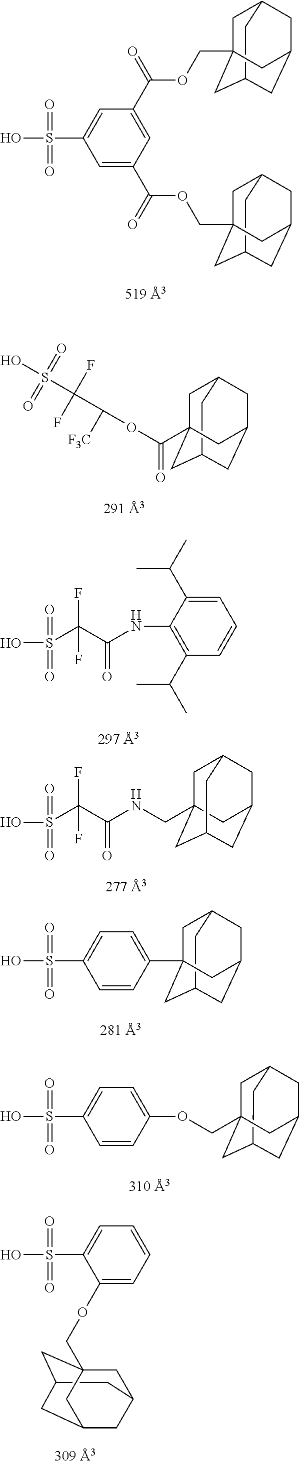

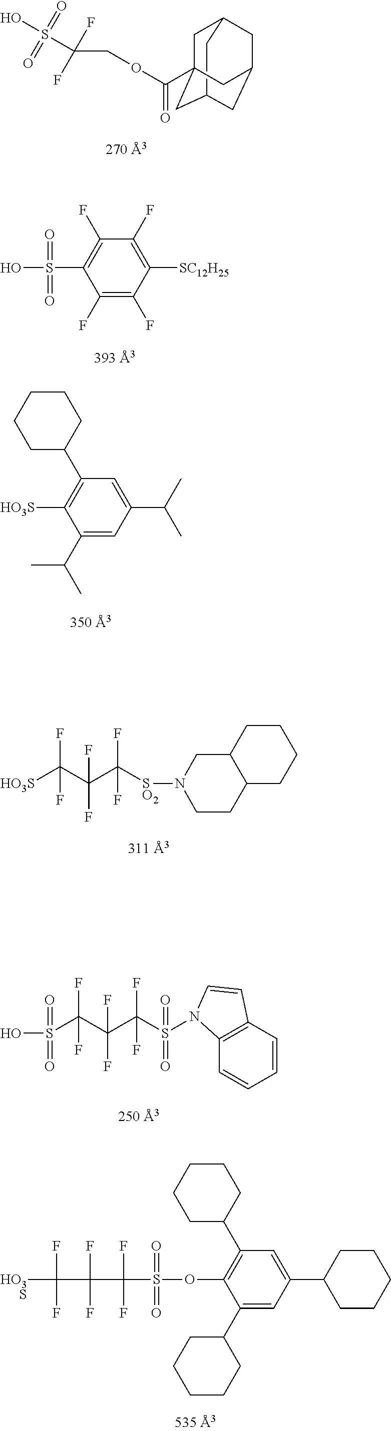

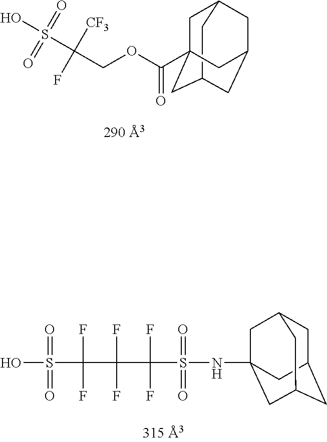 [SMILES: O=C(OCC(F)(C(F)(F)F)S(=O)(=O)O)C12CC3CC(CC(C3)C1)C2 ; O=S(=O)(O)C(F)(F)C(F)(F)C(F)(F)S(=O)(=O)NC12CC3CC(CC(C3)C1)C2]

Among those, the photoacid generator is preferably a photoacid generator consisting of an anionic moiety and a cationic moiety from the viewpoint that the effects of the present invention are more excellent.

More specifically, the photoacid generator is preferably a compound represented by Formula (ZI) or a compound represented by Formula (ZII).

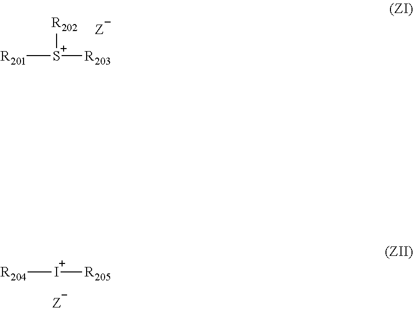

In Formula (ZI),

R₂₀₁, R₂₀₂, and R₂₀₃ each independently represent an organic group.

The organic group as each of R₂₀₁, R₂₀₂, and R₂₀₃ preferably has 1 to 30 carbon atoms, and more preferably has 1 to 20 carbon atoms.

In addition, two of R₂₀₁ to R₂₀₃ may be bonded to each other to form a ring structure, and the ring may include an oxygen atom, a sulfur atom, an ester bond, an amide bond, or a carbonyl group. Examples of the group formed by the bonding of two of R₂₀₁ to R₂₀₃ include an alkylene group (for example, a butylene group and a pentylene group).

Z⁻ represents a non-nucleophilic anion (anion having a remarkably low ability to cause a nucleophilic reaction).

Examples of the non-nucleophilic anion include a sulfonate anion (an aliphatic sulfonate anion, an aromatic sulfonate anion, a camphor sulfonate anion, and the like), a carboxylate anion (an aliphatic carboxylate anion, an aromatic carboxylate anion, an aralkyl carboxylate anion, and the like), a sulfonylimide anion, a bis(alkylsulfonyl)imide anion, and a tris(alkylsulfonyl)methide anion.

The aliphatic moiety in each of the aliphatic sulfonate anion and the aliphatic carboxylate anion may be an alkyl group or a cycloalkyl group, and is preferably a linear or branched alkyl group having 1 to 30 carbon atoms or a cycloalkyl group having 3 to 30 carbon atoms.

As the aromatic ring group in the aromatic sulfonate anion and the aromatic carboxylate anion, an aryl group having 6 to 14 carbon atoms is preferable, and examples thereof include a phenyl group, a tolyl group, and a naphthyl group.

Specific examples of the substituent which may be contained in the alkyl group, the cycloalkyl group, and the aryl group exemplified above include a nitro group, a halogen atom such as fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms).

As the aralkyl group in the aralkyl carboxylate anion, an aralkyl group having 7 to 12 carbon atoms is preferable, and examples thereof include a benzyl group, a phenethyl group, a naphthylmethyl group, a naphthylethyl group, and a naphthylbutyl group.

Examples of the sulfonylimide anion include a saccharin anion.

As the alkyl group in the bis(alkylsulfonyl)imide anion and the tris(alkylsulfonyl)methide anion, an alkyl group having 1 to 5 carbon atoms is preferable. Examples of the substituent of the alkyl group include a halogen atom, an alkyl group substituted with a halogen atom, an alkoxy group, an alkylthio group, an alkyloxysulfonyl group, an aryloxysulfonyl group, and a cycloalkylaryloxysulfonyl group, and the fluorine atom or the alkyl group substituted with a fluorine atom is preferable.

In addition, the alkyl groups in the bis(alkylsulfonyl)imide anion may be bonded to each other to form a ring structure. Thus, the acid strength is increased.

Other examples of the non-nucleophilic anion include fluorinated phosphorus (for example, PF₆⁻), fluorinated boron (for example, BF₄⁻), and fluorinated antimony (for example, SbF₆⁻).

As the non-nucleophilic anion, an aliphatic sulfonate anion substituted with a fluorine atom at least at the α-position of the sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom is preferable. Among those, a perfluoroaliphatic sulfonate anion (more preferably having 4 to 8 carbon atoms) or a fluorine atom-containing benzenesulfonate anion is more preferable, and a nonafluorobutanesulfonate anion, a perfluorooctanesulfonate anion, a pentafluorobenzenesulfonate anion, or a 3,5-bis(trifluoromethyl)benzenesulfonate anion is still more preferable.

Furthermore, it is preferable that the pKa of an acid generated is −1 or less so as to improve the sensitivity.

Moreover, as the non-nucleophilic anion, an anion represented by Formula (AN1) is also preferable.

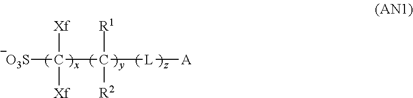

In the formulae,

Xf's each independently represent a fluorine atom or an alkyl group substituted with at least one fluorine atom.

R¹ and R² each independently represent a hydrogen atom, a fluorine atom, or an alkyl group, and in a case where a plurality of R¹'s and R²'s are present, R¹'s and R²'s may be the same as or different from each other.

L represents a divalent linking group, and in a case where a plurality of L's are present, L's may be the same as or different from each other.

A represents a cyclic organic group.

x represents an integer of 1 or 20, y represents an integer of 0 to 10, and z represents an integer of 0 to 10.

Formula (AN1) will be described in more detail.

The number of carbon atoms of the alkyl group in the alkyl group substituted with a fluorine atom of Xf is preferably 1 to 10, and more preferably 1 to 4. In addition, a perfluoroalkyl group is preferable as the alkyl group substituted with a fluorine atom of Xf.

Xf is preferably a fluorine atom or a perfluoroalkyl group having 1 to 4 carbon atoms. Specific examples of Xf include a fluorine atom, CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, the fluorine atom or CF₃ is preferable. In particular, it is preferable that both Xf's are fluorine atoms.

The alkyl group of each of R¹ and R² may have a substituent (preferably a fluorine atom), and the number of carbon atoms in the substituent is preferably 1 to 4. As the substituent, a perfluoroalkyl group having 1 to 4 carbon atoms is preferable. Specific examples of the alkyl group of each of R¹ and R² include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, CF₃ is preferable.

As each of R¹ and R², a fluorine atom or CF₃ is preferable.

x is preferably an integer of 1 to 10, and more preferably 1 to 5.

y is preferably an integer of 0 to 4, and more preferably 0.

z is preferably an integer of 0 to 5, and more preferably an integer of 0 to 3.

The divalent linking group of L is not particularly limited, examples thereof include —COO—, —CO—, —O—, —S—, —SO—, —SO₂—, an alkylene group, a cycloalkylene group, an alkenylene group, and a linking group obtained by linking a plurality of these groups to each other, and the linking group having 12 or less carbon atoms in total is preferable. Among those, —COO—, —OCO—, —CO—, or —O— is preferable, and —COO— or —OCO— is more preferable.

The cyclic organic group of A is not particularly limited as long as it has a cyclic structure, and examples thereof include an alicyclic group, an aromatic ring group, and a heterocyclic group (including not only an aromatic heterocyclic group but also a non-aromatic heterocyclic group).

The alicyclic group may be either a monocycle or a polycycle, and is preferably a monocyclic cycloalkyl group such as a cyclopentyl group, a cyclohexyl group, and a cyclooctyl group, or a polycyclic cycloalkyl group such as a norbornyl group, a tricyclodecanyl group, a tetracyclodecanyl group, a tetracyclododecanyl group, and an adamantyl group. Among those, an alicyclic group with a bulky structure, having 7 or more carbon atoms, such as a norbornyl group, a tricyclodecanyl group, a tetracyclodecanyl group, a tetracyclododecanyl group, and an adamantyl group is preferable from the viewpoints the in-film diffusion in a post-exposure heating step can be suppressed and a mask error enhancement factor (MEEF) is improved.

Examples of the aromatic ring group include a benzene ring, a naphthalene ring, a phenanthrene ring, and an anthracene ring.

Examples of the heterocyclic group include a group derived from a furan ring, a thiophene ring, a benzofuran ring, a benzothiophene ring, a dibenzofuran ring, a dibenzothiophene ring, a pyridine ring, or the like. Among those, groups derived from a furan ring, a thiophene ring, and a pyridine ring are preferable.

The cyclic organic group also includes a group having a lactone structure, and specific examples thereof include groups having a lactone structure represented by Formulae (LC1-1) to (LC1-17).

The cyclic organic group may have a substituent. Examples of the substituent include an alkyl group (which may be linear, branched, or cyclic, and preferably has 1 to 12 carbon atoms), a cycloalkyl group (which may be either a monocycle or a polycycle, in a case where the cycloalkyl group is the polycycle, it may be a spiro ring, and preferably has 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic acid ester group. Incidentally, the carbon constituting the cyclic organic group (carbon contributing to ring formation) may be carbonyl carbon.

Examples of the organic group of each of R₂₀₁, R₂₀₂, and R₂₀₃ include an aryl group, an alkyl group, and a cycloalkyl group.

It is preferable that at least one of R₂₀₁, R₂₀₂, or R₂₀₃ is the aryl group, and it is more preferable that all three are aryl groups. Examples of the aryl group include, in addition to a phenyl group and a naphthyl group, a heteroaryl group such as an indole residue and a pyrrole residue.

As the alkyl group of each of R₂₀₁ to R₂₀₃, a linear or branched alkyl group having 1 to 10 carbon atoms is preferable, and a methyl group, an ethyl group, an n-propyl group, an i-propyl group, an n-butyl group, or the like is more preferable.

As the cycloalkyl group of each of R₂₀₁ to R₂₀₃ a cycloalkyl group having 3 to 10 carbon atoms is preferable, and a cyclopropyl group, a cyclobutyl group, a cyclopentyl group, a cyclohexyl group, or a cycloheptyl group is more preferable.

The substituent which may be contained in these groups include a nitro group, a halogen atom such as a fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), and an alkoxycarbonyloxy group (preferably having 2 to 7 carbon atoms).

In Formula (ZII),

R₂₀₄ to R₂₀₅ each independently represent an aryl group, an alkyl group, or a cycloalkyl group.

The aryl group, the alkyl group, and the cycloalkyl group of each of R₂₀₄ and R₂₀₅ are the same as the above-mentioned groups as the aryl group, the alkyl group, and the cycloalkyl group of each of R₂₀₁ to R₂₀₃ in Formula (ZI).

Examples of the substituent which may be contained in each of the aryl group, the alkyl group, and the cycloalkyl group of each of R₂₀₄ and R₂₀₅ include the same ones which may be contained in the above-mentioned groups as the aryl group, the alkyl group, and the cycloalkyl group of each of R₂₀₁ to R₂₀₃ in the above-mentioned compound (ZI).

Z⁻ represents a non-nucleophilic anion, and examples thereof include the same non-nucleophilic anions as Z⁻ in Formula (ZI).

As the photoacid generator, reference can be made to paragraphs [0368] to [0377] of JP2014-041328A and paragraphs [0240] to [0262] of JP2013-228681A (corresponding to paragraph [0339] of US2015/0004533 Å), the contents of which are incorporated herein by reference. In addition, specific preferred examples of the photoacid generator include, but are not limited to, the following compounds.

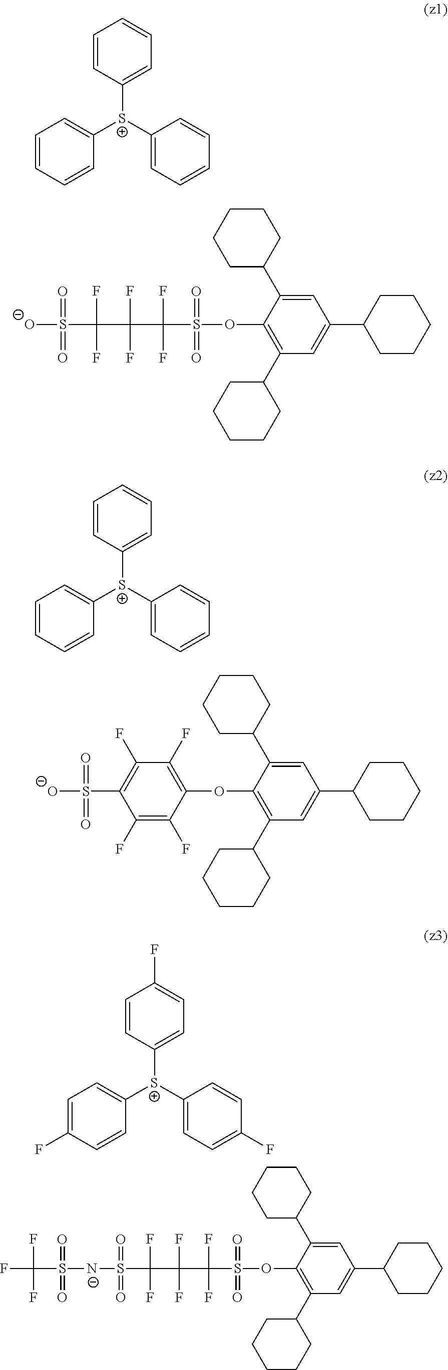 [SMILES: c1ccc([S+](c2ccccc2)c2ccccc2)cc1 ; O=S(=O)([O-])C(F)(F)C(F)(F)C(F)(F)S(=O)(=O)Oc1c(C2CCCCC2)cc(C2CCCCC2)cc1C1CCCCC1 ; c1ccc([S+](c2ccccc2)c2ccccc2)cc1 ; O=S(=O)([O-])c1c(F)c(F)c(Oc2c(C3CCCCC3)cc(C3CCCCC3)cc2C2CCCCC2)c(F)c1F ; Fc1ccc([S+](c2ccc(F)cc2)c2ccc(F)cc2)cc1 ; O=S(=O)([N-]S(=O)(=O)C(F)(F)C(F)(F)C(F)(F)S(=O)(=O)Oc1c(C2CCCCC2)cc(C2CCCCC2)cc1C1CCCCC1)C(F)(F)F]

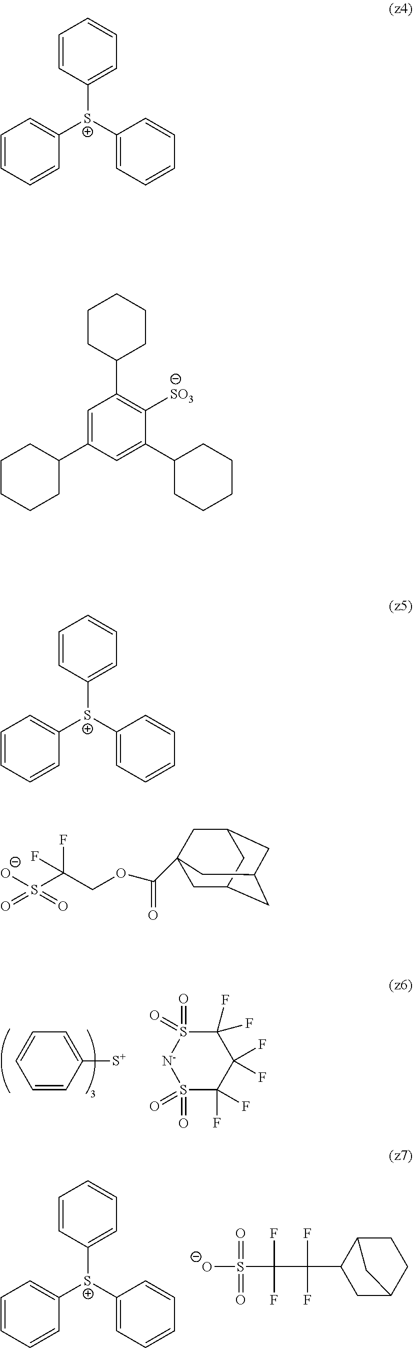

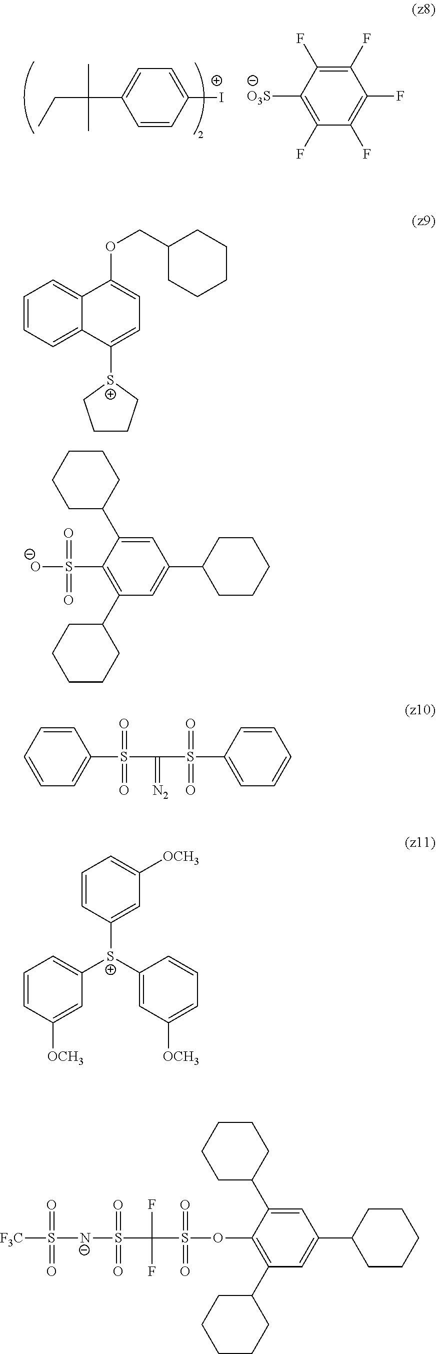

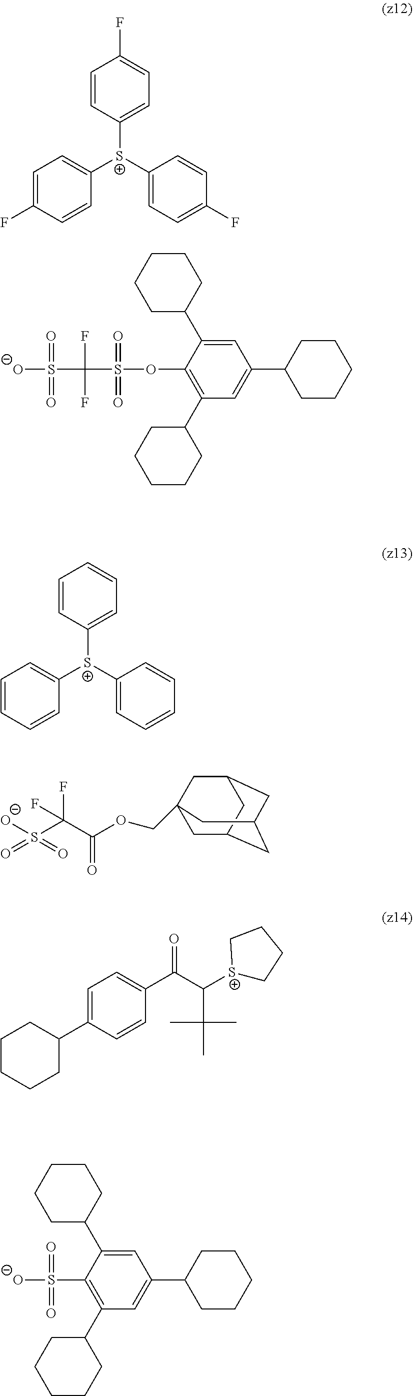 [SMILES: Fc1ccc([S+](c2ccc(F)cc2)c2ccc(F)cc2)cc1 ; O=S(=O)([O-])C(F)(F)S(=O)(=O)Oc1c(C2CCCCC2)cc(C2CCCCC2)cc1C1CCCCC1 ; c1ccc([S+](c2ccccc2)c2ccccc2)cc1 ; O=C(OCC12CC3CC(CC(C3)C1)C2)C(F)(F)S(=O)(=O)[O-] ; CC(C)(C)C(C(=O)c1ccc(C2CCCCC2)cc1)[S+]1CCCC1 ; O=S(=O)([O-])c1c(C2CCCCC2)cc(C2CCCCC2)cc1C1CCCCC1]

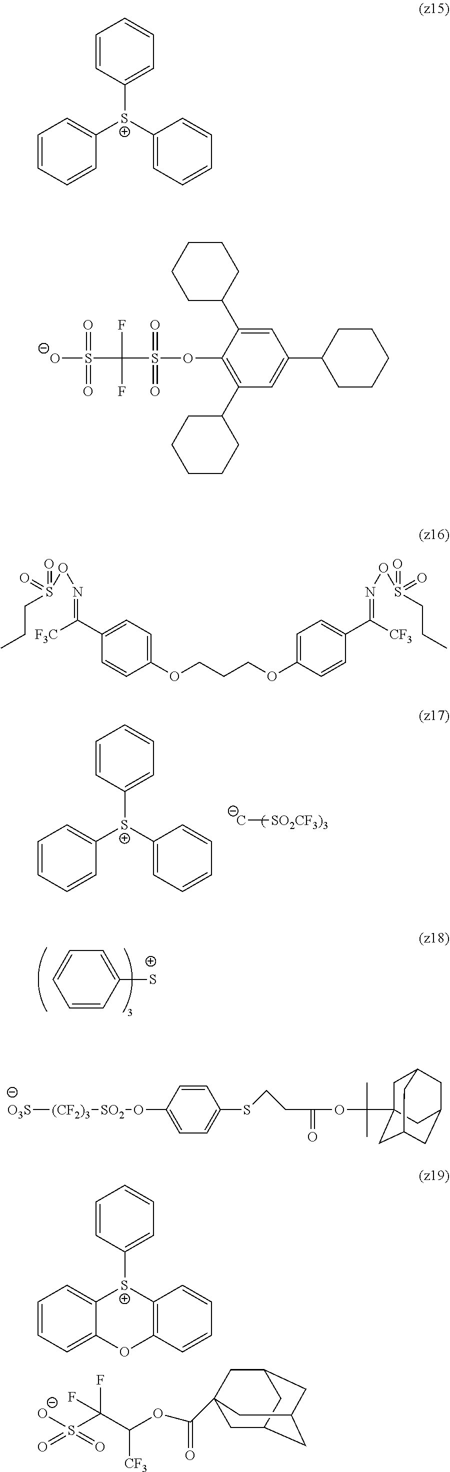

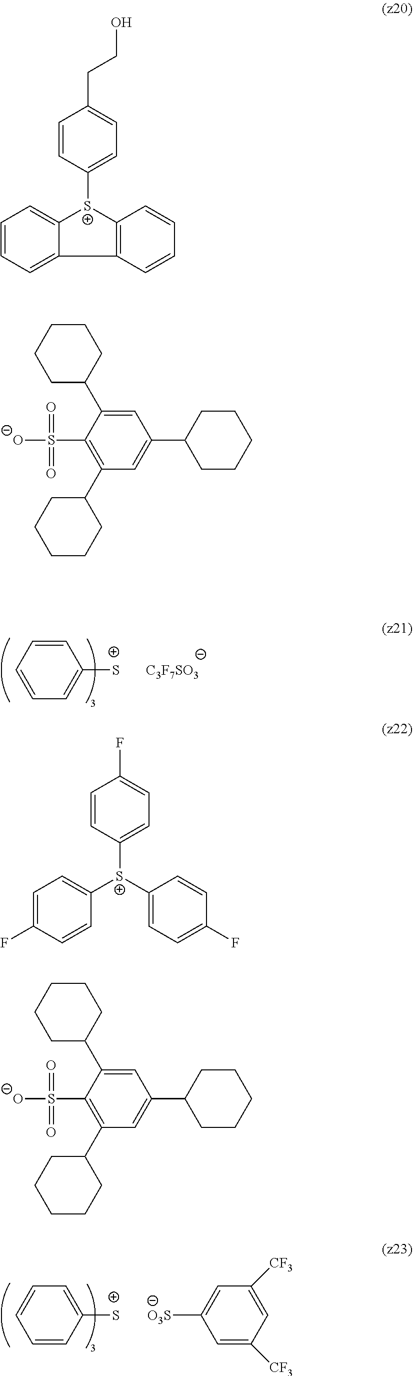

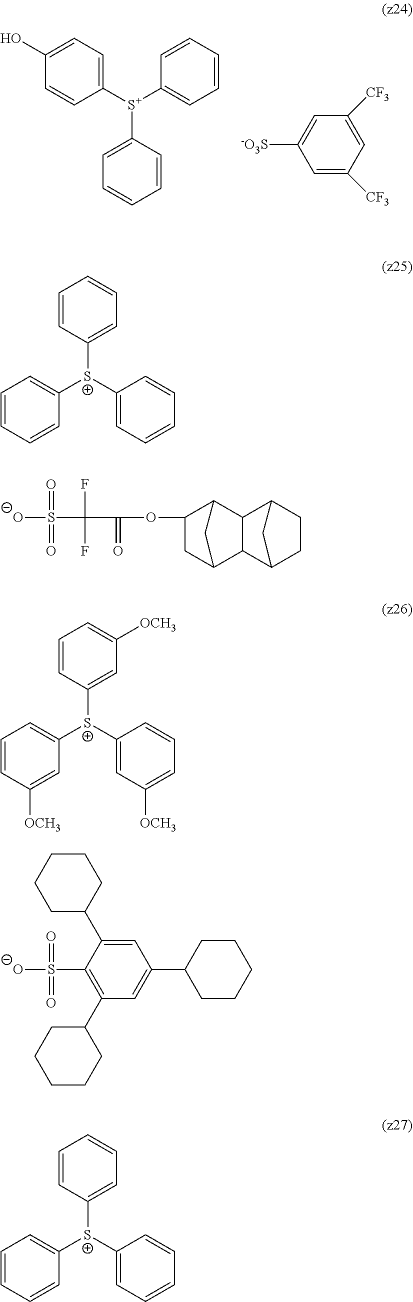

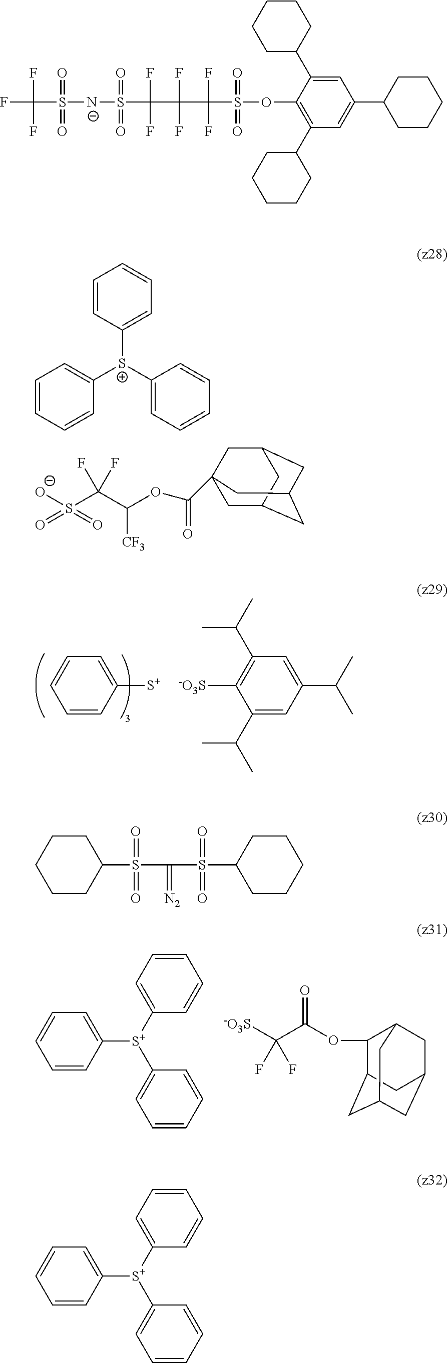

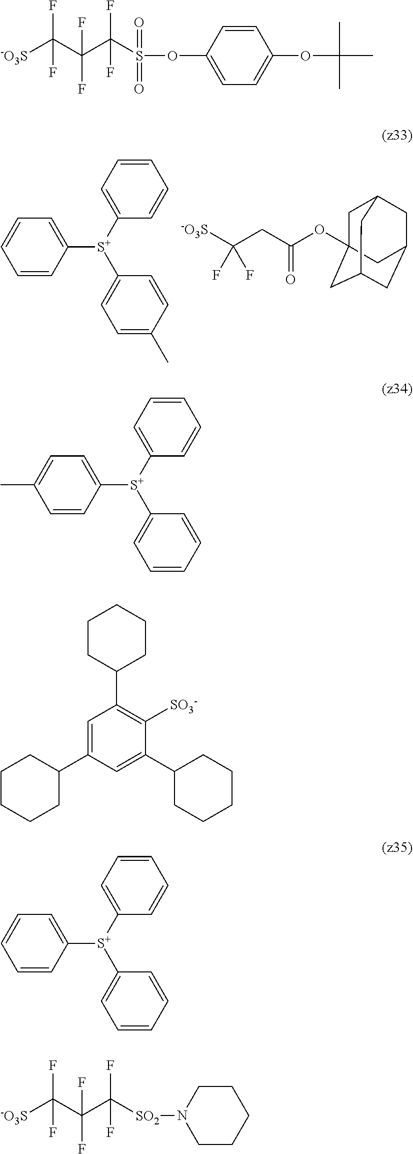

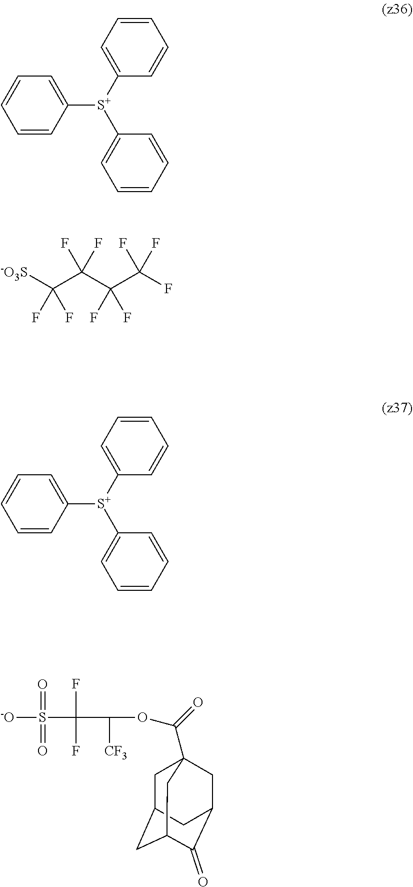

The content of the photoacid generator in the resist composition is not particularly limited, but from the viewpoint that the effects of the present invention are more excellent, the content is preferably 5% to 50% by mass, more preferably 10% to 40% by mass, and still more preferably 10% to 35% by mass, with respect to the total solid content of the composition. The photoacid generators may be used singly or in combination of two or more kinds thereof. In a case where two or more kinds of the photoacid generators are used in combination, the total amount thereof is preferably within the range.

<(C) Solvent>

The resist composition may include a solvent.

In a case where the resist composition is an actinic ray-sensitive or radiation-sensitive resin composition for EUV, it is preferable that the solvent includes at least one solvent of (M1) propylene glycol monoalkyl ether carboxylate or (M2) at least one selected from the group consisting of a propylene glycol monoalkyl ether, a lactic acid ester, an acetic acid ester, an alkoxypropionic acid ester, a chain ketone, a cyclic ketone, a lactone, and an alkylene carbonate as the solvent. In addition, the solvent may further include components other than the components (M1) and (M2).

The present inventors have found that by using such a solvent and the above-mentioned resin (A) in combination, a pattern having a small number of development defects can be formed while improving the coating property of the composition. A reason therefor is not necessarily clear, but the present inventors have considered that since these solvents have a good balance among the solubility, the boiling point, and the viscosity of the resin (A), the unevenness of the film thickness of a composition film, the generation of precipitates during spin coating, and the like can be suppressed.

As the component (M1), at least one selected from the group consisting of propylene glycol monomethyl ether acetate (PGMEA), propylene glycol monomethyl ether propionate, and propylene glycol monoethyl ether acetate is preferable, and propylene glycol monomethyl ether acetate (PGMEA) is more preferable.

As the component (M2), the following ones are preferable.

As the propylene glycol monoalkyl ether, propylene glycol monomethyl ether (PGME) or propylene glycol monoethyl ether is preferable.

As the lactic acid ester, preferably ethyl lactate, butyl lactate, or propyl lactate is preferable.

As the acetic acid ester, methyl acetate, ethyl acetate, butyl acetate, isobutyl acetate, propyl acetate, isoamyl acetate, methyl formate, ethyl formate, butyl formate, propyl formate, or 3-methoxybutyl acetate is preferable.

In addition, butyl butyrate is also preferable.

As the alkoxypropionic acid ester, methyl 3-methoxypropionate (MMP) or ethyl 3-ethoxypropionate (EEP) is preferable.

As the chain ketone, 1-octanone, 2-octanone, 1-nonanone, 2-nonanone, acetone, 2-heptanone, 4-heptanone, 1-hexanone, 2-hexanone, diisobutyl ketone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, or methyl amyl ketone is preferable.

As the cyclic ketone, methyl cyclohexanone, isophorone, or cyclohexanone is preferable.

As the lactone, γ-butyrolactone is preferable.

As the alkylene carbonate, propylene carbonate is preferable.

As the component (M2), propylene glycol monomethyl ether (PGME), ethyl lactate, ethyl 3-ethoxypropionate, methyl amyl ketone, cyclohexanone, butyl acetate, pentyl acetate, γ-butyrolactone, or propylene carbonate is more preferable.

In addition to the components, it is preferable to use an ester-based solvent having 7 or more carbon atoms (preferably 7 to 14 carbon atoms, more preferably 7 to 12 carbon atoms, and still more preferably 7 to 10 carbon atoms) and 2 or less heteroatoms.

As the ester-based solvent having 7 or more carbon atoms and 2 or less heteroatoms, amyl acetate, 2-methylbutyl acetate, 1-methylbutyl acetate, hexyl acetate, pentyl propionate, hexyl propionate, butyl propionate, isobutyl isobutyrate, heptyl propionate, or butyl butanoate is preferable, and isoamyl acetate is more preferable.

As the component (M2), a component having a flash point (hereinafter also referred to as fp) of 37° C. or higher is preferably used. As such a component (M2), propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 44° C.), pentyl acetate (fp: 45° C.), methyl 2-hydroxyisobutyrate (fp: 45° C.), γ-butyrolactone (fp: 101° C.), or propylene carbonate (fp: 132° C.) is preferable. Among those, propylene glycol monoethyl ether, ethyl lactate, pentyl acetate, or cyclohexanone is more preferable, and propylene glycol monoethyl ether or ethyl lactate is still more preferable.

In addition, the “flash point” herein is intended to mean the value described in a reagent catalog of Tokyo Chemical Industry Co., Ltd. or Sigma-Aldrich Co. LLC.

It is preferable that the solvent includes the component (M1). It is more preferable that the solvent is formed of substantially only the component (M1) or is a mixed solvent formed from the component (M1) and other components. In the latter case, it is still more preferable that the solvent includes both the component (M1) and the component (M2).

The mass ratio (M1/M2) of the content of the component (M1) to the component (M2) is preferably in the range of “100/0” to “15/85”, more preferably in the range of “100/0” to “40/60”, and still more preferably in the range of “100/0” to “60/40”. That is, the solvent includes only the component (M1) or includes both of the component (M1) and the component (M2), and a mass ratio thereof is preferably as follows. That is, in the latter case, the mass ratio of the component (M1) to the component (M2) is preferably 15/85 or more, more preferably 40/60 or more, and still more preferably 60/40 or more. In a case of adopting such a configuration, it is possible to further reduce the number of development defects.

Moreover, in a case where both of the component (M1) and the component (M2) are included in the solvent, the mass ratio of the component (M1) to the component (M2) is set to, for example, 99/1 or less.

As described above, the solvent may further include components other than the components (M1) and (M2). In this case, the content of the components other than the components (M1) and (M2) is preferably in the range of 5% to 30% by mass with respect to the total mass of the solvent.

In a case where the resist composition is an actinic ray-sensitive or radiation-sensitive resin composition for ArF, examples of the solvent include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may contain a ring, alkylene carbonate, alkyl alkoxyacetate, and alkyl pyruvate.

As the alkylene glycol monoalkyl ether carboxylate, propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, or ethylene glycol monoethyl ether acetate is preferable.

As the alkylene glycol monoalkyl ether, propylene glycol monomethyl ether, propylene glycol monoethyl ether, propylene glycol monopropyl ether, propylene glycol monobutyl ether, ethylene glycol monomethyl ether or ethylene glycol monoethyl ether is preferable.

As the alkyl lactate ester, methyl lactate, ethyl lactate, propyl lactate, or butyl lactate is preferable.

As the alkyl alkoxypropionate, ethyl 3-ethoxypropionate, methyl 3-methoxypropionate, methyl 3-ethoxypropionate, or ethyl 3-methoxypropionate is preferable.

As the cyclic lactones, β-propiolactone, β-butyrolactone, γ-butyrolactone, α-methyl-γ-butyrolactone, β-methyl-γ-butyrolactone, γ-valerolactone, γ-caprolactone, γ-octanoic lactone, or α-hydroxy-γ-butyrolactone is preferable.

As the monoketone compound which may include a ring, 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, or 3-methylcycloheptanone is preferable.

As the alkylene carbonate, propylene carbonate, vinylene carbonate, ethylene carbonate, or butylene carbonate is preferable.

As the alkyl alkoxyacetate, for example, 2-methoxyethyl acetate, 2-ethoxyethyl acetate, 2-(2-ethoxyethoxy)ethyl acetate, 3-methoxy-3-methylbutyl acetate, or 1-methoxy-2-propyl acetate is preferable.

As the alkyl pyruvate, methyl pyruvate, ethyl pyruvate, or propyl pyruvate is preferable.

As the solvent, a solvent having a boiling point of 130° C. or higher at a normal temperature under a normal pressure is preferable. Specific examples of the solvent include cyclopentanone, γ-butyrolactone, cyclohexanone, ethyl lactate, ethylene glycol monoethyl ether acetate, propylene glycol monomethyl ether acetate, 3-ethyl ethoxypropionate, ethyl pyruvate, 2-ethoxyethyl acetate, 2-(2-ethoxyethoxy)ethyl acetate, and propylene carbonate.

In the present invention, the solvents may be used singly or in combination of two or more kinds thereof.

As the solvent, a mixed solvent obtained by mixing a solvent having a hydroxyl group in the structure as an organic solvent and a solvent having no hydroxyl group may be used. As the solvent having a hydroxyl group and the solvent having no hydroxyl group, the above-mentioned exemplary compounds can be appropriately selected, but as the solvent having a hydroxyl group, alkylene glycol monoalkyl ether or alkyl lactate is preferable, and propylene glycol monomethyl ether or ethyl lactate is more preferable.

Further, as the solvent having no hydroxyl group, alkylene glycol monoalkyl ether acetate, alkyl alkoxypropionate, a monoketone compound which may include a ring, a cyclic lactone, or alkyl acetate is preferable, and propylene glycol monomethyl ether acetate, ethyl ethoxypropionate, 2-heptanone, γ-butyrolactone, cyclohexanone, or butyl acetate is more preferable, and propylene glycol monomethyl ether acetate, ethyl ethoxypropionate, or 2-heptanone are still more preferable.

A mixing ratio (mass) of the solvent having a hydroxyl group to the solvent having no hydroxyl group is preferably 1/99 to 99/1, more preferably 10/90 to 90/10, and still more preferably 20/80 to 60/40.

A mixed solvent containing 50% by mass or more of the solvent having no hydroxyl group is particularly preferable from the viewpoint of coating evenness.

As the solvent, a mixed solvent of two or more kinds including propylene glycol monomethyl ether acetate is preferable.

The content of the solvent in the resist composition is preferably set so that the concentration of solid content is 0.5% to 30% by mass, and more preferably set so that the concentration of solid content is 1% to 20% by mass. This makes the coating property of the resist composition further improved.

<(D) Acid Diffusion Control Agent>

The resist composition may include an acid diffusion control agent.

The acid diffusion control agent acts as a quencher that suppresses a reaction of the acid-decomposable resin in the unexposed area by excessive generated acids by trapping the acids generated from a photoacid generator and the like upon exposure. Examples of the acid diffusion control agent include a basic compound (DA), a basic compound (DB) having basicity reduced or lost upon irradiation with actinic rays or radiation, an onium salt (DC) which is a weak acid relative to an acid generator, a low-molecular-weight compound (DD) having a nitrogen atom and a group that leaves by the action of an acid, and an onium salt compound (DE) having a nitrogen atom in the cationic moiety. In the resist composition, a known acid diffusion control agent can be appropriately used. For example, the known compounds disclosed in paragraphs [0627] to [0664] of the specification of US2016/0070167A1, paragraphs [0095] to [0187] of the specification of US2015/0004544A1, paragraphs [0403] to [0423] of the specification of US2016/0237190A1, and paragraphs [0259] to [0328] of the specification of US2016/0274458A1 can be suitably used as the acid diffusion control agent.

As the basic compound (DA), compounds having structures represented by Formulae (A) to (E) are preferable.

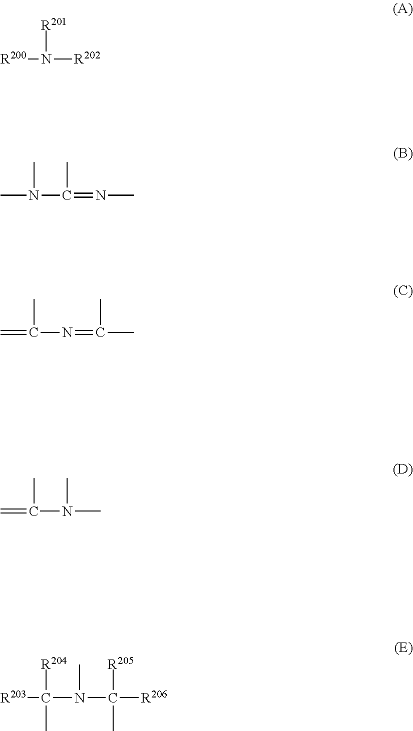

In Formulae (A) and (E),

R²⁰⁰, R²⁰¹, and R²⁰² may be the same as or different from each other, and each independently represent a hydrogen atom, an alkyl group (preferably having 1 to 20 carbon atoms), a cycloalkyl group (preferably having 3 to 20 carbon atoms), or an aryl group (having 6 to 20 carbon atoms). R²⁰¹ and R²⁰² may be bonded to each other to form a ring.

R²⁰³, R²⁰⁴, R²⁰⁵, and R²⁰⁶ may be the same as or different from each other and each independently represent an alkyl group having 1 to 20 carbon atoms.

The alkyl group in each of Formulae (A) and (E) may have a substituent or may be unsubstituted.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl groups in each of Formulae (A) and (E) are more preferably unsubstituted.

As the basic compound (DA), guanidine, aminopyrrolidine, pyrazole, pyrazoline, piperazine, aminomorpholine, aminoalkylmorpholine, or piperidine is preferable; and a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, or an aniline derivative having a hydroxyl group and/or an ether bond is more preferable.

The basic compound (DB) having basicity reduced or lost upon irradiation with actinic rays or radiation (hereinafter also referred to as a “compound (DB)”) is a compound which has a proton-accepting functional group, and decomposes under irradiation with actinic rays or radiation to exhibit deterioration in proton-accepting properties, no proton-accepting properties, or a change from the proton-accepting properties to acidic properties.

The proton-accepting functional group refers to a functional group having a group or an electron which is capable of electrostatically interacting with a proton, and for example, means a functional group with a macrocyclic structure, such as a cyclic polyether, or a functional group having a nitrogen atom having an unshared electron pair not contributing to π-conjugation. The nitrogen atom having an unshared electron pair not contributing to π-conjugation is, for example, a nitrogen atom having a partial structure represented by the following formula.

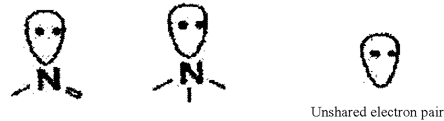

Preferred examples of the partial structure of the proton-accepting functional group include a crown ether structure, an azacrown ether structure, primary to tertiary amine structures, a pyridine structure, an imidazole structure, and a pyrazine structure.

The compound (DB) decomposes upon irradiation with actinic rays or radiation to generate a compound exhibiting deterioration in proton-accepting properties, no proton-accepting properties, or a change from the proton-accepting properties to acidic properties. Here, exhibiting deterioration in proton-accepting properties, no proton-accepting properties, or a change from the proton-accepting properties to acidic properties means a change of proton-accepting properties due to the proton being added to the proton-accepting functional group, and specifically a decrease in the equilibrium constant at chemical equilibrium in a case where a proton adduct is produced from the compound (DB) having the proton-accepting functional group and the proton.

The proton-accepting properties can be confirmed by performing pH measurement.

The acid dissociation constant pKa of the compound generated by decomposition of the compound (DB) upon irradiation with actinic rays or radiation preferably satisfies pKa<−1, and more preferably satisfies −13<pKa<−1, and still more preferably satisfies 13<pKa<−3.

Furthermore, the acid dissociation constant pKa can be determined by the above-mentioned method.

In the composition of the embodiment of the present invention, the onium salt (DC) which is a weak acid relative to a photoacid generator can be used as the acid diffusion control agent.

In a case where the photoacid generator and the onium salt that generates an acid which is a weak acid relative to an acid generated from the photoacid generator are mixed and used, an acid generated from the photoacid generator upon irradiation with actinic rays or radiation produces an onium salt having a strong acid anion by discharging the weak acid through salt exchange in a case where the acid collides with an onium salt having an unreacted weak acid anion. In this process, the strong acid is exchanged with a weak acid having a lower catalytic ability, and thus, the acid is apparently deactivated and the acid diffusion can be controlled.

As the onium salt which is a weak acid relative to the photoacid generator, compounds represented by Formulae (d1-1) to (d1-3) are preferable.

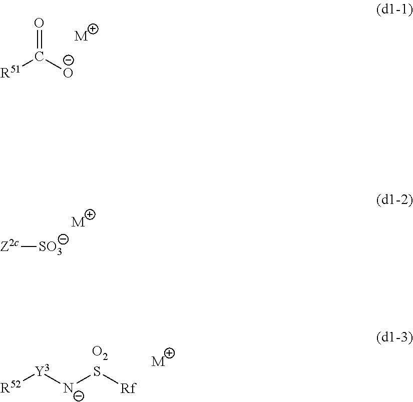

In the formula, R⁵¹ is a hydrocarbon group which may have a substituent, Z^{2c} is a hydrocarbon group having 1 to 30 carbon atoms, which may have a substituent (provided that carbon adjacent to S is not substituted with a fluorine atom), R⁵² is an organic group, Y³ is a linear, branched, or cyclic alkylene group or an arylene group, Rf is a hydrocarbon group including a fluorine atom, and M⁺'s are each independently an ammonium cation, a sulfonium cation, or an iodonium cation.

Preferred examples of the sulfonium cation or iodonium cation represented by M⁺ include the sulfonium cation exemplified for Formula (ZI) and the iodonium cation exemplified for Formula (ZII) as mentioned above.

The onium salt (DC) which is a weak acid relative to a photoacid generator may be a compound having a cationic moiety and an anionic moiety in the same molecule, in which the cationic moiety and the anionic moiety are linked by a covalent bond (hereinafter also referred to as a “compound (DCA)”).

The compound (DCA) is preferably a compound represented by any of Formulae (C-1) to (C-3).

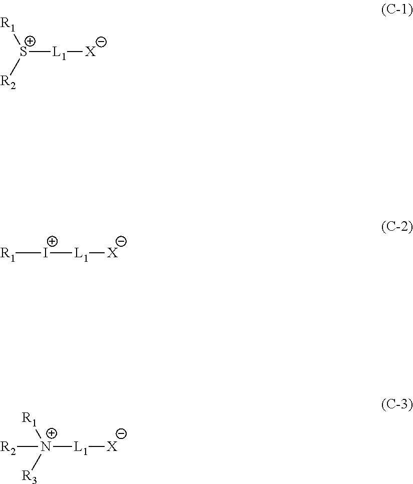

In Formulae (C-1) to (C-3),

R₁, R₂, and R₃ each independently represent a substituent having 1 or more carbon atoms.

L₁ represents a divalent linking group that links a cationic moiety with an anionic moiety, or a single bond.

—X⁻ represents an anionic moiety selected from —COO⁻, —SO₃⁻, —SO₂⁻, and —N⁻—R₄. R₄ represents a monovalent substituent having at least one of a carbonyl group: —C(═O)—, a sulfonyl group: —S(═O)₂—, or a sulfinyl group: —S(═O)— at a site for linking to an adjacent N atom.

R₁, R₂, R₃, R₄, and L₁ may be bonded to each other to form a ring structure. Further, in Formula (C-3), two of R₁ to R₃ together represent one divalent substituent, and may be bonded to an N atom by a double bond.

Examples of the substituent having 1 or more carbon atoms in each of R₁ to R₃ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group. Among those, the alkyl group, the cycloalkyl group, or the aryl group is preferable.

Examples of L₁ as a divalent linking group include a linear or branched alkylene group, a cycloalkylene group, an arylene group, a carbonyl group, an ether bond, an ester bond, an amide bond, an urethane bond, an urea bond, and a group formed by a combination of two or more kinds of these groups. L₁ is preferably the alkylene group, the arylene group, the ether bond, the ester bond, and the group formed by a combination of two or more of these groups.

The low-molecular-weight compound (DD) having a nitrogen atom and having a group that leaves by the action of an acid (hereinafter also referred to as a “compound (DD)”) is preferably an amine derivative having a group that leaves by the action of an acid on the nitrogen atom.

As the group that leaves by the action of an acid, an acetal group, a carbonate group, a carbamate group, a tertiary ester group, a tertiary hydroxyl group, or a hemiaminal ether group is preferable, and the carbamate group or the hemiaminal ether group is more preferable.

The molecular weight of the compound (DD) is preferably 100 to 1,000, more preferably 100 to 700, and still more preferably 100 to 500.

The compound (DD) may have a carbamate group having a protective group on the nitrogen atom. The protective group constituting the carbamate group is represented by Formula (d-1).

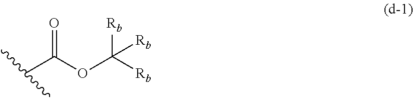

In Formula (d-1),

R_{b}'s each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be linked to each other to form a ring.

The alkyl group, the cycloalkyl group, the aryl group, or the aralkyl group represented by R_{b} may be each independently substituted with a functional group such as a hydroxyl group, a cyano group, an amino group, a pyrrolidino group, a piperidino group, a morpholino group, and an oxo group, an alkoxy group, or a halogen atom. The same applies to the alkoxyalkyl group represented by R_{b}.

As R_{b}, a linear or branched alkyl group, a cycloalkyl group, or an aryl group is preferable, and the linear or branched alkyl group, or the cycloalkyl group is more preferable.

Examples of the ring formed by the mutual linking of two R_{b}'s include an alicyclic hydrocarbon, an aromatic hydrocarbon, a heterocyclic hydrocarbon, and derivatives thereof.

Examples of the specific structure of the group represented by Formula (d-1) include, but are not limited to, the structures disclosed in paragraph [0466] of the specification of US2012/0135348A1.

The compound (DD) is preferably a compound represented by Formula (6).

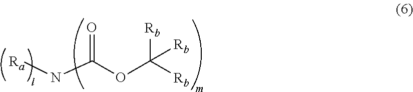

In Formula (6),

l represents an integer of 0 to 2, m represents an integer of 1 to 3, and these satisfy l+m=3.

Rₐ represents a hydrogen atom, an alkyl group, a cycloalkyl group, an aryl group, or an aralkyl group. In a case where 1 is 2, two Rₐ's may be the same as or different from each other, and the two Rₐ's may be linked to each other to form a heterocycle with the nitrogen atom in the formula. This heterocycle may include a heteroatom other than the nitrogen atom in the formula.

R_{b} has the same definition as R_{b} in Formula (d-1), and preferred examples are also the same.

In Formula (6), the alkyl group, the cycloalkyl group, the aryl group, and the aralkyl group as Rₐ may be each independently substituted with the same groups as the group mentioned above as a group which may be substituted in the alkyl group, the cycloalkyl group, the aryl group, and the aralkyl group as R_{b}.

Specific examples of the alkyl group, the cycloalkyl group, the aryl group, and the aralkyl group (such the alkyl group, the cycloalkyl group, the aryl group, and the aralkyl group may be substituted with the groups as described above) of Rₐ include the same groups as the specific examples as described above with respect to R_{b}.

Specific examples of the particularly preferred compound (DD) in the present invention include, but are not limited to, the compounds disclosed in paragraph [0475] of the specification of US2012/0135348 Å¹.

The onium salt compound (DE) having a nitrogen atom in the cationic moiety (hereinafter also referred to as a “compound (DE)”) is preferably a compound having a basic moiety including a nitrogen atom in the cationic moiety. The basic moiety is preferably an amino group, and more preferably an aliphatic amino group. All of the atoms adjacent to the nitrogen atom in the basic moiety are still more preferably hydrogen atoms or carbon atoms. In addition, from the viewpoint of improving basicity, it is preferable that an electron-withdrawing functional group (such as a carbonyl group, a sulfonyl group, a cyano group, and a halogen atom) is not directly linked to the nitrogen atom.

Preferred specific examples of the compound (DE) include, but are not limited to, the compounds disclosed in paragraph [0203] of US2015/0309408A1.

Preferred examples of the acid diffusion control agent are shown below.

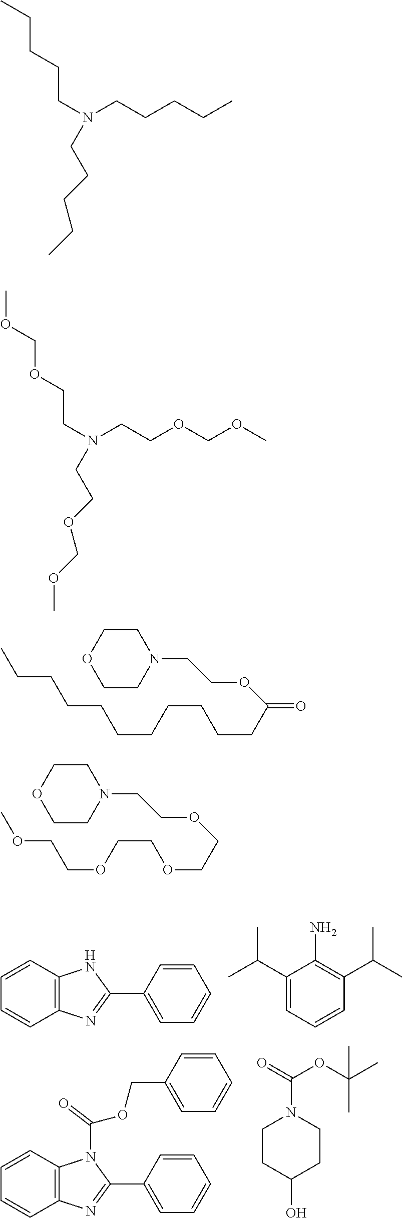

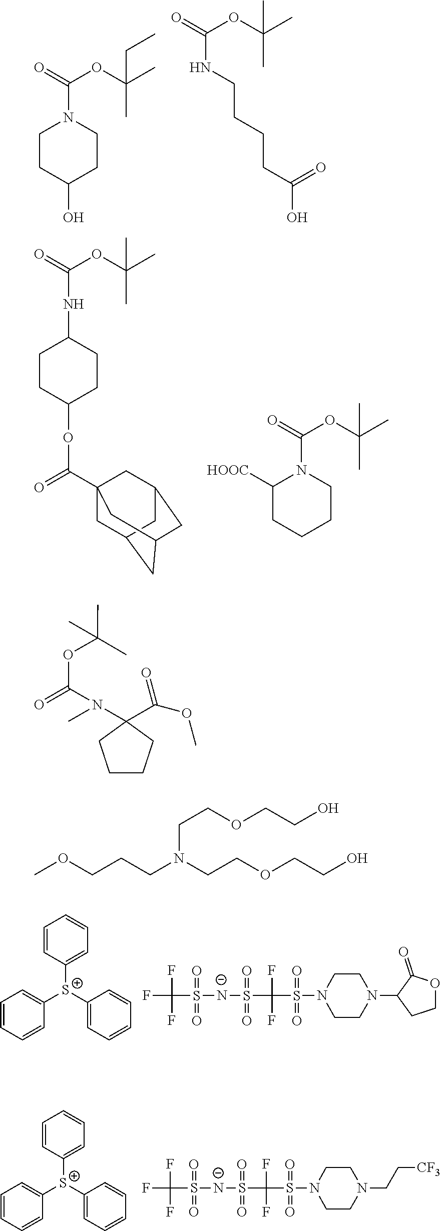

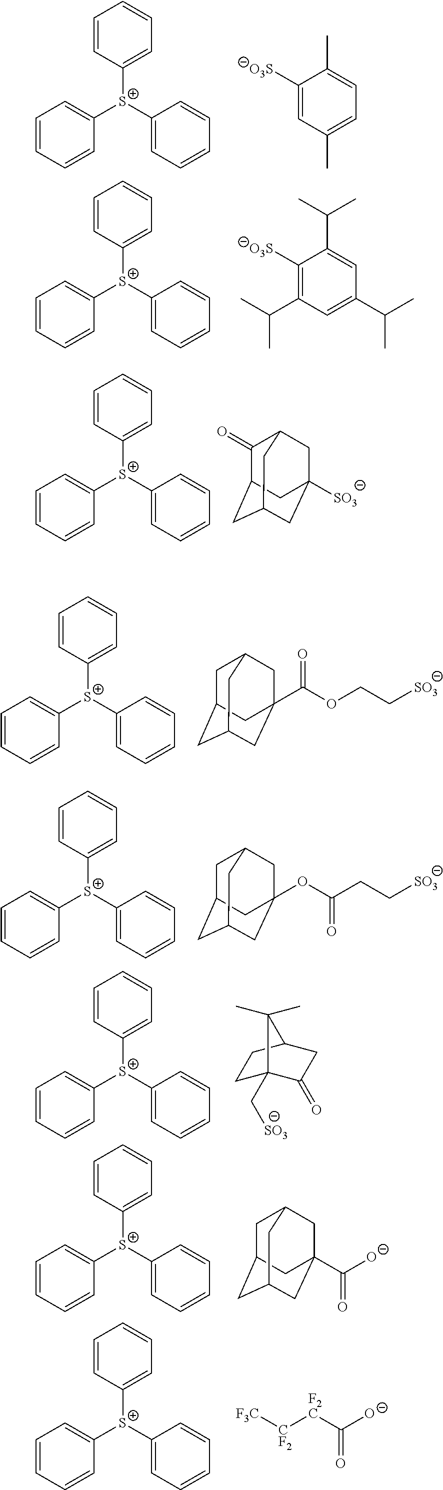

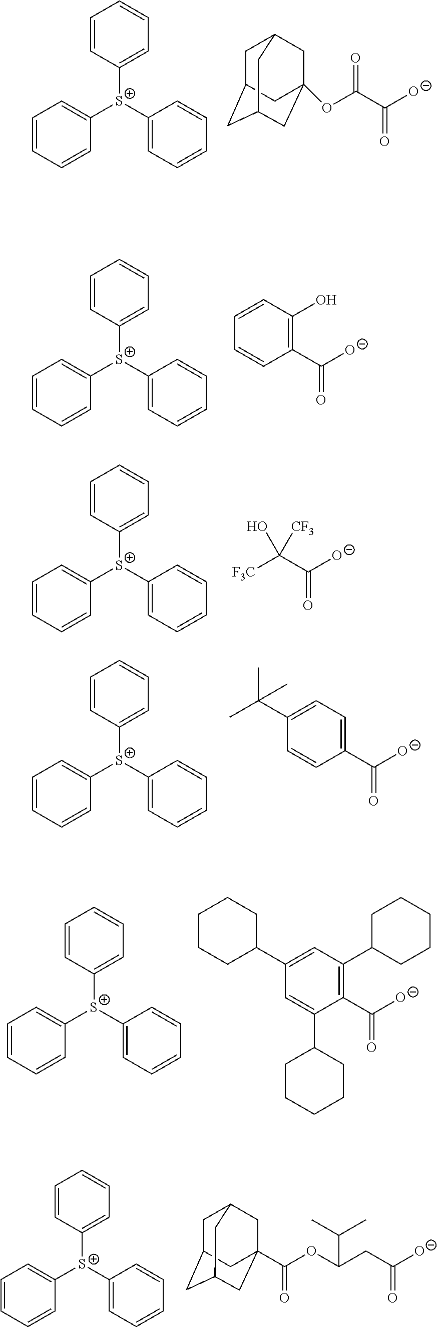

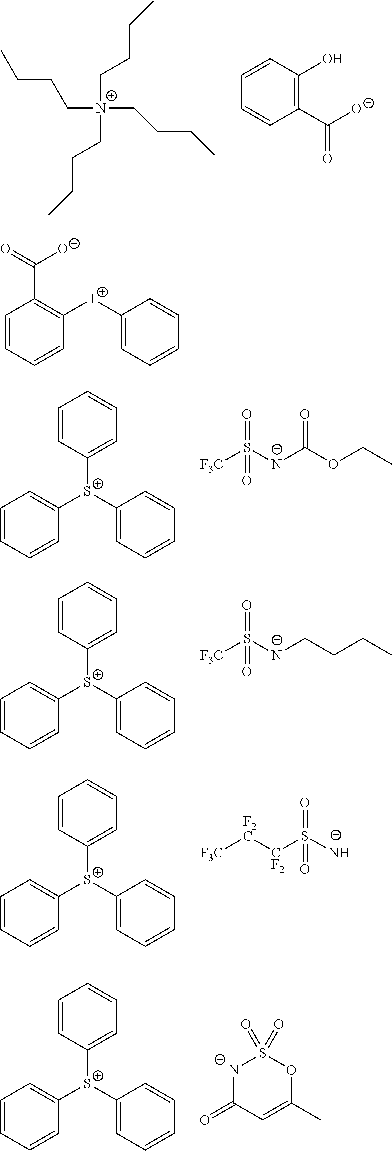

In a case where the resist composition includes an acid diffusion control agent, the content of the acid diffusion control agent (in a case where a plurality of kinds of the acid diffusion control agents are present, a total content thereof) is preferably 0.1% to 10.0% by mass, and more preferably 0.1% to 5.0% by mass, with respect to the total solid content of the composition.

In the resist composition, the acid diffusion control agents may be used singly or in combination of two or more kinds thereof.

<(E) Hydrophobic Resin>

The resist composition may include a hydrophobic resin different from the resin (A), in addition to the resin (A).

Although it is preferable that the hydrophobic resin is designed to be unevenly distributed on a surface of the resist film, it does not necessarily need to have a hydrophilic group in the molecule as different from the surfactant, and does not need to contribute to uniform mixing of polar materials and non-polar materials.

Examples of the effect of addition of the hydrophobic resin include a control of static and dynamic contact angles of a surface of the resist film with respect to water and suppression of out gas.

The hydrophobic resin preferably has any one or more of a “fluorine atom”, a “silicon atom”, and a “CH₃ partial structure which is included in a side chain moiety of a resin” from the viewpoint of uneven distribution on the film surface layer, and more preferably has two or more kinds. Incidentally, the hydrophobic resin preferably has a hydrocarbon group having 5 or more carbon atoms. These groups may be contained in the main chain or may be substituted in a side chain of the resin.

In a case where hydrophobic resin includes a fluorine atom and/or a silicon atom, the fluorine atom and/or the silicon atom in the hydrophobic resin may be included in the main chain or a side chain of the resin.

In a case where the hydrophobic resin includes a fluorine atom, as a partial structure having a fluorine atom, an alkyl group having a fluorine atom, a cycloalkyl group having a fluorine atom, or an aryl group having a fluorine atom is preferable.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and the alkyl group may further have a substituent other than the fluorine atom.

The cycloalkyl group having a fluorine atom is a monocyclic or polycyclic cycloalkyl group in which at least one hydrogen atom is substituted with a fluorine atom, and the cycloalkyl group may further have a substituent other than a fluorine atom.

Examples of the aryl group having a fluorine atom include an aryl group such as a phenyl group and a naphthyl group, in which at least one hydrogen atom is substituted with a fluorine atom, and the aryl group may further have a substituent other than the fluorine atom.

Examples of the repeating unit having a fluorine atom or a silicon atom include those exemplified in paragraph [0519] of US2012/0251948A1.

Moreover, it is also preferable that the hydrophobic resin includes a CH₃ partial structure in the side chain moiety as described above.

Here, the CH₃ partial structure contained in the side chain moiety in the hydrophobic resin includes a CH₃ partial structure contained in an ethyl group, a propyl group, and the like. On the other hand, a methyl group bonded directly to the main chain of the hydrophobic resin (for example, an α-methyl group in the repeating unit having a methacrylic acid structure) makes only a small contribution of uneven distribution on the surface of the hydrophobic resin due to the effect of the main chain, and it is therefore not included in the CH₃ partial structure in the present invention.

With regard to the hydrophobic resin, reference can be made to the description in paragraphs [0348] to [0415] of JP2014-010245A, the contents of which are incorporated herein by reference.

Furthermore, the resins described in JP2011-248019A, JP2010-175859A, and JP2012-032544A, in addition to those above, can also be preferably used as the hydrophobic resin.

In a case where the resist composition includes a hydrophobic resin, the content of the hydrophobic resin is preferably 0.01% to 20% by mass, and more preferably 0.1% to 15% by mass, with respect to the total solid content of the composition.

<(F) Surfactant>

The resist composition may include a surfactant. By incorporation of the surfactant, it is possible to form a pattern having more excellent adhesiveness and fewer development defects.

As the surfactant, fluorine-based and/or silicon-based surfactants are preferable. Examples of the fluorine-based and/or silicon-based surfactants include the surfactants described in paragraph [0276] of the specification of US2008/0248425A. In addition, EFTOP EF301 or EF303 (manufactured by Shin-Akita Chemical Co., Ltd.); FLORAD FC430, 431, or 4430 (manufactured by Sumitomo 3M Inc.); MEGAFACE F171, F173, F176, F189, F113, F110, F177, F120, or R08 (manufactured by DIC Corporation); SURFLON S-382, SC101, 102, 103, 104, 105, or 106 (manufactured by Asahi Glass Co., Ltd.); TROYSOL S-366 (manufactured by Troy Chemical Corporation); GF-300 or GF-150 (manufactured by Toagosei Chemical Industry Co., Ltd.); SURFLON S-393 (manufactured by Seimi Chemical Co., Ltd.); EFTOP EF121, EF122 Å, EF122B, RF122C, EF125M, EF135M, EF351, EF352, EF801, EF802, or EF601 (manufactured by JEMCO Inc.); PF636, PF656, PF6320, or PF6520 (manufactured by OMNOVA Solutions Inc.); KH-20 (manufactured by Asahi Kasei Corporation); or FTX-204G, 208G, 218G, 230G, 204D, 208D, 212D, 218D, or 222D (manufactured by NEOS COMPANY LIMITED) may be used. In addition, a polysiloxane polymer, KP-341 (manufactured by Shin-Etsu Chemical Co., Ltd.), can also be used as the silicon-based surfactant.

Furthermore, the surfactant may be synthesized using a fluoroaliphatic compound produced by a telomerization method (also referred to as a telomer method) or an oligomerization method (also referred to as an oligomer method), in addition to the known surfactants as shown above. Specifically, a polymer having a fluoroaliphatic group, derived from the fluoroaliphatic compound, may also be used as the surfactant. The fluoroaliphatic compound can be synthesized in accordance with the method described in JP2002-090991A.

As the polymer having a fluoroaliphatic group, a copolymer of a monomer having a fluoroaliphatic group and (poly(oxyalkylene))acrylate and/or (poly(oxyalkylene))methacrylate is preferable, and the polymer may be unevenly distributed or block-copolymerized. Furthermore, examples of the poly(oxyalkylene) group include a poly(oxyethylene) group, a poly(oxypropylene) group, and a poly(oxybutylene) group, and the poly(oxyalkylene) group, and the group may also be a unit such as those having alkylenes having different chain lengths within the same chain length such as poly(block-linked oxyethylene, oxypropylene, and oxyethylene) and poly(block-linked oxyethylene and oxypropylene). In addition, the copolymer of a monomer having a fluoroaliphatic group and (poly(oxyalkylene))acrylate (or methacrylate) is not limited only to a binary copolymer but may also be a ternary or higher copolymer obtained by simultaneously copolymerizing monomers having two or more different fluoroaliphatic groups or two or more different (poly(oxyalkylene)) acrylates (or methacrylates).

Examples of a commercially available surfactant thereof include MEGAFACE F-178, F-470, F-473, F-475, F-476, and F-472 (manufactured by DIC Corporation), a copolymer of acrylate (or methacrylate) having a C₆F₁₃ group and (poly(oxyalkylene))acrylate (or methacrylate), and a copolymer of acrylate (or methacrylate) having a C₃F₇ group, (poly(oxyethylene))acrylate (or methacrylate), and (poly(oxypropylene))acrylate (or methacrylate).

In addition, a surfactant other than the fluorine-based and/or silicon-based surfactants described in paragraph [0280] of US2008/0248425A may also be used.

These surfactants may be used singly or in combination of two or more kinds thereof.

The content of the surfactant is preferably 0.0001 to 2% by mass and more preferably 0.0005 to 1% by mass, with respect to the total solid content of the resist composition.

<(G) Carboxylic Acid Onium Salt>

The resist composition may include a carboxylic acid onium salt.

The carboxylic acid onium salt is preferably an iodonium salt or a sulfonium salt. As the anionic moiety, a linear, branched, or cyclic (for example, monocyclic or polycyclic) alkyl carboxylate anion having 1 to 30 carbon atoms is preferable, and an alkyl carboxylate anion in which part or all of the alkyl groups are fluorine-substituted is more preferable.

An oxygen atom may be included in the alkyl group. This ensures the transparency to light at a wavelength of 220 nm or shorter, improves the sensitivity and resolving power, and enhances the density dependency and the exposure margin.

Examples of the anion of the fluorine-substituted carboxylic acid include anions of fluoroacetic acid, difluoroacetic acid, trifluoroacetic acid, pentafluoropropionic acid, heptafluorobutyric acid, nonafluoropentanoic acid, perfluorododecanoic acid, perfluorotridecanoic acid, perfluorocyclohexanecarboxylic acid, and 2,2-bistrifluoromethylpropionicacid.

The content of the carboxylic acid onium salt is preferably 0.1% to 20% by mass, more preferably 0.5% to 10% by mass, and still more preferably 1% to 7% by mass, with respect to the total solid content of the resist composition.

<(H) Dissolution Inhibiting Compound Having Molecular Weight of 3,000 or Less, Whose Solubility in Alkali Developer is Increased Upon Decomposition by Action of Acid>

The resist composition may include a dissolution inhibiting compound having a molecular weight of 3,000 or less, having a solubility in an alkali developer which is increased upon decomposition by the action of an acid (hereinafter also referred to as a “dissolution inhibiting compound”).

As the dissolution inhibiting compound, an alicyclic or aliphatic compound containing an acid-decomposable group, such as a cholic acid derivative including an acid-decomposable group described in Proceeding of SPIE, 2724, 355 (1996), is preferable since it does not reduce the transparency to light at 220 nm or less.

Moreover, in a case where the resist composition of the embodiment of the present invention is exposed to a KrF excimer laser or irradiated with electron beams, a dissolution inhibiting compound including a structure in which a phenolic hydroxyl group of a phenol compound is substituted with an acid-decomposable group is preferable. In a case where the dissolution inhibiting compound is a phenol compound, the phenol compound preferably includes 1 to 9 phenol skeletons, and more preferably includes 2 to 6 phenol skeletons.

The content of the dissolution inhibiting compound is preferably 3% to 50% by mass, and more preferably 5% to 40% by mass, with respect to the total solid content of the resist composition.

Specific examples of the dissolution inhibiting compound are shown below, but the present invention is not limited thereto.

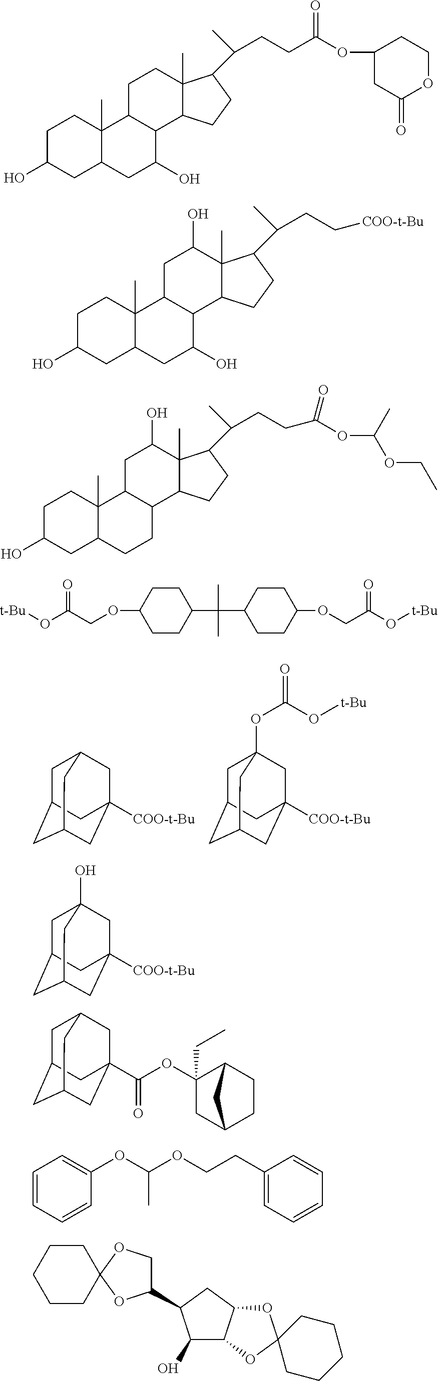

<Other Additives>

The resist composition may further include a dye, a plasticizer, a photosensitizer, a light absorber, and/or a compound that accelerates a solubility in a developer (for example, a phenol compound having a molecular weight of 1,000 or less, and an alicyclic or aliphatic compound having a carboxyl group).

The phenol compound having a molecular weight of 1,000 or less can be synthesized by those skilled in the art with reference to the method described in, for example, JP1992-122938A (JP-H04-122938A), JP1990-028531A (JP-H02-028531A), U.S. Pat. No. 4,916,210A, EP219294B, and the like.

Specific examples of the alicyclic or aliphatic compound having a carboxyl group include a carboxylic acid derivative having a steroid structure, such as a cholic acid, deoxycholic acid, and lithocholic acid, an adamantane carboxylic acid derivative, adamantane dicarboxylic acid, cyclohexane carboxylic acid, and cyclohexane dicarboxylic acid.

<Pattern Forming Method>

The procedure of the pattern forming method using the resist composition is not particularly limited, but preferably has the following steps.

Step 1: A step of forming a resist film on a substrate using the resist composition

Step 2: A step of exposing the resist film

Step 3: A step of developing the exposed resist film using a developer to form a pattern

Hereinafter, the procedure of each of the steps will be described in detail.

(Step 1: Resist Film Forming Step)

Step 1 is a step of forming a resist film on a substrate using a resist composition.

The definition of the resist composition is as described above.

Examples of the method of forming a resist film on a substrate using a resist composition include a method of applying a resist composition onto a substrate.

Furthermore, it is preferable to filter a resist composition through a filter before application, as necessary. The pore size of the filter is preferably 0.1 μm or less, more preferably 0.05 μm or less, and still more preferably 0.03 μm or less. In addition, the filter is preferably a polytetrafluoroethylene-made, polyethylene-made, or nylon-made filter.

The resist composition can be applied onto a substrate (for example, silicon and silicon dioxide coating) as used in the manufacture of integrated circuit elements by a suitable application method such as ones using a spinner or a coater. As the application method, spin application using a spinner is preferable. The rotation speed upon spin application using a spinner is preferably 1,000 to 3,000 rpm.

After applying the resist composition, the substrate may be dried to form a resist film. In addition, various underlying films (an inorganic film, an organic film, or an antireflection film) may be formed on the underlayer of the resist film.

Examples of the drying method include a method of heating and drying. The heating may e performed using a unit included in an ordinary exposure machine and/or development machine, and may also be performed using a hot plate or the like. The heating temperature is preferably 80° C. to 150° C., more preferably 80° C. to 140° C., and still more preferably 80° C. to 130° C. The heating time is preferably 30 to 1,000 seconds, more preferably 60 to 800 seconds, and still more preferably 60 to 600 seconds.

The film thickness of the resist film is not particularly limited, but is preferably 10 to 150 nm, and more preferably 15 to 100 nm, from the viewpoint that a fine pattern having higher accuracy can be formed.

Moreover, a topcoat may be formed on the upper layer of the resist film, using the topcoat composition.

It is preferable that the topcoat composition is not mixed with the resist film and can be uniformly applied onto the upper layer of the resist film.

Furthermore, it is preferable to dry the resist film before forming the topcoat. Then, the topcoat composition can be applied onto the obtained resist film by the same unit as the method for forming a resist film, and further dried to form a topcoat.

The film thickness of the topcoat is preferably 10 to 200 nm, and more preferably 20 to 100 nm.

The topcoat is not particularly limited, a topcoat known in the related art can be formed by a method known in the related art, and the topcoat can be formed on the basis of the description in, for example, paragraphs [0072] to [0082] of JP2014-059543A.

The topcoat including a basic compound as described in, for example, JP2013-061648A is preferably formed on a resist film. Specific examples of the basic compound which can be included in the topcoat include a basic compound which may be included in a resist composition which will be described later.

In addition, the topcoat preferably includes a compound which includes at least one group or bond selected from the group consisting of an ether bond, a thioether bond, a hydroxyl group, a thiol group, a carbonyl bond, and an ester bond.

(Step 2: Exposing Step)

Step 2 is a step of exposing the resist film.

Examples of the exposing method include a method of irradiating a resist film thus formed with actinic rays or radiation through a predetermined mask.

Examples of the actinic rays or radiation include infrared light, visible light, ultraviolet light, far ultraviolet light, extreme ultraviolet light, X-rays, and electron beams, preferably a far ultraviolet light having a wavelength of 250 nm or less, more preferably a far ultraviolet light having a wavelength of 220 nm or less, and particularly preferably a far ultraviolet light having a wavelength of 1 to 200 nm, specifically, KrF excimer laser (248 nm), ArF excimer laser (193 nm), F₂ excimer laser (157 nm), EUV (13 nm), X-rays, and electron beams.

It is preferable to perform baking (heating) before performing development after the exposure. The baking accelerates a reaction in the exposed area, and the sensitivity and the pattern shape are improved.

The heating temperature is preferably 80° C. to 150° C., more preferably 80° C. to 140° C., and still more preferably 80° C. to 130° C.

The heating time is preferably 10 to 1,000 seconds, more preferably 10 to 180 seconds, and still more preferably 30 to 120 seconds.

The heating may be performed using a unit included in an ordinary exposure machine and/or an ordinary development machine, and may also be performed using a hot plate or the like.

This step is also referred to as a post-exposure bake.

(Step 3: Developing Step)

Step 3 is a step of developing the exposed resist film using a developer to form a pattern.

Examples of the developing method include a method in which a substrate is dipped in a tank filled with a developer for a certain period of time (a dip method), a method in which development is performed by heaping a developer up onto the surface of a substrate by surface tension, and then leaving it to stand for a certain period of time (a puddle method), a method in which a developer is sprayed on the surface of a substrate (a spray method), and a method in which a developer is continuously jetted onto a substrate rotating at a constant speed while scanning a developer jetting nozzle at a constant rate (a dynamic dispense method).

Furthermore, after the step of performing development, a step of stopping the development may be carried out while substituting the solvent with another solvent.

The development time is not particularly limited as long as the resin in the unexposed area is sufficiently dissolved, and is preferably 10 to 300 seconds, and more preferably 20 to 120 seconds.

The temperature of the developer is preferably 0° C. to 50° C., and more preferably 15° C. to 35° C.

Examples of the developer include an alkali developer and an organic solvent developer.

As the alkali developer, it is preferable to use an aqueous alkali solution including an alkali. The type of the aqueous alkali solution is not particularly limited, but examples thereof include an aqueous alkali solution including a quaternary ammonium salt typified by tetramethylammonium hydroxide, an inorganic alkali, a primary amine, a secondary amine, a tertiary amine, an alcoholamine, a cyclic amine, or the like. Among those, the alkali developer is preferably an aqueous solution of a quaternary ammonium salt typified by tetramethylammonium hydroxide (TMAH). An appropriate amount of an alcohol, a surfactant, or the like may be added to the alkali developer. The alkali concentration of the alkali developer is usually 0.1% to 20% by mass. Further, the pH of the alkali developer is usually 10.0 to 15.0.

The organic solvent developer is a developer including an organic solvent.

The vapor pressure of the organic solvent included in the organic solvent developer (in a case of a mixed solvent, a vapor pressure as a whole) is preferably 5 kPa or less, more preferably 3 kPa or less, and still more preferably 2 kPa or less at 20° C. By setting the vapor pressure of the organic solvent to 5 kPa or less, evaporation of the developer on a substrate or in a development cup is suppressed, the temperature uniformity in a wafer plane is improved, and as a result, the dimensional uniformity in the wafer plane is enhanced.

Examples of the organic solvent used in the organic solvent developer include known organic solvents, and include an ester-based solvent, a ketone-based solvent, an alcohol-based solvent, an amide-based solvent, an ether-based solvent, and a hydrocarbon-based solvent.

It is preferable to use an ester-based solvent having 7 or more carbon atoms (preferably 7 to 14 carbon atoms, more preferably 7 to 12 carbon atoms, and still more preferably 7 to 10 carbon atoms), and 2 or less heteroatoms as the organic solvent included in the organic solvent developer, from the viewpoint that swelling of the resist film can be suppressed in a case where EUV and electron beams are used in the exposing step.

The heteroatom of the ester-based solvent is an atom other than a carbon atom and a hydrogen atom, and examples thereof include an oxygen atom, a nitrogen atom, and a sulfur atom. The number of the heteroatoms is preferably 2 or less.

As the ester-based solvent having 7 or more carbon atoms and 2 or less heteroatoms, amyl acetate, isoamyl acetate, 2-methylbutyl acetate, 1-methylbutyl acetate, hexyl acetate, pentyl propionate, hexyl propionate, butyl propionate, isobutyl isobutyrate, heptyl propionate, butyl butanoate, or the like is preferable, and isoamyl acetate is more preferable.

In a case where EUV and electron beams are used in the exposing step, a mixed solvent of the ester-based solvent and the hydrocarbon-based solvent or a mixed solvent of the ketone-based solvent and the hydrocarbon-based solvent may be used instead of the ester-based solvent having 7 or more carbon atoms and having 2 or less heteroatoms as the organic solvent included in the organic solvent developer. Also, in this case, it is effective in suppressing the swelling of the resist film.

In a case where the ester-based solvent and the hydrocarbon-based solvent are used in combination, it is preferable to use isoamyl acetate as the ester-based solvent. In addition, from the viewpoint of adjusting the solubility of the resist film, a saturated hydrocarbon-based solvent (for example, octane, nonane, decane, dodecane, undecane, and hexadecane) is preferable as the hydrocarbon-based solvent.

In a case where the ketone-based solvent and the hydrocarbon-based solvent are used in combination, it is preferable to use 2-heptanone as the ketone-based solvent. In addition, from the viewpoint of adjusting the solubility of the resist film, a saturated hydrocarbon-based solvent (for example, octane, nonane, decane, dodecane, undecane, and hexadecane) is preferable as the hydrocarbon-based solvent.

Since the content of the hydrocarbon-based solvent depends on the solvent solubility of the resist film in a case of using the mixed solvent, it is not particularly limited, the content may be appropriately adjusted to determine a necessary amount of the hydrocarbon solvent.

A plurality of the organic solvents may be mixed or the organic solvent may be used in admixture with a solvent other than those described above or water. However, in order to fully exert the effects of the present invention, the moisture content of the developer as a whole is preferably less than 10% by mass, and the developer is more preferably substantially free of the moisture. The concentration of the organic solvent (in a case of mixing a plurality of the organic solvents, a total thereof) in the developer is preferably 50% by mass or more, more preferably 50% to 100% by mass, still more preferably 85% to 100% by mass, even still more preferably 90% to 100% by mass, and particularly preferably 95% to 100% by mass.

(Other Steps)

It is preferable that the pattern forming method includes a step of performing washing using a rinsing liquid after Step 3.

Examples of the rinsing liquid used in the rinsing step after the step of performing development using the developer include pure water. Further, an appropriate amount of a surfactant may be added to pure water.

An appropriate amount of a surfactant may be added to the rinsing liquid.

A method for the rinsing step is not particularly limited, but examples thereof include a method in which a rinsing liquid is continuously jetted on a substrate rotated at a constant speed (a rotation application method), a method in which a substrate is dipped in a tank filled with a rinsing liquid for a certain period of time (a dip method), and a method in which a rinsing liquid is sprayed on a substrate surface (a spray method).

Furthermore, the pattern forming method of the embodiment of the present invention may include a heating step (postbaking) after the rinsing step. By the present step, the developer and the rinsing liquid remaining between and inside the patterns are removed by the baking step. In addition, the present step also has an effect that a resist pattern is annealed and the surface roughness of the pattern is improved. The heating step after the rinsing step is usually performed at 40° C. to 250° C. (preferably 90° C. to 200° C.) for usually 10 seconds to 3 minutes (preferably 30 to 120 seconds).

In addition, an etching treatment on the substrate may be carried out using the formed pattern as a mask. That is, the substrate (or the underlayer film and the substrate) may be processed using the pattern formed in Step 3 as a mask to form a pattern on the substrate.

A method for processing the substrate (or the underlayer film and the substrate) is not particularly limited, but is preferably a method in which a pattern is formed on a substrate by subjecting the substrate (or the underlayer film and the substrate) to dry etching using the pattern formed in Step 3 as a mask.

The dry etching may be one-stage etching or multi-stage etching. In a case where the etching is etching including a plurality of stages, the etchings at the respective stages maybe the same treatment or different treatments.

For etching, any of known methods can be used, and various conditions and the like are appropriately determined according to the type of a substrate, usage, and the like. The etching can be carried out, for example, in accordance with The International Society for Optical Engineering (Proc. of SPIE), Vol. 6924, 692420 (2008), JP2009-267112A, and the like. In addition, the etching can also be carried out in accordance with “Chapter 4 Etching” in “Semiconductor Process Text Book, 4^{th} Ed., published in 2007, publisher: SEMI Japan”.

Among those, oxygen plasma etching is preferable as the dry etching.

It is preferable that the resist composition, and various materials (for example, a solvent, a developer, a rinsing liquid, a composition for forming an antireflection film, and a composition for forming a topcoat) used in the pattern forming method of the embodiment of the present invention include no impurities such as a metal. The content of the impurities included in these materials is preferably 1 ppm by mass or less, more preferably 10 ppb by mass or less, still more preferably 100 ppt by mass or less, particularly preferably 10 ppt by mass or less, and most preferably 1 ppt by mass or less. Here, examples of the metal impurities include Na, K, Ca, Fe, Cu, Mg, Al, Li, Cr, Ni, Sn, Ag, As, Au, Ba, Cd, Co, Pb, Ti, V, W, and Zn.

Examples of a method for removing impurities such as metals from the various materials include filtration using a filter. As for the filter pore diameter, the pore size is preferably less than 100 nm, more preferably 10 nm or less, and still more preferably 5 nm or less. As the filter, a polytetrafluoroethylene-made, polyethylene-made, or nylon-made filter is preferable. The filter may be constituted with a composite material in which the filter material is combined with an ion exchange medium. As the filter, a filter which has been washed with an organic solvent in advance may be used. In the step of filtration using a filter, a plurality of kinds of filters linked in series or in parallel may be used. In a case of using a plurality of kinds of filters, a combination of filters having different pore diameters and/or materials may be used. In addition, various materials may be filtered plural times, and the step of filtering plural times may be a circulating filtration step.

In the production of a resist composition, for example, it is preferable to dissolve the respective components such as a resin and a photoacid generator in a solvent, and then perform circulatory filtration using a plurality of filters having different materials. For example, it is preferable to connect a polyethylene-made filter having a pore diameter of 50 nm, a nylon-made filter having a pore diameter of 10 nm, and a polyethylene-made filter having a pore diameter of 3 nm in permuted connection, and then perform circulatory filtration 10 times or more. A smaller pressure difference among the filters is more preferable, and the pressure difference is generally 0.1 MPa or less, preferably 0.05 MPa or less, and more preferably 0.01 MPa or less. A smaller pressure difference between the filter and the charging nozzle is also preferable, and the pressure difference is generally 0.5 MPa or less, preferably 0.2 MPa or less, and more preferably 0.1 MPa or less.

It is preferable to subject the inside of a device for producing the resist composition to gas replacement with an inert gas such as nitrogen.

With this, it is possible to suppress dissolution of an active gas such as oxygen in the composition.

The resist composition is filtered by a filter and then charged into a clean container. It is preferable that the resist composition charged in the container is subjected to cold storage. This makes it possible to suppress performance deterioration over time. A shorter time from completion of the charge of the composition into the container to initiation of cold storage is more preferable, and the time is generally 24 hours or shorter, preferably 16 hours or shorter, more preferably 12 hours or shorter, and still preferably 10 hours or shorter. The storage temperature is preferably 0° C. to 15° C., more preferably 0° C. to 10° C., and still more preferably 0° C. to 5° C.

In addition, examples of a method for reducing the impurities such as a metal included in various materials include a method of selecting raw materials having a low content of metals as raw materials constituting various materials, a method of subjecting raw materials constituting various materials to filtration using a filter, and a method of performing distillation under the condition for suppressing the contamination as much as possible by, for example, lining the inside of a device with TEFLON (registered trademark).

In addition to the filtration using a filter, removal of impurities by an adsorbing material may be performed, or a combination of filtration using a filter and an adsorbing material may be used. As the adsorbing material, known adsorbing materials can be used, and for example, inorganic adsorbing materials such as silica gel and zeolite, and organic adsorbing materials such as activated carbon can be used. It is necessary to prevent the incorporation of metal impurities in the production step in order to reduce the impurities such as a metal included in the various materials. Sufficient removal of metal impurities from a production device can be confirmed by measuring the content of metal components included in a washing liquid used to wash the production device. The content of the metal components included in the washing liquid after the use is preferably 100 parts per trillion (ppt) by mass or less, more preferably 10 ppt by mass or less, and still more preferably 1 ppt by mass or less.

A conductive compound may be added to an organic treatment liquid such as a rinsing liquid in order to prevent breakdown of chemical liquid pipes and various parts (a filter, an O-ring, a tube, or the like) due to electrostatic charging, and subsequently generated electrostatic discharging. The conductive compound is not particularly limited, but examples thereof include methanol. The addition amount is not particularly limited, but from the viewpoint that preferred development characteristics or rinsing characteristics are maintained, the addition amount is preferably 10% by mass or less, and more preferably 5% by mass or less.

For the chemical liquid pipe, it is possible to use various pipes coated with stainless steel (SUS), or a polyethylene resin, a polypropylene resin, or a fluorine resin (a polytetrafluoroethylene resin, a perfluoroalkoxy resin, or the like) which has been subjected to an antistatic treatment. Similarly, a polyethylene resin, a polypropylene resin, or a fluorine resin (a polytetrafluoroethylene resin, a perfluoroalkoxy resin, or the like) which has been subjected to an antistatic treatment can be used for a filter and an O-ring.

A method for improving the surface roughness of a pattern may be applied to a pattern formed by the method of the embodiment of the present invention. Examples of the method for improving the surface roughness of the pattern include the method of treating a pattern with a plasma of a hydrogen-containing gas disclosed in W2014/002808A. Additional examples of the method include known methods as described in JP2004-235468A, US2010/0020297A, JP2008-083384A, and Proc. of SPIE Vol. 8328 83280N-1 “EUV Resist Curing Technique for LWR Reduction and Etch Selectivity Enhancement”.

In a case where a pattern formed is in the form of a line, an aspect ratio determined by dividing the height of the pattern with the line width is preferably 2.5 or less, more preferably 2.1 or less, and still more preferably 1.7 or less.

In a case where a pattern formed is in the form of a trench (groove) pattern or a contact hole pattern, an aspect ratio determined by dividing the height of the pattern with the trench width or the hole diameter is preferably 4.0 or less, more preferably 3.5 or less, and still more preferably 3.0 or less.

The pattern forming method of the embodiment of the present invention can also be used for forming a guide pattern in a directed self-assembly (DSA) (see, for example, ACS Nano Vol. 4, No. 8, Pages 4815-4823).

In addition, a pattern formed by the method can be used as a core material (core) of the spacer process disclosed in, for example, JP1991-270227A (JP-H03-270227A) and JP2013-164509A.

Moreover, the present invention further relates to a method for manufacturing an electronic device, including the above-described pattern forming method, and an electronic device manufactured by the manufacturing method.

The electronic device of an embodiment of the present invention is suitably mounted on electric or electronic equipment (for example, home appliances, office automation (OA)-related equipment, media-related equipment, optical equipment, telecommunication equipment, and the like).

### EXAMPLES

Hereinbelow, the present invention will be described in more detail with reference to Examples. The materials, the amounts of materials used, the proportions, the treatment details, the treatment procedure, and the like shown in the Examples below may be modified as appropriate as long as the modifications do not depart from the spirit of the present invention. Therefore, the scope of the present invention should not be construed as being limited to the Examples shown below.

<Resin>

As resins A-1 to A-23, those synthesized according to a method for synthesizing a resin A-1 (Synthesis Example 1) which will be described later were used. The compositional ratio (molar ratio; corresponding in order from the left), the weight-average molecular weight (Mw), and the dispersity (Mw/Mn) of each repeating unit shown below are shown in Table 1.

Furthermore, the weight-average molecular weight (Mw) and the dispersity (Mw/Mn) of the resins A-1 to A-23 were measured by GPC (carrier: tetrahydrofuran (THF)) (a value converted in terms of polystyrene). In addition, the compositional ratio (ratio based on % by mole) of the resin was measured by ¹³C-nuclear magnetic resonance (NMR).

TABLE 1

| | Molar ratio of repeating unit | | | | Mw | Mw/Mn |
|---|---|---|---|---|---|---|
| Resin A-1 | 20 | 20 | 60 | — | 7,800 | 1.5 |
| Resin A-2 | 30 | 70 | — | — | 11,300 | 1.4 |
| Resin A-3 | 10 | 40 | 50 | — | 9,400 | 1.6 |
| Resin A-4 | 40 | 10 | 50 | — | 6,200 | 1.7 |
| Resin A-5 | 30 | 50 | 20 | — | 8,400 | 1.8 |
| Resin A-6 | 40 | 10 | 50 | — | 13,400 | 1.5 |
| Resin A-7 | 30 | 20 | 50 | — | 6,900 | 1.6 |
| Resin A-8 | 30 | 70 | — | — | 8,200 | 1.7 |
| Resin A-9 | 20 | 20 | 50 | 10 | 4,500 | 1.6 |
| Resin A-10 | 60 | 10 | 30 | — | 6,200 | 1.8 |
| Resin A-11 | 40 | 40 | 20 | — | 13,400 | 1.6 |
| Resin A-12 | 20 | 30 | 50 | — | 11,300 | 1.4 |
| Resin A-13 | 30 | 30 | 40 | — | 9,700 | 1.5 |
| Resin A-14 | 25 | 25 | 50 | — | 12,000 | 1.8 |
| Resin A-15 | 20 | 30 | 50 | — | 5,700 | 1.7 |
| Resin A-16 | 30 | 10 | 60 | — | 8,400 | 1.6 |
| Resin A-17 | 20 | 10 | 20 | 50 | 6,800 | 1.5 |
| Resin A-18 | 20 | 30 | 50 | — | 8,900 | 1.7 |
| Resin A-19 | 45 | 15 | 40 | — | 10,000 | 1.8 |
| Resin A-20 | 35 | 15 | 50 | — | 9,700 | 1.5 |
| Resin A-21 | 40 | 60 | — | — | 12,100 | 1.5 |
| Resin A-22 | 40 | 40 | 20 | — | 4,600 | 1.5 |
| Resin A-23 | 30 | 20 | 50 | — | 6,900 | 1.5 |

The structural formulae of the resins A-1 to A-23 shown in Table 1 are shown below.

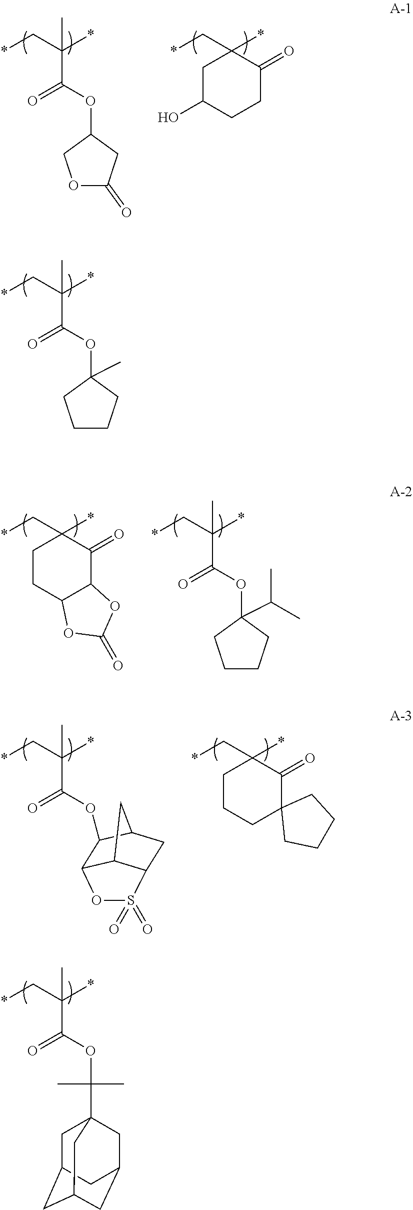

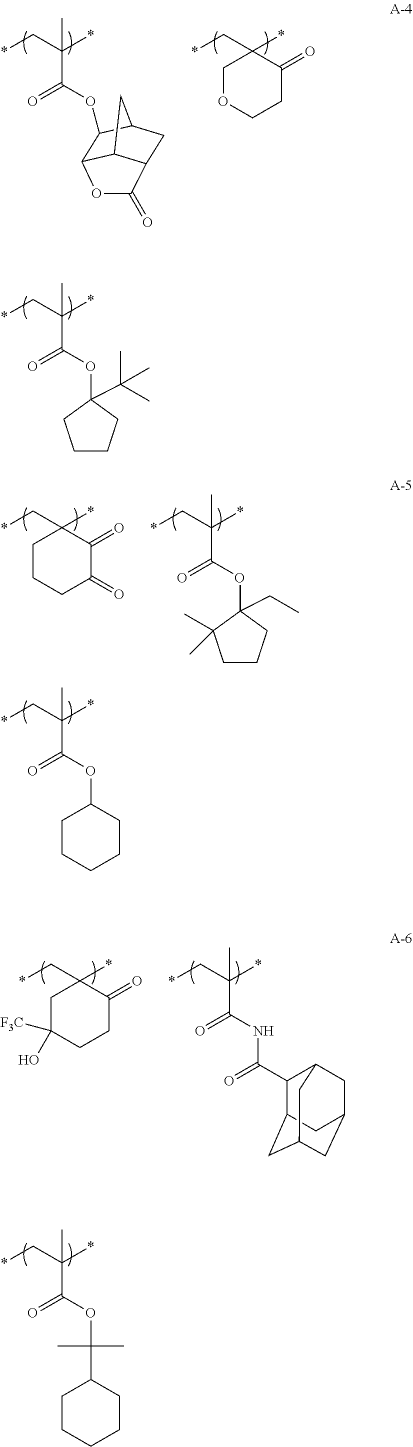

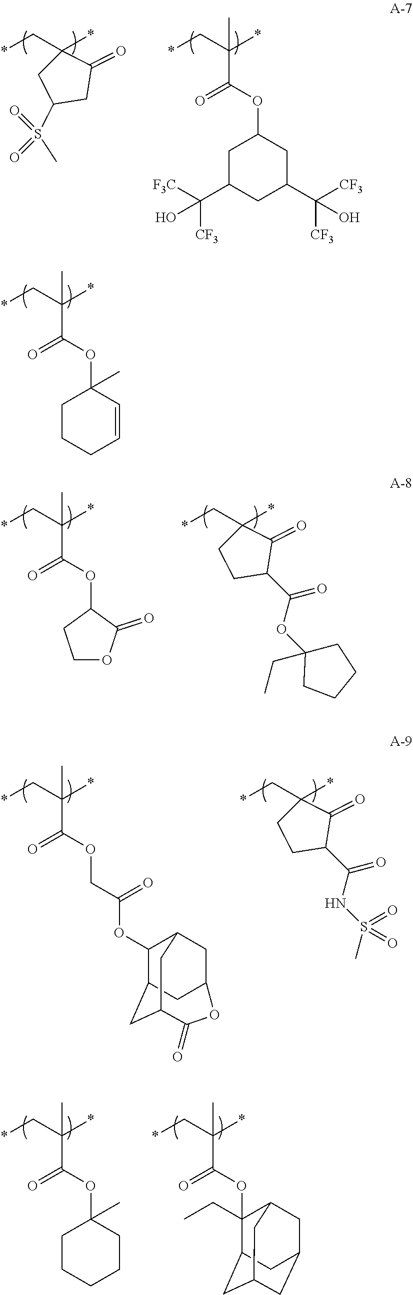

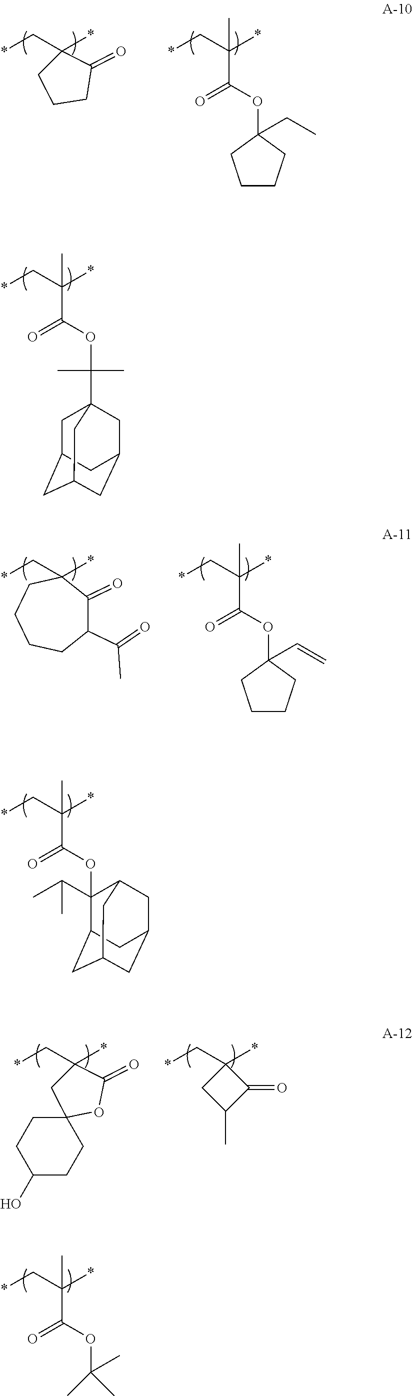

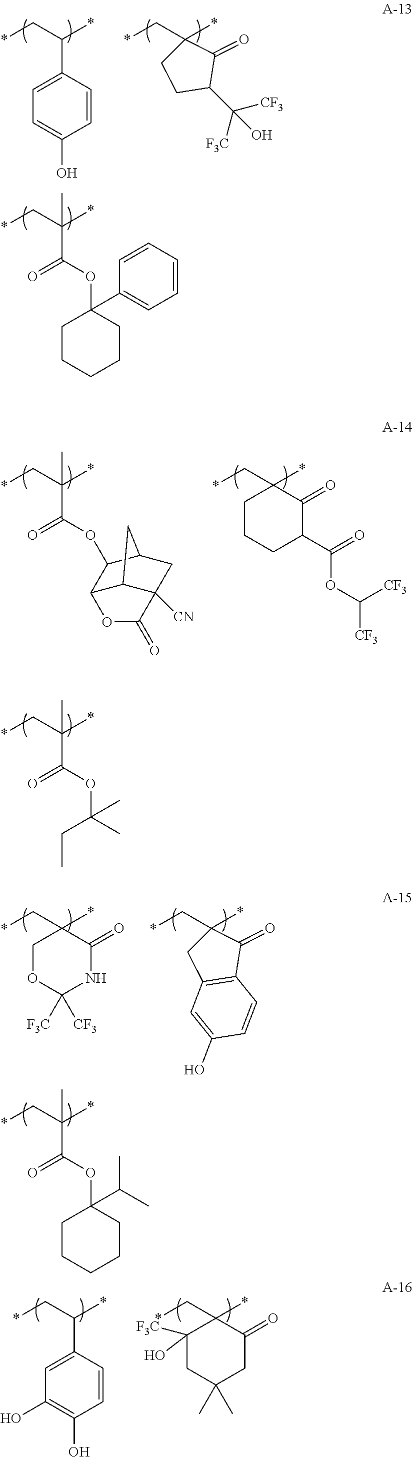

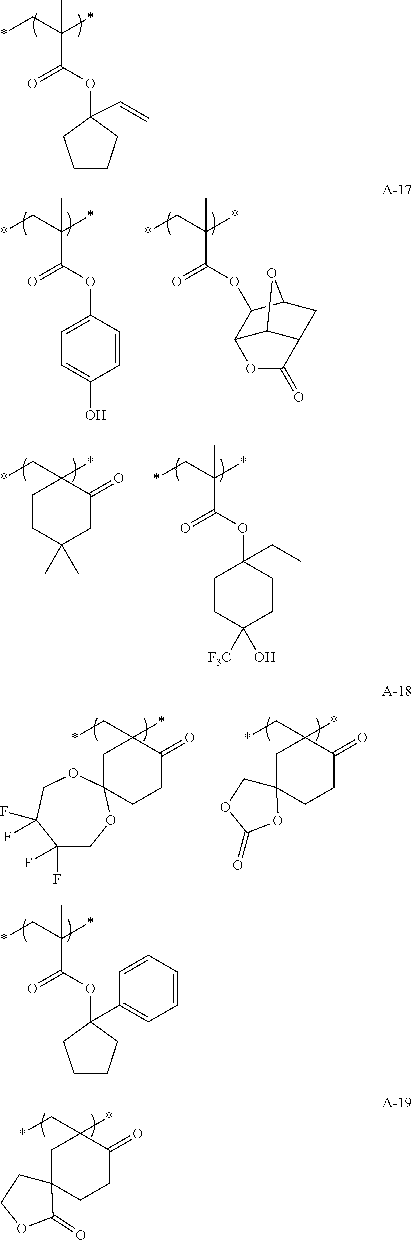

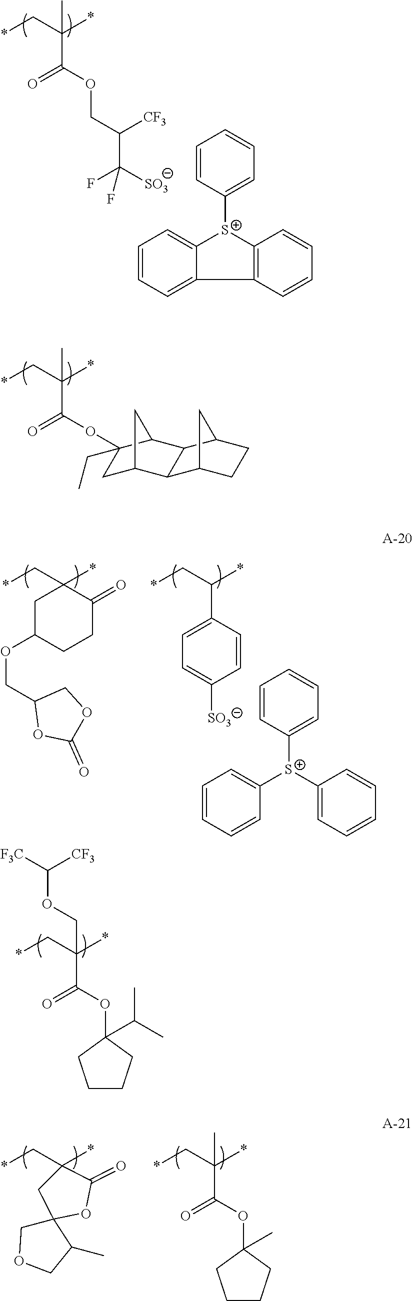

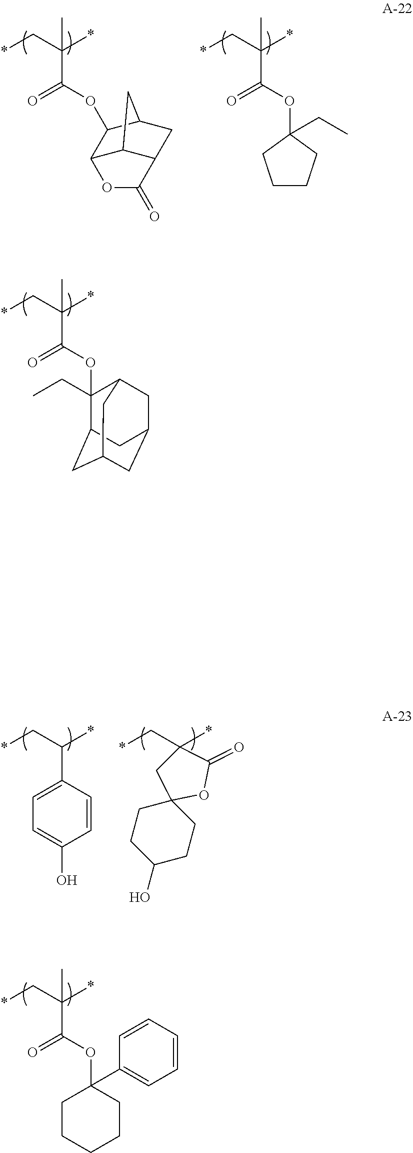

### Synthesis Example 1: Synthesis of Resin A-1

Cyclohexanone (95 parts by mass) was heated to 80° C. under a nitrogen stream. While stirring this liquid, a mixed solution of a monomer represented by Formula M-1 (10.1 parts by mass), a monomer represented by Formula M-2 (7.6 parts by mass), a monomer represented by Formula M-3 (30.3 parts by mass), cyclohexanone (177 parts by mass), and dimethyl 2,2′-azobisisobutyrate [V-601, manufactured by FUJIFILM Wako Pure Chemical Corporation] (5.2 parts by mass) were added dropwise thereto over 6 hours to obtain a reaction solution. After completion of dropwise addition, the reaction solution was further stirred at 80° C. for 2 hours. The obtained reaction solution was cooled, then reprecipitated with a large amount of methanol/water (mass ratio: 9:1), and filtered, and the obtained solid was vacuum-dried to obtain 42.3 parts by mass of a resin A-1.

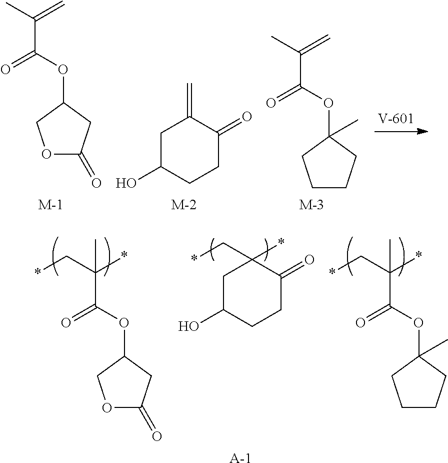

The resin A-1 thus obtained had a weight-average molecular weight (Mw: polystyrene equivalent) of 7,800 and a dispersity (Mw/Mn) of 1.5, as determined from GPC (carrier: tetrahydrofuran (THF)). The compositional ratio measured by ¹³C-nuclear magnetic resonance (NMR) was 20/20/60 in terms of a molar ratio.

<Photoacid Generator>

The structures of photoacid generators (compounds B-1 to B-15) shown in Table 3 are shown below.

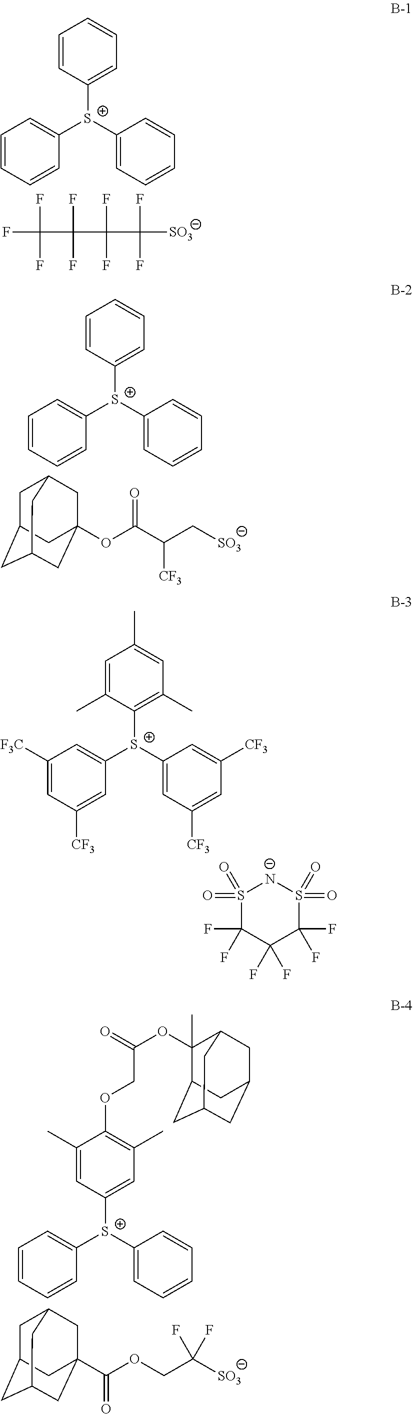

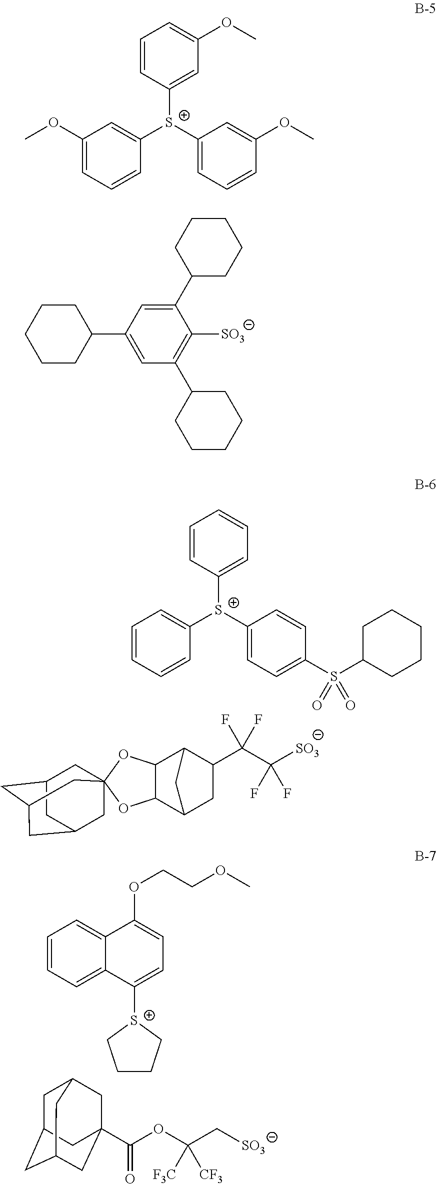

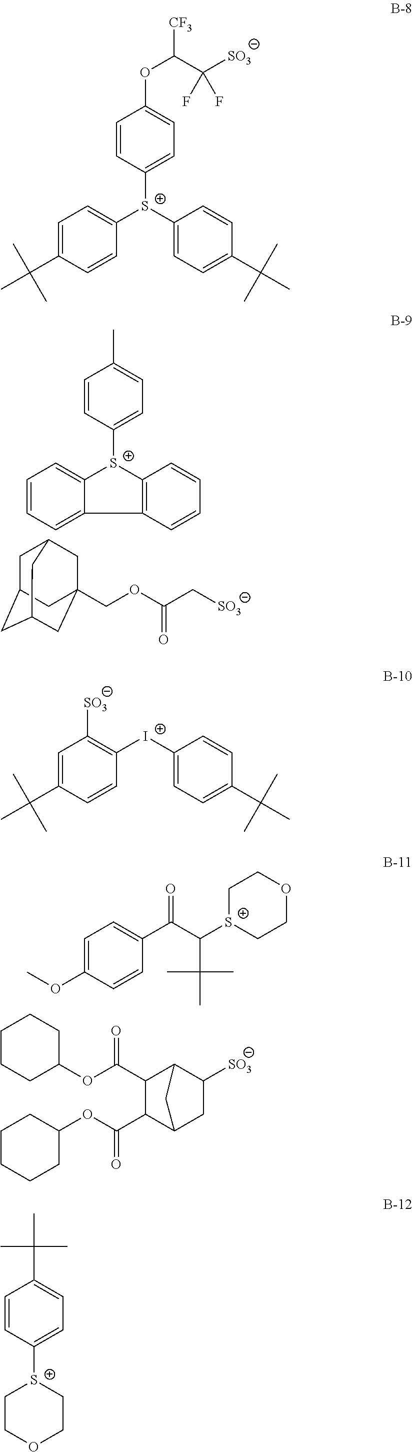

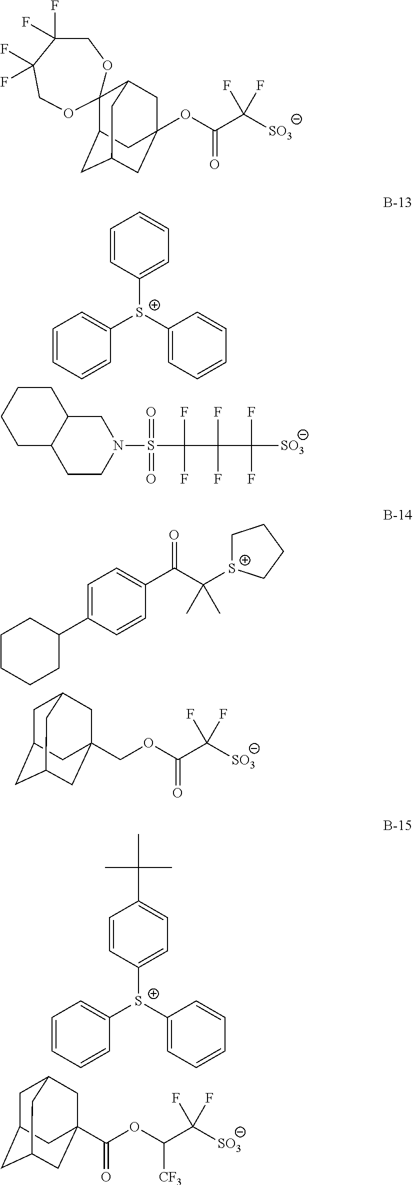

<Acid Diffusion Control Agent>

The structures of acid diffusion control agents (compounds C-1 to C-11) shown in Table 3 are shown below.

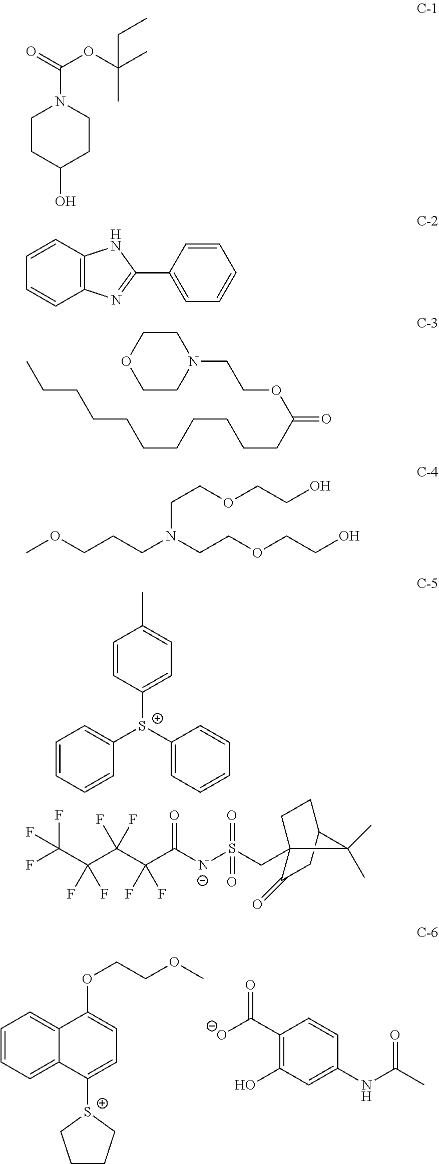

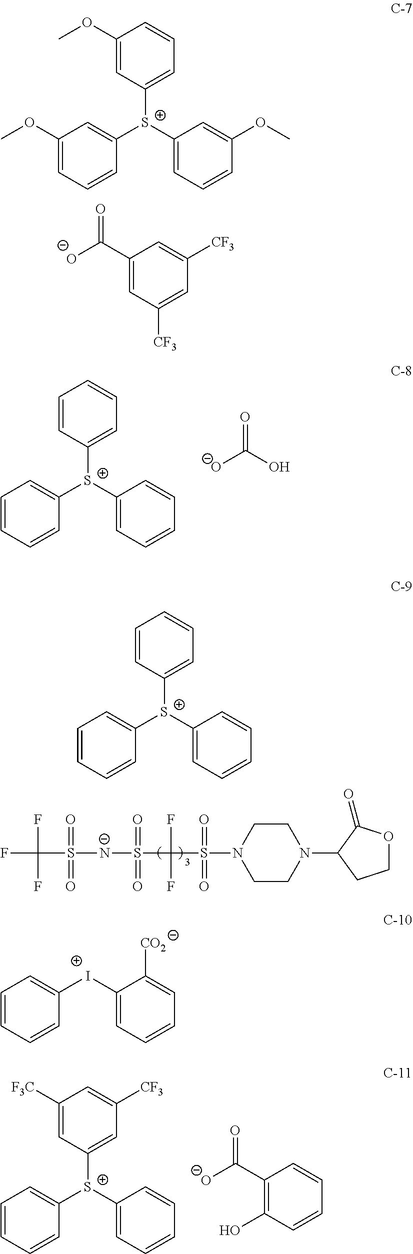

<Hydrophobic Resin and Resin for Topcoat>

Hydrophobic resins (E-1 to E-11) shown in Table 3 and topcoat resins (PT-1 to PT-3) shown in Table 4 were synthesized.

The molar ratios of the repeating units, the weight-average molecular weights (Mw), and the dispersities (Mw/Mn) in the hydrophobic resins shown in Table 3 and the resins for topcoat shown in Table 4 are shown in Table 2.

Furthermore, the weight-average molecular weights (Mw) and the dispersities (Mw/Mn) of the hydrophobic resins E-1 to E-11 and the topcoat resins PT-1 to PT-3 were measured by GPC (carrier: tetrahydrofuran (THE)) (a value converted in terms of polystyrene). In addition, the compositional ratio (ratio based on % by mole) of the resin was measured by ¹³C-nuclear magnetic resonance (NMR).

TABLE 2

| | Molar ratio of | | Molar ratio of | | Molar ratio of | | Molar ratio of | | | |
|---|---|---|---|---|---|---|---|---|---|---|
| | repeating unit 1 | | repeating unit 2 | | repeating unit 3 | | repeating unit 4 | | Mw | Mw/Mn |
| Resin E-1 | ME-3 | 60 | ME-4 | 40 | | | | | 10,000 | 1.4 |
| Resin E-2 | ME-15 | 50 | ME-1 | 50 | | | | | 12,000 | 1.5 |
| Resin E-3 | ME-2 | 40 | ME-13 | 50 | ME-9 | 5 | ME-20 | 5 | 6,000 | 1.3 |
| Resin E-4 | ME-19 | 50 | ME-14 | 50 | | | | | 9,000 | 1.5 |
| Resin E-5 | ME-10 | 50 | ME-2 | 50 | | | | | 15,000 | 1.5 |
| Resin E-6 | ME-17 | 50 | ME-15 | 50 | | | | | 10,000 | 1.5 |
| Resin E-7 | ME-7 | 100 | | | | | | | 23,000 | 1.7 |
| Resin E-8 | ME-5 | 100 | | | | | | | 13,000 | 1.5 |
| Resin E-9 | ME-6 | 50 | ME-16 | 50 | | | | | 10,000 | 1.7 |
| Resin E-10 | ME-13 | 10 | ME-18 | 85 | ME-9 | 5 | | | 11,000 | 1.4 |
| Resin E-11 | ME-8 | 80 | ME-11 | 20 | | | | | 13,000 | 1.4 |
| Resin PT-1 | ME-2 | 40 | ME-11 | 30 | ME-9 | 30 | | | 8,000 | 1.6 |
| Resin PT-2 | ME-2 | 50 | ME-8 | 40 | ME-3 | 10 | | | 5,000 | 1.5 |
| Resin PT-3 | ME-3 | 30 | ME-4 | 65 | ME-12 | 5 | | | 8,500 | 1.7 |

The monomer structures used in the synthesis of the hydrophobic resins E-1 to E-11 shown in Table 3 and the topcoat resins PT-1 to PT-3 shown in Table 4 are shown below.

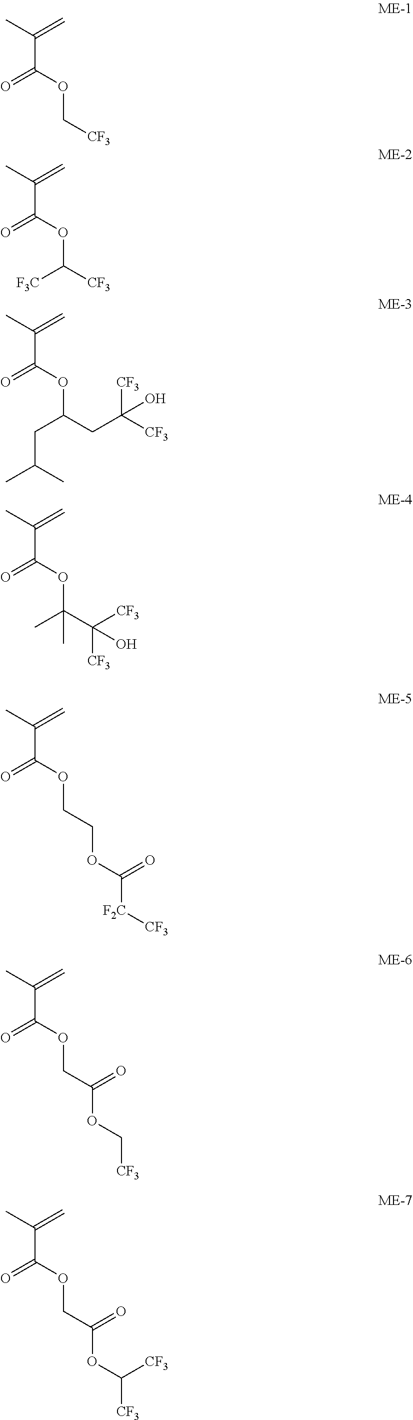

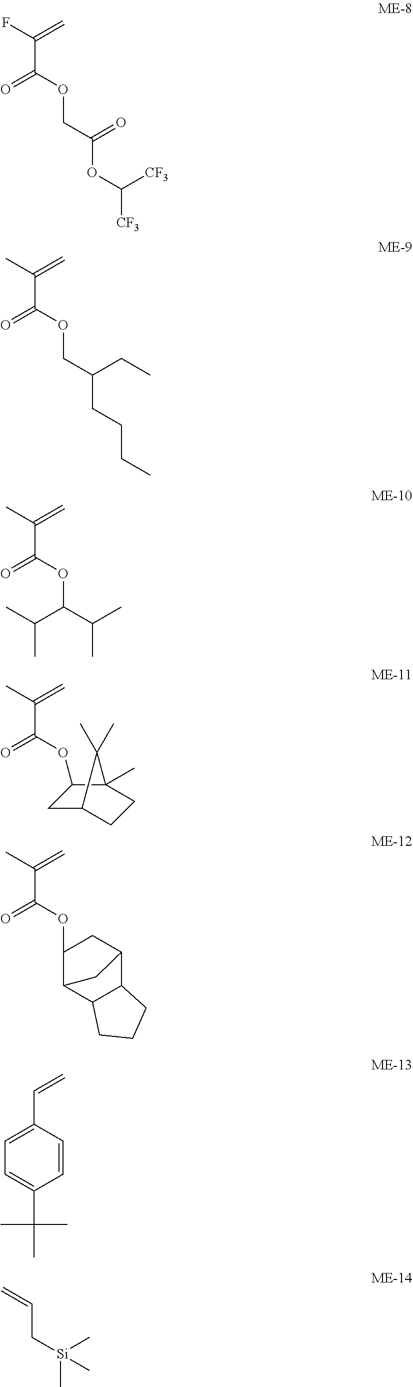

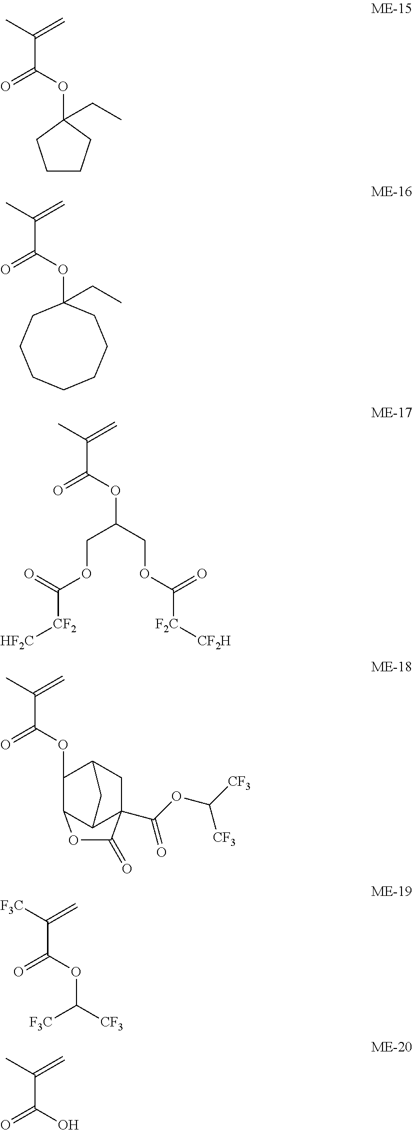

<Surfactant>

Surfactants shown in Table 3 are shown below.

H-1: MEGAFACE F176 (manufactured by DIC Corporation, fluorine-based surfactant)

H-2: MEGAFACE R⁰⁸ (manufactured by DIC Corporation, fluorine- and silicon-based surfactant)

H-3: PF656 (manufactured by OMNOVA, fluorine-based surfactant)

<Solvent>

Solvents shown in Table 3 are shown below.

F-1: Propylene glycol monomethyl ether acetate (PGMEA)

F-2: Propylene glycol monomethyl ether (PGME)

F-3: Propylene glycol monoethyl ether (PGEE)

F-4: Cyclohexanone

F-5: Cyclopentanone

F-6: 2-Heptanone

F-7: Ethyl lactate

F-8: γ-Butyrolactone

F-9: Propylene carbonate

<Preparation of Actinic Ray-Sensitive or Radiation-Sensitive Resin Composition (1) ArF Liquid Immersion Exposure>

The respective components shown in Table 3 were mixed so that the concentration of solid contents was 4% by mass. Next, the obtained mixed solution was filtered through firstly a polyethylene-made filter having a pore diameter of 50 nm, a nylon-made filter having a pore diameter of 10 nm, and lastly a polyethylene-made filter having a pore diameter of 5 nm in this order to prepare an actinic ray-sensitive or radiation-sensitive resin composition (hereinafter also referred to as a “resin composition”). In addition, in the resin composition, the solid content means all components other than the solvent. The obtained resin composition was used in Examples and Comparative Examples.

In addition, in Table 3, the content (% by mass) of each component means the content with respect to the total solid content.

TABLE 3

| | | | Photoacid | | Acid diffusion | | Hydrophobic | | | | | |
|---|---|---|---|---|---|---|---|---|---|---|---|---|
| | Resin | | generator | | control agent | | resin | | Surfactant | | Solvent | |
| | | % by | | % by | | % by | | % by | | % by | | Mixing |
| | Type | mass | Type | mass | Type | mass | Type | mass | Type | mass | Type | ratio |
| Re-1 | A-1 | 89.8 | B-15 | 8.5 | C-1 | 1.1 | E-1/E-2 | 0.6 | — | — | F-1/F-2 | 80/20 |
| Re-2 | A-2 | 81.7 | B-1/B-11 | 4.8/11.1 | C-2 | 0.9 | E-3 | 1.5 | — | — | F-1/F-2/F-8 | 70/25/5 |
| Re-3 | A-3 | 77.1 | B-2 | 18.6 | C-3 | 3.3 | E-4 | 0.9 | H-1 | 0.1 | F-1/F-8 | 70/30 |
| Re-4 | A-4 | 81.1 | B-10 | 14.2 | C-4 | 1.6 | E-8 | 3.1 | — | — | F-1/F-7 | 80/20 |
| Re-5 | A-5 | 73.8 | B-7 | 21.4 | C-5 | 4.5 | — | — | H-1/H-2 | 0.2/0.1 | F-1/F-4 | 70/30 |
| Re-6 | A-6 | 84.6 | B-6 | 12.7 | C-6 | 2.5 | — | — | H-3 | 0.1 | F-1/F-5 | 50/50 |
| Re-7 | A-7 | 77.8 | B-14/B-9 | 6.4/11.3 | C-7 | 3.7 | E-5 | 0.8 | — | — | F-1/F-8 | 90/10 |
| Re-8 | A-8 | 80.1 | B-12 | 14.1 | C-8 | 1.3 | E-9 | 4.5 | — | — | F-2/F-8 | 60/40 |
| Re-9 | A-9 | 80.5 | B-4 | 12.6 | C-9 | 4.0 | E-10 | 3.0 | — | — | F-1/F-8 | 50/50 |
| Re-10 | A-10 | 87.3 | B-8 | 9.0 | C-10 | 1.7 | E-11 | 2.0 | — | — | F-7/F-9 | 60/40 |
| Re-11 | A-11 | 74.7 | B-9 | 19.7 | C-11 | 3.8 | E-8 | 1.8 | — | — | F-1/F-8 | 50/50 |
| Re-12 | A-12 | 84.6 | B-3 | 13.0 | C-1/C-10 | 0.4/0.5 | E-7 | 1.5 | — | — | F-7/F-5 | 70/30 |
| Re-13 | A-3/A-5 | 86.8 | B-13 | 10.9 | C-2 | 1.0 | E-10 | 1.3 | — | — | F-7/F-3 | 60/40 |
| Re-14 | A-21 | 88.7 | B-1 | 8.9 | C-1 | 1.4 | E-4 | 1.0 | — | — | F-2/F-8 | 60/40 |
| Re-15 | A-22 | 88.6 | B-15 | 8.5 | C-11 | 2.3 | E-8 | 0.6 | — | — | F-1/F-8 | 70/30 |

The various components included in the topcoat composition shown in Table 4 are shown below.

<Resin (PT)>

As the resin (PT) shown in Table 4, the resins PT-1 to PT-3 shown in Table 2 were used.

<Additive (DT)>

The structures of the additives (DT) shown in Table 4 are shown below.

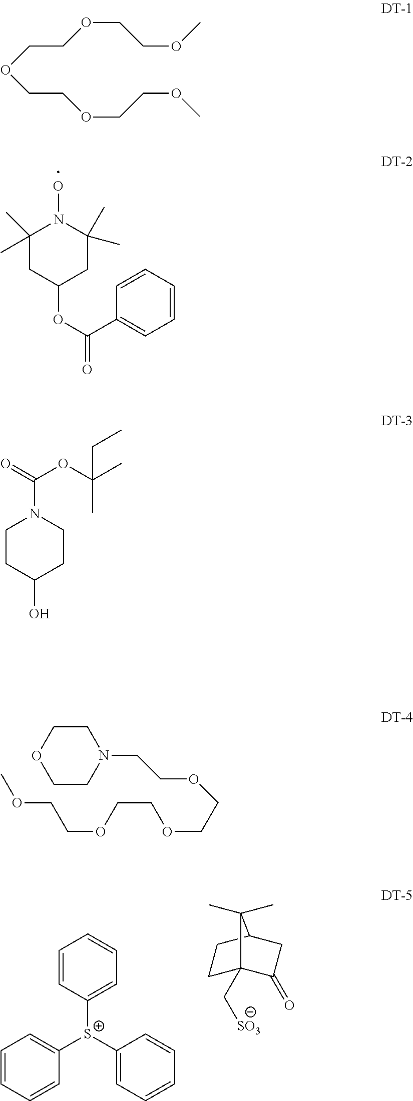

<Surfactant (H)>

As a surfactant (H) shown in Table 4, a surfactant H-3 was used.

<Solvent (FT)>

Solvents (FT) shown in Table 4 are shown below.

FT-1: 4-Methyl-2-pentanol (MIBC)

FT-2: n-Decane

FT-3: Diisoamyl ether

<Preparation of Topcoat Composition>

The respective components shown in Table 4 were mixed so that the concentration of solid contents was 3% by mass, and then the obtained mixed solution was filtered through firstly a polyethylene-made filter having a pore diameter of 50 nm, a nylon-made filter having a pore diameter of 10 nm, and lastly a polyethylene-made filter having a pore diameter of 5 nm in this order to prepare a topcoat composition. In addition, the solid content as mentioned herein means all components other than the solvent (FT). The obtained topcoat composition was used in Examples.

TABLE 4

| | Resin | | Additive | | Surfactant | | Solvent | |
|---|---|---|---|---|---|---|---|---|
| | Type | Mass [g] | Type | Mass [g] | Type | Mass [g] | Type | Mixing ratio (mass) |
| TC-1 | PT-1 | 10 | DT-1/DT-2 | 1.3/0.06 | | | FT-1/FT-2 | 70/30 |
| TC-2 | PT-2 | 10 | DT-3/DT-4 | 0.04/0.06 | H-3 | 0.005 | FT-1/FT-3 | 75/25 |
| TC-3 | PT-3 | 10 | DT-5 | 0.05 | | | FT-1/FT-3 | 10/90 |

<Pattern Formation (1): ArF Liquid Immersion Exposure and Organic Solvent Development>

A composition for forming an organic antireflection film, ARC29SR (manufactured by Brewer Science, Inc.), was applied onto a silicon wafer and baked at 205° C. for 60 seconds to form an antireflection film having a film thickness of 98 nm. The resin composition shown in Table 3 was applied thereon and baked at 100° C. for 60 seconds to form a resist film (actinic ray-sensitive or radiation-sensitive film) having a film thickness of 90 nm. In addition, in Examples 1-5, 1-6, and 1-7, a topcoat film was formed on the upper layer of the resist film (the types of topcoat compositions used are shown in Table 5). The film thickness of the topcoat film was 100 nm in all cases.

The resist film was exposed via a 6% halftone mask having a 1:1 line-and-space pattern with a line width of 45 nm, using an ArF excimer laser liquid immersion scanner (XT1700i, manufactured by ASML, NA 1.20, Dipole, outer sigma: 0.950, inner sigma: 0.850, Y deflection). Ultrapure water was used as the immersion liquid.

The resist film after the exposure was baked at 90° C. for 60 seconds, developed with n-butyl acetate for 30 seconds, and then rinsed with 4-methyl-2-pentanol for 30 seconds. Then, the film was spin-dried to obtain a negative tone pattern.

(Defect Evaluation)

After forming the pattern having a line width of 45 nm, the defect distribution on the silicon wafer was detected with UVision5 (manufactured by AMAT), and the shape of the defect was observed using SEMVisionG4 (manufactured by AMAT). The number of defects per sheet of the silicon wafer was counted and evaluated in accordance with the following evaluation standard. A smaller number of defects indicate better results.

“A”: The number of defects is 100 or less.

“B”: The number of defects is more than 100 and 300 or less.

“C”: The number of defects is more than 300 and 500 or less.

“D”: The number of defects is more than 500.

(Line Width Roughness (LWR, nm))

In a case where a 45 nm (1:1) line-and-space pattern resolved with an optimum exposure dose upon resolving a line pattern having an average line width of 45 nm was observed from the upper part of the pattern using a critical dimension scanning electron microscope (SEM (S-9380II manufactured by Hitachi, Ltd.), the line width was observed at any points, and a measurement deviation thereof was evaluated as 3G. A smaller value thereof indicates better performance. In addition, LWR (nm) is preferably 3.0 nm or less, more preferably 2.7 nm or less, and still more preferably 2.5 nm or less.

(Evaluation Results)

The results of the evaluation tests are shown in Table 5 below.

In addition, in Table 5, the “Number of ring members” column shows the number of ring members of the ring including X, L¹, and L² in Formula (1).

The “Heteroatom” column shows whether or not a heteroatom is included in at least one of L¹ or L² in Formula (1), a case where the heteroatom is included is cited as “Present”, and a case where the heteroatom is not included is cited as “Absent”.

TABLE 5

| | Actinic ray-sensitive | | | | | Evaluation |
|---|---|---|---|---|---|---|
| | or radiation- | Number | | | Evaluation | item 2 |
| | sensitive resin | of ring | | Topcoat | item 1 | LWR |
| | composition | members | Heteroatom | composition | defects | [nm] |
| Example 1-1 | Re-1 | 6 | Present | | A | 2.2 |
| Example 1-2 | Re-2 | 6 | Present | | A | 2.4 |
| Example 1-3 | Re-3 | 6 | Absent | | B | 2.7 |
| Example 1-4 | Re-4 | 6 | Present | | A | 2.4 |
| Example 1-5 | Re-5 | 6 | Present | TC-1 | A | 2.5 |
| Example 1-6 | Re-6 | 6 | Present | TC-2 | A | 2.3 |
| Example 1-7 | Re-7 | 5 | Present | TC-3 | A | 2.4 |
| Example 1-8 | Re-8 | 5 | Present | | A | 2.5 |
| Example 1-9 | Re-9 | 5 | Present | | A | 2.3 |
| Example 1-10 | Re-10 | 5 | Absent | | B | 2.7 |
| Example 1-11 | Re-11 | 7 | Present | | B | 2.6 |
| Example 1-12 | Re-12 | 4 | Absent | | C | 3.0 |
| Example 1-13 | Re-13 | 5 | Present | | A | 2.3 |
| Comparative | Re-14 | — | — | | D | 3.3 |
| Example 1-1 | | | | | | |
| Comparative | Re-15 | — | — | | D | 3.4 |
| Example 1-2 | | | | | | |

As shown in Table 5 above, the resist composition of the embodiment of the present invention exhibited desired effects.

In particular, in a case where the number of ring members in the ring including X, L¹, and L² in Formula (1) is 5 or 6, and a case where at least one of L or L² in Formula (1) includes a heteroatom, the effects were more excellent.

<Pattern Formation (2): ArF Liquid Immersion Exposure and Alkali Development>

A composition for forming an organic antireflection film, ARC29SR (manufactured by Brewer Science, Inc.), was applied onto a silicon wafer and baked at 205° C. for 60 seconds to form an antireflection film having a film thickness of 98 nm. The resin composition shown in Table 3 was applied thereon and baked at 100° C. for 60 seconds to form a resist film having a film thickness of 90 nm. In addition, in Examples 2-5 and 2-6, a topcoat film was formed as an upper layer of the resist film (the types of the topcoat composition used are shown in Table 5). The film thickness of the topcoat film was 100 nm in all cases. The resist film was exposed via a 6% halftone mask having a 1:1 line-and-space pattern with a line width of 45 nm, using an ArF excimer laser liquid immersion scanner (XT1700i, manufactured by ASML, NA 1.20, Dipole, outer sigma: 0.950, inner sigma: 0.890, Y deflection). Ultrapure water was used as the immersion liquid.

The resist film after the exposure was baked at 90° C. for 60 seconds, developed with an aqueous tetramethylammonium hydroxide solution (2.38%-by-mass) for 30 seconds, and then rinsed with pure water for 30 seconds. Thereafter, the resist film was spin-dried to obtain a positive tone pattern.

The obtained positive tone pattern was subjected to (Defect Evaluation) and (Line Width Roughness (LWR, nm)) which had been carried out on the negative tone pattern obtained by the above-described <Pattern Formation (1): ArF Liquid Immersion Exposure and Organic Solvent Development>.

(Evaluation Results)

The results of the evaluation tests above are shown in Table 6 below.

In addition, in Table 6, the “Number of ring members” column shows the number of ring members of the ring including X, L¹, and L² in Formula (1).

The “Heteroatom” column shows whether or not a heteroatom is included in at least one of L¹ or L² in Formula (1), a case where the heteroatom is included is cited as “Present”, and a case where the heteroatom is not included is cited as “Absent”.

TABLE 6

| | Actinic ray-sensitive | | | | | Evaluation |
|---|---|---|---|---|---|---|
| | or radiation- | Number | | | Evaluation | item 2 |
| | sensitive resin | of ring | | Topcoat | item 1 | LWR |
| | composition | members | Heteroatom | composition | defects | [nm] |
| Example 2-1 | Re-1 | 6 | Present | | A | 2.3 |
| Example 2-2 | Re-2 | 6 | Present | | A | 2.4 |
| Example 2-3 | Re-3 | 6 | Absent | | B | 2.7 |
| Example 2-4 | Re-4 | 6 | Present | | A | 2.3 |
| Example 2-5 | Re-5 | 6 | Present | TC-3 | A | 2.5 |
| Example 2-6 | Re-6 | 6 | Present | TC-3 | A | 2.4 |
| Example 2-7 | Re-7 | 5 | Present | | A | 2.3 |
| Example 2-8 | Re-8 | 5 | Present | | A | 2.3 |
| Example 2-9 | Re-9 | 5 | Present | | A | 2.4 |
| Example 2-10 | Re-10 | 5 | Absent | | B | 2.6 |
| Example 2-11 | Re-11 | 7 | Present | | B | 2.7 |
| Example 2-12 | Re-12 | 4 | Absent | | C | 2.9 |
| Example 2-13 | Re-13 | 5 | Present | | A | 2.3 |
| Comparative | Re-14 | — | — | | D | 3.5 |
| Example 2-1 | | | | | | |
| Comparative | Re-15 | — | — | | D | 3.4 |
| Example 2-2 | | | | | | |

<Preparation of Actinic Ray-Sensitive or Radiation-Sensitive Resin Composition (2) EUV Exposure>

The respective components shown in Table 7 were mixed so that the concentration of solid contents was 2% by mass. Next, the obtained mixed solution was filtered through firstly a polyethylene-made filter having a pore diameter of 50 nm, a nylon-made filter having a pore diameter of 10 nm, and lastly a polyethylene-made filter having a pore diameter of 5 nm in this order to prepare an actinic ray-sensitive or radiation-sensitive resin composition (hereinafter also referred to as a “resin composition”). In addition, in the resin composition, the solid content means all components other than the solvent. The obtained resin composition was used in Examples and Comparative Examples.

TABLE 7

| | | | Photoacid | | Acid diffusion | | Hydrophobic | | | | | |
|---|---|---|---|---|---|---|---|---|---|---|---|---|
| | Resin | | generator | | control agent | | resin | | Surfactant | | Solvent | |
| | | % by | | % by | | % by | | % by | | % by | | Mixing |
| | Type | mass | Type | mass | Type | mass | Type | mass | Type | mass | Type | ratio |
| Re-16 | A-13 | 79.4 | B-6 | 18.5 | C-11 | 2.1 | | | | | F-1/F-7 | 50/50 |
| Re-17 | A-14 | 76.5 | B-3/B-11 | 21.3 | C-7 | 2.2 | | | | | F-7/F-8 | 70/25/5 |
| Re-18 | A-15 | 71.5 | B-1/B-5 | 25.2 | C-8 | 3.2 | | | H-1 | 0.1 | F-1/F-8 | 70/30 |
| Re-19 | A-16 | 77.5 | B-13 | 20.4 | C-6 | 2.1 | | | | | F-7 | 100 |
| Re-20 | A-17 | 77.5 | B-2 | 19.2 | C-10 | 2.3 | E-6 | 1.0 | | | F-1/F-2/F-4 | 70/30 |
| Re-21 | A-18 | 66.8 | B-12 | 30.0 | C-10 | 3.2 | | | | | F-1/F-5 | 60/40 |
| Re-22 | A-19 | 71.5 | B-7 | 25.4 | C-3 | 3.1 | | | | | F-1/F-6 | 80/20 |
| Re-23 | A-20 | 76.9 | B-15 | 20.6 | C-6 | 2.5 | | | | | F-2/F-8 | 95/5 |
| Re-24 | A-23 | 77.6 | B-4 | 20.4 | C-5 | 2.0 | | | | | F-1/F-8 | 80/20 |

<Pattern Formation (3): EUV Exposure and Organic Solvent Development>

A composition for forming an underlayer film, AL412 (manufactured by Brewer Science, Inc.), was applied onto a silicon wafer and baked at 205° C. for 60 seconds to form an underlying film having a film thickness of 20 nm. The resin composition shown in Table 7 was applied thereon and baked at 100° C. for 60 seconds to form a resist film having a film thickness of 30 nm.

The silicon wafer having the resist film thus obtained was subjected to patternwise irradiation using an EUV exposure device (manufactured by Exitech Ltd., Micro Exposure Tool, NA 0.3, Quadrupol, outer sigma 0.68, inner sigma 0.36). Further, as a reticle, a mask having a line size=20 nm and a line:space=1:1 was used.

The resist film after the exposure was baked at 90° C. for 60 seconds, developed with n-butyl acetate for 30 seconds, and spin-dried to obtain a negative tone pattern.

(Defect Evaluation)

After forming the pattern having a line width of 20 nm, the defect distribution on the silicon wafer was detected with UVision5 (manufactured by AMAT), and the shape of the defect was observed using SEMVisionG4 (manufactured by AMAT). The number of defects per sheet of the silicon wafer was counted and evaluated in accordance with the following evaluation standard. A smaller number of defects indicate better results.

“A”: The number of defects is 100 or less.

“B”: The number of defects is more than 100 and 300 or less.

“C”: The number of defects is more than 300 and 500 or less.

“D”: The number of defects is more than 500.

(Line Width Roughness (LWR, Nm))

In a case where a 20 nm (1:1) line-and-space pattern resolved with an optimum exposure dose upon resolving a line pattern having an average line width of 20 nm was observed from the upper part of the pattern using a critical dimension scanning electron microscope (SEM (S-9380II manufactured by Hitachi, Ltd.), the line width was observed at any points, and a measurement deviation thereof was evaluated as 3a. A smaller value thereof indicates better performance. In addition, LWR (nm) is preferably 4.2 nm or less, more preferably 3.8 nm or less, and still more preferably 3.5 nm or less.

(Evaluation Results)

The results of the evaluation tests are shown in Table 8 below.

In addition, in Table 8, the “Number of ring members” column shows the number of ring members of the ring including X, L¹, and L² in Formula (1).

The “Heteroatom” column shows whether or not a heteroatom is included in at least one of L¹ or L² in Formula (1), a case where the heteroatom is included is cited as “Present”, and a case where the heteroatom is not included is cited as “Absent”.

TABLE 8

| | Actinic ray- | | | | |
|---|---|---|---|---|---|
| | sensitive or | | | | |
| | radiation- | | | | Evaluation |
| | sensitive | Number | | Evaluation | item 2 |
| | resin | of ring | Hetero- | item 1 | LWR |
| | composition | members | atom | defect | [nm] |
| Example 3-1 | Re-16 | 5 | Present | A | 3.1 |
| Example 3-2 | Re-17 | 6 | Present | A | 3.2 |
| Example 3-3 | Re-18 | 5 | Present | A | 3.1 |
| Example 3-4 | Re-19 | 6 | Present | A | 3.3 |
| Example 3-5 | Re-20 | 6 | Absent | B | 4.0 |
| Example 3-6 | Re-21 | 6 | Present | A | 3.2 |
| Example 3-7 | Re-22 | 6 | Present | A | 3.2 |
| Example 3-8 | Re-23 | 6 | Present | A | 3.4 |
| Comparative | Re-24 | — | — | D | 4.6 |
| Example 3-1 | | | | | |

<Pattern Formation (4): EUV Exposure and Alkali Development>

A composition for forming an underlayer film, AL412 (manufactured by Brewer Science, Inc.), was applied onto a silicon wafer and baked at 205° C. for 60 seconds to form an underlying film having a film thickness of 20 nm. The resin composition shown in Table 7 was applied thereon and baked at 100° C. for 60 seconds to form a resist film having a film thickness of 30 nm.

The silicon wafer having the resist film thus obtained was subjected to patternwise irradiation using an EUV exposure device (manufactured by Exitech Ltd., Micro Exposure Tool, NA 0.3, Quadrupol, outer sigma 0.68, inner sigma 0.36). Further, as a reticle, a mask having a line size=20 nm and a line:space=1:1 was used.

The resist film after the exposure was baked at 90° C. for 60 seconds, developed with an aqueous tetramethylammonium hydroxide solution (2.38%-by-mass) for 30 seconds, and then rinsed with pure water for 30 seconds. Thereafter, the resist film was spin-dried to obtain a positive tone pattern.

The obtained positive tone pattern was subjected to (Defect Evaluation) and (Line Width Roughness (LWR, nm)) which had been carried out on the negative tone pattern obtained by the above-described <Pattern Formation (3): EUV Exposure and Organic Solvent Development>.

<Evaluation Results>

The results of the evaluation tests are shown in Table 9 below.

In addition, in Table 9, the “Number of ring members” column shows the number of ring members of the ring including X, L¹, and L² in Formula (1).

The “Heteroatom” column shows whether or not a heteroatom is included in at least one of L¹ or L² in Formula (1), a case where the heteroatom is included is cited as “Present”, and a case where the heteroatom is not included is cited as “Absent”.

TABLE 9

| | Actinic ray- | | | | |
|---|---|---|---|---|---|
| | sensitive or | | | | |
| | radiation- | | | | Evaluation |
| | sensitive | Number | | Evaluation | item 2 |
| | resin | of ring | Hetero- | item 1 | LWR |
| | composition | members | atom | defect | [nm] |
| Example 4-1 | Re-16 | 5 | Present | A | 3.3 |
| Example 4-2 | Re-17 | 6 | Present | A | 2.9 |
| Example 4-3 | Re-18 | 5 | Present | A | 3.2 |
| Example 4-4 | Re-19 | 6 | Present | A | 3.5 |
| Example 4-5 | Re-20 | 6 | Absent | B | 3.9 |
| Example 4-6 | Re-21 | 6 | Present | A | 3.6 |
| Example 4-7 | Re-22 | 6 | Present | A | 3.1 |
| Example 4-8 | Re-23 | 6 | Present | A | 3.2 |
| Comparative | Re-24 | — | — | D | 4.3 |
| Example 4-1 | | | | | |

What is claimed is:

1. An actinic ray-sensitive or radiation-sensitive resin composition comprising:
a resin having a repeating unit represented by Formula (1) and a repeating unit having an acid-decomposable group; and 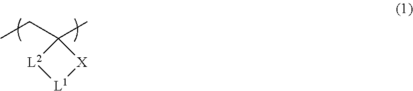
in Formula (1), X represents —C(═O)—, L¹ represents a group represented by Formula (A) or a group represented by Formula (B), and L² represents a divalent linking group,
*2-L⁴-L³-*1 Formula (A)
*2-L⁶=L⁵-*1 Formula (B)
in Formula (A), L³ represents —C(R¹)(R²)—, —C(═O)—, —C(═S)—, or —C(═N—R³)—, and
L⁴ represents a single bond or —C(R⁴)(R⁵)—,
where R¹ to R⁵ each independently represent a hydrogen atom or a substituent, and
R¹ and R² may be bonded to each other to form a ring which may include a heteroatom, R⁴ and R⁵ may be bonded to each other to form a ring which may include a heteroatom, and in a case where L³ is —C(R¹)(R²)— and L⁴ is —C(R⁴)(R⁵)—, R¹ or R², and R⁴ or R⁵ may be bonded to each other to form a ring which may include a heteroatom;
in Formula (B), L⁵ represents ═C(R⁶)—, and L⁶ represents —C(R⁷)═, where R⁶ and R¹ each independently represent a hydrogen atom or a substituent, and R⁶ and R¹ may be bonded to each other to form a ring which may include a heteroatom; and
in Formula (A) and Formula (B), *1 represents a bonding position with X and *2 represents a bonding position with L².

2. The actinic ray-sensitive or radiation-sensitive resin composition according to claim 1,
wherein a ring including X, L¹, and L² in Formula (1) has 5 or 6 ring members.

3. The actinic ray-sensitive or radiation-sensitive resin composition according to claim 1,
wherein at least one of L or L² includes a heteroatom.

4. The actinic ray-sensitive or radiation-sensitive resin composition according to claim 1,
wherein at least one of L or L² includes a halogen atom.

5. A pattern forming method comprising:
a step of forming a resist film on a substrate, using the actinic ray-sensitive or radiation-sensitive resin composition according to claim 1;
a step of exposing the resist film; and
a step of developing the exposed resist film using a developer to form a pattern.

6. A method for manufacturing an electronic device, the method comprising the pattern forming method according to claim 5.

7. A resin comprising:
a repeating unit represented by Formula (1); and
a repeating unit having an acid-decomposable group, 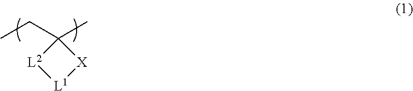
in Formula (1), X represents —C(═O)—, L¹ represents a group represented by Formula (A) or a group represented by Formula (B), and L² represents a divalent linking group,
*2-L⁴-L³-*1 Formula (A)
*2-L⁶-L⁵-*1 Formula (B)
in Formula (A), L³ represents —C(R¹)(R²)—, —C(═O)—, —C(═S)—, or —C(═N—R³)—, and
L⁴ represents a single bond or —C(R⁴)(R⁵)—,
where R¹ to R⁵ each independently represent a hydrogen atom or a substituent, and
R¹ and R² may be bonded to each other to form a ring which may include a heteroatom, R⁴ and R¹ may be bonded to each other to form a ring which may include a heteroatom, and in a case where L³ is —C(R¹)(R²)— and L⁴ is —C(R⁴)(R⁵)—, R¹ or R², and R⁴ or R⁵ may be bonded to each other to form a ring which may include a heteroatom;
in Formula (B), L⁵ represents ═C(R⁶)—, and L⁶ represents —C(R⁷)═, where R⁶ and R⁷ each independently represent a hydrogen atom or a substituent, and R⁶ and R¹ may be bonded to each other to form a ring which may include a heteroatom; and
in Formula (A) and Formula (B), *1 represents a bonding position with X and *2 represents a bonding position with L².

8. The actinic ray-sensitive or radiation-sensitive resin composition according to claim 2, wherein at least one of L¹ or L² includes a heteroatom.

9. The actinic ray-sensitive or radiation-sensitive resin composition according to claim 2, wherein at least one of L or L² includes a halogen atom.

10. A pattern forming method comprising:
a step of forming a resist film on a substrate, using the actinic ray-sensitive or radiation-sensitive resin composition according to claim 2;
a step of exposing the resist film; and
a step of developing the exposed resist film using a developer to form a pattern.

11. A method for manufacturing an electronic device, the method comprising the pattern forming method according to claim 10.

12. The actinic ray-sensitive or radiation-sensitive resin composition according to claim 3, wherein at least one of L¹ or L² includes a halogen atom.

13. A pattern forming method comprising:
a step of forming a resist film on a substrate, using the actinic ray-sensitive or radiation-sensitive resin composition according to claim 3;
a step of exposing the resist film; and
a step of developing the exposed resist film using a developer to form a pattern.

14. A method for manufacturing an electronic device, the method comprising the pattern forming method according to claim 13.

15. A pattern forming method comprising:
a step of forming a resist film on a substrate, using the actinic ray-sensitive or radiation-sensitive resin composition according to claim 4;
a step of exposing the resist film; and
a step of developing the exposed resist film using a developer to form a pattern.

16. A method for manufacturing an electronic device, the method comprising the pattern forming method according to claim 15.
